(19) United States
(12) Patent Application Publication
(10) Pub. No.: US 2024/0064947 A1
(43) Pub. Date: Feb. 22, 2024

(54) POLYMER COMPOSITE

(71) Applicant: Axiom Group Inc., Aurora (CA)

(72) Inventors: Meysam Salari, Toronto (CA); Nello D. Sansone, Richmond Hill (CA); Zahir Razzaz, Mississauga (CA); Matthew Leroux, Whitby (CA); Patrick C. Lee, Etobicoke (CA); Rafaela Antunes Costa Aguiar, Toronto (CA); Iman Soltani, Richmond Hill (CA)

(21) Appl. No.: 18/368,857

(22) Filed: Sep. 15, 2023

Related U.S. Application Data
(63) Continuation-in-part of application No. PCT/IB2023/058292, filed on Aug. 18, 2023.
(60) Provisional application No. 63/407,252, filed on Sep. 16, 2022.
(60) Provisional application No. 63/399,371, filed on Aug. 19, 2022.

(51) Int. Cl. H05K 9/00; C08F 10/06; C08K 7/14; C09K 5/14

(52) U.S. Cl. CPC H05K 9/0083; C08F 10/06; C08K 7/14; C09K 5/14; C08K 2201/001; C08K 2201/003; C08K 2201/004; C08K 2201/011; C08K 2201/014

(57) ABSTRACT

Provided is a polymer composite reinforced with graphene nanoplatelets and glass fibers, which may be prepared by injection molding. Molecular interactions between the graphene nanoplatelets and the glass fibers result in improved mechanical performance in the polymer composite. Synergistic effects are observed when the concentration of the glass fibers is over 10% and the concentration of the graphene nanoplatelets is between about 0.25% and about 5%. Particular examples of the polymer composite provide electromagnetic inference shielding.

### CROSS-REFERENCE TO RELATED APPLICATION

This application claims the benefit of U.S. Provisional Patent Application No. 63/407,252 entitled “MULTIFUNCTIONAL HYBRID GRAPHENE NANOPLATELETS/GLASS FIBER COMPOSITES WITH TAILORED MECHANICAL PROPERTIES FOR ELECTROMAGNETIC INTERFERENCE SHIELDING APPLICATIONS”, filed Sep. 16, 2022, and is also a continuation-in-part of PCT/IB2023/058292 entitled “POLYMER COMPOSITE”, filed Aug. 18, 2023, which claims the benefit of U.S. Provisional Patent Application No. 63/399,371 entitled “TAILORING MULTIFUNCTIONAL AND LIGHTWEIGHT HIERARCHICAL HYBRID GRAPHENE NANOPLATELET AND GLASS FIBER COMPOSITES”, filed Aug. 19, 2022; the entire contents of each of which are incorporated herein by reference.

### FIELD

The present specification is directed to polymer composites and particularly hybrid polymers comprising graphene nanoplatelets and glass fiber reinforcement.

### BACKGROUND

Lightweighting is a strategy aimed at reducing the overall weight of vehicles and aircraft to enhance fuel efficiency and performance. In automotive and aerospace applications, every kilogram of weight reduction translates into fuel savings, increased range, and reduced emissions. Polymers, being lightweight and versatile materials, have become increasingly popular for lightweighting purposes. However, reinforcing materials are necessary to meet the mechanical and physical standards of automotive and aerospace applications in which both strength and functionality are required.

Hybrid composites comprising glass fiber and nanosized fillers have been explored to address drawbacks and shortcomings inherent to conventional biphasic single-fiber reinforced composites. Glass fibers and nanosized filler generally improve the mechanical properties of a polymer composite but approaches that merely rely on glass fibers for reinforcement can also reduce the flowability of the polymer composite while increasing the weight, brittleness, and cost. Nanosized fillers also have faced serious challenges in improving the strength.

Furthermore, the unprecedented proliferation of electronic devices in recent years has resulted in the pervasiveness of electromagnetic (EM) waves emitted from such electronic devices. These EM waves produce electromagnetic interference (EMI) that cause malfunctions in the operations of surrounding electronic equipment.

### SUMMARY

An aspect of the specification provides a polymer composite that includes a polymer matrix, greater than 20±1% by weight of the composite of glass fibers; and between about 0.25±0.01% to 5±0.2% by weight of the composite of graphene nanoplatelets.

The glass fibers may be silanized. The glass fibers may have an average length between 1±0.05 mm and 20±1 mm. The glass fibers may have an average length of about 10±0.5 mm. The glass fibers may have an average diameter of between 4±0.2 μm and 34±1.7 μm. The glass fibers may have an average diameter of 14±0.7 μm. The glass fibers may include between 15±1% and 60%±3% by weight of the composite. The composite may include 40±2% glass fibers by weight of the composite. At least a portion of the graphene nanoplatelets may be bound to the glass fibers.

The agglomerate flake diameter of the graphene nanoplatelets may be between 0.2 μm and 70 μm. The agglomerate flake diameter of the graphene nanoplatelets may be about 38±2 μm. The graphene nanoplatelets may include between about 1 and about 100 layers of graphene. The graphene nanoplatelets may include between about 6 and about 10 layers of graphene. The graphene nanoplatelets may have a bulk density of 0.18±0.01 g/cm³. The polymer composite may include 0.5±0.025% graphene nanoplatelets by weight of the composite.

The polymer composite may have a specific tensile strength greater than 6×10⁴ Pa·m⁴/kg and a flexural strength great than 90 MPa.

The polymer matrix may include polypropylene. The polypropylene may include a homopolymer. The polypropylene may be designed to have a melt flow rate of about 4 to about 50 g/10 min. The polypropylene may be designed to have a melt flow rate of 35±2 g/10 min to 70±2 g/10 min.

The polymer composite may have a density of 1±0.05 g/cm³ to 2±0.1 g/cm³.

Another aspect of the specification provides a polymer composite that includes a polymer matrix, about 40±2% by weight of the composite of glass fibers; and about 0.5±0.025% by weight of the composite of graphene nanoplatelets, the graphene nanoplatelets bound to the glass fibers.

Another aspect of the specification provides a component for a vehicle. The component includes one of the above-described polymer composites. The component may be for an automotive vehicle or an aerospace vehicle.

A further aspect of the specification provides a method of preparing a polymer composite. The method includes melt mixing a polymer matrix with glass fibers and graphene nanoplatelets to create a composition including greater than 20% by weight of the composition of the glass fibers, and between 0.1±0.01% to 5±1% by weight of the composition of the graphene nanoplatelets. The composition is injected into a mold with an injection molding machine.

A further aspect of the specification provides a method of preparing a polymer composite. The method includes dry blending a first masterbatch including a polymer matrix and glass fibers with a second masterbatch including the polymer matrix and graphene nanoplatelets to create a composition that is greater than 20% by weight of the composition of the glass fibers, and between 0.1±0.01% to 5±1% by weight of the composition of the graphene nanoplatelets. The composition is melt-mixed with an injection molding machine and injected into a mold with the injection molding machine.

The mold may be shaped to form the composition into a component for a vehicle. The vehicle may be an automotive vehicle or an aerospace vehicle.

The component may be a battery encasement.

A further aspect of the specification provides a component for a vehicle that includes the above-described polymer composite.

A further aspect of the specification provides a polymer composite for use in electromagnetic interference (EMI) shielding including polypropylene, 10±2% to 30±6% by weight of the composite of glass fibers, and 1±0.2% to 3±0.6 by weight of the composite of graphene nanoplatelets.

The graphene nanoplatelets may include an average of 6 to 10 layers of graphene. The polymer composite may have an electromagnetic interference shielding effectiveness of about 19 dB to about 24 dB, and in particular examples, at least about 20 db. The polymer composite may have a thermal conductivity of about 0.84 W/m·K to about 1.24 W/m·K, and in particular examples, about 1.09 W/m·K. The polymer composite may have a tensile strength of about 60 to about 85 MPa or about 80 MPa. The polymer composite may have a tensile modulus of about 7 GPa to about 10 GPa. The polymer composite may have a tensile modulus of about 9.4 GPa.

The glass fibers may be silanized. The glass fibers have an average length between 1±0.05 mm and 20±1 mm. The glass fibers may have an average length of about 10±0.5 mm. The glass fibers may have an average diameter of between 4±0.2 μm and 34±1.7 μm. The glass fibers may have an average diameter of 14±0.7 μm. The composite may include between 20% and 26% glass fibers by weight of the composite. The composite may include 25±1% glass fibers by weight of the composite. At least a portion of the graphene nanoplatelets may be bound to the glass fibers. The agglomerate flake diameter of the graphene nanoplatelets may be between 0.2 μm and 70 μm, and in particular examples, about 38±2 μm. The graphene nanoplatelets may have between about 1 and about 100 layers of graphene, and in particular examples, between about 6 and about 10 layers of graphene on average. The graphene nanoplatelets may have between about 11 and about 20 layers of graphene on average. The graphene nanoplatelets may have a bulk density of 0.18±0.01 g/cm³. The graphene nanoplatelets may be 1.8%±0.4% by weight of the composite. The polymer matrix may include polypropylene. The polypropylene may include a homopolymer. The polypropylene may be designed to have a melt flow rate of about 4 to about 50 g/10 min. The polypropylene may be designed to have a melt flow rate of 35±2 g/10 min to 70±2 g/10 min. The polymer composite may have a density of about 0.99±0.1 g/cm³.

In another aspect, the specification discloses a polymer composite for electromagnetic interference shielding. The polymer composite includes polypropylene, 25±1% by weight of the composite of glass fibers, and 1.8±0.4% by weight of the composite of graphene nanoplatelets. The graphene nanoplatelets have an average of 6 to 10 layers of graphene. The polymer composite has an electromagnetic interference shielding effectiveness of at least about 20 dB.

In a further aspect, the specification discloses an enclosure for an electric component of a vehicle including one of the above-described polymer composites for EMI shielding. The electric component may include a battery and the enclosure may include an encasement for the battery.

In a further aspect, the specification discloses a coating for a conductor, the coating including one of the above-described polymer composites for EMI shielding.

In a further aspect, the specification discloses an electric vehicle including one of the above-described polymer composites for EMI shielding.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

Embodiments are described with reference to the following figures.

FIG. 1A is a schematic diagram of graphene nanoplatelets coating a glass fiber, according to one embodiment.

FIG. 1B is a schematic diagram of a graphene nanoplatelet chemically binding to a glass fiber, according to another embodiment.

FIG. 1C is a schematic diagram of spherulitic crystals binding to graphene nanoplatelets coating a glass fiber, according to another embodiment.

FIG. 2A is a method of preparing a polymer composite, according to an embodiment.

FIG. 2B is a flowchart depicting exemplary performance of method 200.

FIG. 2C is a flowchart depicting exemplary performance of method 200.

FIG. 3 is a graph comparing the FTIR spectra for un-sized glass fibers (GF), sized GF, and a hybrid composite of polypropylene (PP), graphene nanoplatelets (GnP, and GF.

FIG. 4 is a graph comparing the XPS full spectra for un-sized GF, sized GF, and a hybrid composite of PP, GnP, and GF.

FIG. 5 is a graph comparing the high-resolution C1s region spectra for un-sized GF, sized GF, and a hybrid composite of PP, GnP, and GF.

FIG. 6 is a graph comparing the high-resolution N1s region spectra for un-sized GF, sized GF, and a hybrid composite of PP, GnP, and GF.

FIG. 7A is an SEM image of graphene nanoplatelets and glass fibers.

FIG. 7B is an SEM image of graphene nanoplatelets and glass fibers.

FIG. 7C is a POM image of graphene nanoplatelets and glass fibers.

FIG. 8A is an SEM image for the core region of Neat PP.

FIG. 8B is an SEM image for the core region of PPGF10.

FIG. 8C is an SEM image for the core region of PPGnP0.5.

FIG. 8D is an SEM image for the core region of PPGnP0.5GF10.

FIG. 9 is a thermogram for crystallization for example composites.

FIG. 10 is a thermogram for second heating for example composites.

FIG. 11 is a graph showing XRD diffractograms for example composites.

FIG. 12 is a graph of κ_{β} as a function of reinforcement concentration for example composites.

FIG. 13 is a graph of χ_{c} as a function of reinforcement concentration, for example composites.

FIG. 14 is a graph of the specific tensile strength versus reinforcement concentration for example composites.

FIG. 15 is a graph of flexural strength versus reinforcement concentration plots for example composites.

FIG. 16 is a graph of specific tensile modulus versus specific tensile strength for example composites.

FIG. 17 is a graph of effective synergistic effect versus specific tensile strengths and flexural strengths for example composites.

FIG. 18 is a graph of thermal conductivity versus reinforcement concentration for example composites.

FIG. 19 is graph of effective percent synergy versus reinforcement concentration for example composites.

FIG. 20A is a transverse (the upper one) and a longitudinal (the lower one) SEM image of a non-etched sample in concentrations of low GnP and low GF.

FIG. 20B is a transverse (the upper one) and a longitudinal (the lower one) SEM image of a non-etched sample in concentrations of low GnP and high GF.

FIG. 20C is a transverse (the upper one) and a longitudinal (the lower one) SEM image of a non-etched sample in concentrations of high GnP and low GF.

FIG. 20D is a transverse (the upper one) and a longitudinal (the lower one) SEM image of a non-etched sample in concentrations of high GnP and high GF.

FIG. 21A is a schematic diagram of the SEM image of FIG. 20A.

FIG. 21B is a schematic diagram of the SEM image of FIG. 20B.

FIG. 21C is a schematic diagram of the SEM image of FIG. 20C.

FIG. 21D is a schematic diagram of the SEM image of FIG. 20D.

FIG. 22A is an XRD pole figure for a biphasic composite.

FIG. 22B is another XRD pole figure for a hybrid composite.

FIG. 22C is a SEM micrograph of a cross-section of a biphasic composite.

FIG. 22D is a SEM micrograph of a cross-section of a hybrid composite.

FIG. 22E is a SEM micrograph of a cross-section of the biphasic composite of FIG. 22C.

FIG. 22F is a SEM micrograph of a cross-section of the hybrid composite of FIG. 22D.

FIG. 23A is a SEM micrograph of a hybrid composite including an illustration of a Voronoi tessellation.

FIG. 23B is an illustration of the Voronoi tessellation of FIG. 23A.

FIG. 24A is a graph showing the broadband electrical conductivity of biphasic composites.

FIG. 24B is a graph showing the broadband electrical conductivity of hybrid composites.

FIG. 25 is a graph showing DC electrical conductivities of the biphasic and hybrid composites.

FIG. 26A is a schematic illustrating the arrangement of glass fibers and graphene nanoplatelets in a low-GF composite.

FIG. 26B is a schematic of a Voronoi tessellation corresponding to FIG. 26A.

FIG. 27A is a schematic illustrating the arrangement of glass fibers and graphene nanoplatelets in a high-GF composite.

FIG. 27B is a schematic of a Voronoi tessellation corresponding to FIG. 27A.

FIG. 28A is a schematic illustrating current paths in a hybrid composite.

FIG. 28B is a schematic illustrating quantum tunnelling between graphene nanoplatelets.

FIG. 28C is a schematic illustrating overlapping graphene nanoplatelets.

FIG. 29A is a graph showing broadband real permittivity of example composites.

FIG. 29B is a graph showing broadband dielectric loss of example composites.

FIG. 30A is a graph showing broadband real permittivity of example composites.

FIG. 30B is a graph showing broadband dielectric loss of example composites.

FIG. 31A is a graph showing broadband real permittivity of example composites.

FIG. 31B is a graph showing broadband dielectric loss of example composites.

FIG. 32A is a graph showing real permittivity of example composites.

FIG. 32B is a graph showing dielectric loss of example composites.

FIG. 33A is a graph showing electromagnetic interference (EMI) shielding effectiveness of example composites.

FIG. 33B is another graph showing electromagnetic interference (EMI) shielding effectiveness of example composites.

FIG. 34A is another graph showing electromagnetic interference (EMI) shielding effectiveness of example composites.

FIG. 34B is a graph showing electromagnetic interference (EMI) shielding effectiveness synergy of example composites.

FIG. 35A is a graph showing thermal conductivity of example composites.

FIG. 35B is a 2D-contour showing thermal conductivity of example composites.

FIG. 36 is a graph showing thermal conductivity synergy of example composites.

FIG. 37A is a graph showing tensile modulus of example composites.

FIG. 37B is a graph showing tensile strength of example composites.

FIG. 38A is a schematic illustrating the hybrid structure of the polymer composite.

FIG. 38B is a SEM micrograph showing the hybrid structure of the polymer composite.

FIG. 39A is an FTIR spectra of example composites.

FIG. 39B is an X-ray diffractogram (XRD) for example composites

FIG. 40A is an Azimuthal intensity profile of the XRD for example composites.

FIG. 40B is a ramen spectroscopy of a graphene nanoplatelet.

FIG. 41A is a SEM micrograph and schematic of an example composite.

FIG. 41B is a SEM micrograph and schematic of an example composite.

FIG. 41C is a SEM micrograph and schematic of an example composite.

FIG. 41D is a SEM micrograph and schematic of an example composite.

FIG. 42A is a graph showing real part of permittivity for example composites.

FIG. 42B is a graph showing imaginary part of permittivity for example composites.

FIG. 43A is a graph showing fracture toughness of example composites.

FIG. 43B is a graph showing flexural modulus of example composites.

FIG. 44A is a XPS high-resolution C1s region spectra and high-resolution N1s rejection spectra for an example composite.

FIG. 44B is a XPS high-resolution C1s region spectra and high-resolution N1s rejection spectra for an example composite.

FIG. 44C is a XPS high-resolution C1s region spectra and high-resolution N1s rejection spectra for an example composite.

FIG. 44D is a XPS high-resolution C1s region spectra and high-resolution N1s rejection spectra for an example composite.

FIG. 45A is a schematic of graphene nanoplatelets.

FIG. 45B is another schematic of graphene nanoplatelets.

### DETAILED DESCRIPTION

### List of Abbreviations

The following abbreviations are used herein:

| | |
|---|---|
| f_{c} | critical frequency |
| σ | conductivity |
| σₜᵤₙ | quantum tunneling conductivity |
| rₜᵤₙ | tunnelling distance |
| R̅ | resistivity |
| N̅ | average Number of current paths |
| ε | average Permittivity |
| d̅ | average polymer gap width |
| CPC | conductive polymer composites |
| FTIR | Fourier-Transform Infrared |
| FWHM | full-width at half-maximum |
| GF | glass fibers |
| GnP | graphene nanoplatelets |
| MFI | melt flow index |
| PP | polypropylene |
| SEM | scanning electron microscope |
| UV | ultraviolet |
| vol % | percent composition by volume |
| wt % | percent composition by weight |
| XPS | X-ray photoelectron spectroscopy |
| XRD | X-ray diffraction |

### Definitions

“About” herein refers to a range of +/−20% of the numerical value that follows. In one embodiment, the term “about” refers to a range of +/−10% of the numerical value that follows. In one embodiment, the term “about” refers to a range of +/−5% of the numerical value that follows.

“Bulk density”, “apparent density” and “volumetric density” are used interchangeably herein to refer to the weight of a volume unit of a divided substance such as powders and granules. Bulk density is calculated as the weight of a full container divided by the container volume.

“Composite” herein refers to a substance comprising two or more constituents.

“Filler” herein refers to any substance that is combined with a polymer to form a polymer composite. Fillers may be selected to improve properties of the composite such as tensile strength, flexural modulus, heat resistance, color, clarity, etc. There are two primary groups of fillers: particulates and fibers. In specific examples described herein, “filler” is used to describe glass fiber and graphene nanoplatelets.

“Flexural modulus” herein refers to the ability of a material to resist bending. Flexural modulus is measured as the ratio of stress to strain during flexural deformation.

“Graphene nanoplatelets” (or “GnP”) herein refers to a nanoparticle comprising planar sheets of graphene stacked on top of one another. GnPs typically have a thickness of 1-25 nm and range in width from 0.5 to 50 μm.

“Glass fiber” (or “GF”) herein refers to a substance comprising fine fibers of glass.

“Hybrid composite” herein refers to a polymer composite comprising two or more fillers.

“Inorganic filler” herein refers to any non-hydrocarbon that is combined with a polymer to form a polymer composite.

“Kᵤ band” herein refers to a range of frequencies in the electromagnetic spectrum used for long-range communications. Kᵤ band ranges from 12 to 18 GHz and is commonly used for satellite communications, broadcast television, aircraft communication, and maritime communications.

“Melt flow rate” herein refers to the ease of flow of the melt of a thermoplastic polymer. To calculate the melt flow rate, the polymer is made fluid by heating and forced to flow out of a cylinder through a capillary die under standard conditions. Melt flow rate is useful for comparing batches of the same material or to estimate flow properties of different materials.

“Polymer” herein refers to any macromolecule formed from repeating subunits known as monomers. When a macromolecule comprises two or more different types of monomers, it is known as a “copolymer”. When a macromolecule comprises a single type of monomer, it is known as a “homopolymer”.

“Polypropylene” (or “PP”) herein refers to a polymer formed from the monomer propene (also known as “propylene”) and having the general chemical formula (C₃H₆)ₙ.

“Specific gravity” and “relative density” are used interchangeably herein to refer to the density of a material relative to the density of water.

“Silanized” herein refers to a glass surface that has been treated with a silane agent resulting in a silane monolayer. During silanization, the hydroxyl groups on the surface of the silica are replaced by silyl groups.

“Tensile strength” herein refers to the maximum stress that a material can withstand while being stretched or pulled before breaking. Tensile strength is measured as force per unit area.

### Polymer Composite

Disclosed herein is a polymer composite that includes a polymer matrix, an inorganic filler, and graphene nanoplatelets (GnPs).

The polymer composite may further include one or more additives including but not limited to water, surfactant, dispersants, anti-foam agents, antioxidants, thermal stabilizers, light or UV stabilizers, light or UV absorbing additives, microwave absorbing additives, reinforcing fibers, conductive fibers or particles, lubricants, process aids, fire retardants, anti-blocking additives, crystallization or nucleation agents, and a combination thereof.

In the examples described herein, the polymer matrix is generally described as polypropylene, however other suitable polymers are contemplated including but not limited to polyethylene, polyamide, polyester, styrene acrylic, vinyl-acrylic, polyvinyl alcohol, polyolefins, polyurethane, polyvinylchloride, polystyrene, epoxy resin, phenoxy, vinyl ester, acrylate, polycarbonate, polyacetal, polybutylene terephthalate, acrylonitrile butadiene styrene, polyphenylene sulfide, polylactic acid, polyhydroxyalkanoates, polybutylene adipate terephthalate, polyoxymethylene, polyethylene terephthalate, poly(methyl methacrylate), thermoplastic elastomers, and combinations including blends, copolymers, and terpolymers thereof.

In examples, where the polymer matrix comprises polypropylene, the polypropylene (PP) comprises a homopolymer or a copolymer. The polypropylene may have a melt flow rate of about 4 to about 70 g/10 min. In specific embodiments, the polypropylene has a melt flow rate of 30±2 g/10 min to 70±2 g/10 min and advantageously 50±2 g/10 min to 70±2 g/10 min.

In its granular form, the polypropylene may have a specific gravity between 0.895 g/cm³ and 0.94 g/cm³. In specific embodiments, the polypropylene has a specific gravity between 0.90 g/cm³ and 0.91 g/cm³ and advantageously 0.902±0.04 g/cm³.

A non-limiting example of the polypropylene is HIVAL® 2435 Neat PP, with a melt flow rate of 35±2 g/10 min (230° C./2.16 kg) and a specific gravity of 0.902±0.04 g/cm³ produced by Nexeo Plastics® (Texas, United States).

The inorganic filler comprises a particulate or fiber suitable for compounding with the polymer matrix. In the examples described herein, the inorganic filler comprises glass fibers, however other suitable fillers are contemplated including but not limited to glass beads, carbon fibers, Wollastonite, calcium carbonate, silica, clay, kaeolin, magnesium hydroxide, carbon, and combinations thereof.

Generally, the glass fibers have an average length between 1±0.05 mm and 20±1 mm. In specific embodiments, the glass fibers have an average length between 5±0.25 mm and 15±0.75 mm, advantageously between 8±0.4 mm and 12±0.6 mm, and more advantageously 12±0.6 mm.

Generally, the glass fibers have an average diameter between 4±0.2 μm. and 34±1.7 μm. In specific embodiments, the glass fibers have an average diameter between 10±0.5 μm to 20±1 μm, advantageously between 12±0.6 μm and 16±0.8 μm, and more advantageously 14±0.7 μm.

Silane groups may coat the outer surface of the glass fibers. The glass fibers may be pre-treated with a silane agent such that at least one silane group is covalently bonded to the surface of at least one of the glass fibers. Typically, silane agents bind to a hydroxyl group on the outer surface of a glass fiber. Silane groups may include Si—O—Si, Si—OCH₃, NH₂-silane, or Si—OR, but the silane groups are not particularly limited. Generally, the binding of the silane groups to the glass fibers functionalizes the glass fibers, increasing the affinity of the glass fibers to the GnPs. Glass fibers that are pre-treated with a silane agent may be referred to herein as “silanized” glass fibers.

The graphene nanoplatelets (GnPs) include an average of between about 1 to about 100 layers. In specific embodiments, the GnPs have an average of between about 6 to about 10 layers. In further embodiments, the GnPs have an average of at least 11 layers. It should be understood that the number of layers in the GnPs may increase or decrease due to dispersion and aggregation when combined with the polymer matrix and glass fibers according to methods described herein. Generally, the GnPs are sized to enhance dispersion and surface area in the polymer composite, which in turn improves physical properties.

The GnPs may have a bulk density of about 0.02±0.001 g/cm³ to about 0.4±0.02 g/cm³. In specific embodiments, the GnPs have a bulk density of about 0.1±0.005 g/cm³ to about 0.2±0.01 g/cm³ and advantageously about 0.18±0.9 g/cm³. In further specific embodiments, the GnPs comprise less than 10% oxygen, and advantageously less than 5% oxygen. In contrast to graphene oxide, which typically comprises 20% to 30% oxygen, GnPs enhance the thermal and electrical conductivity and mechanical properties of composites.

In a non-limiting example, the GnPs comprise GrapheneBlack™ 3X (NanoXplore Inc., Quebec, Canada). GrapheneBlack™ 3X has an agglomerate flake diameter of 10 to 70 and preferably, average of 38 μm, with approximately 6-10 layers, a bulk density of 0.18 g/cm³, and comprising less than 1 wt. % oxygen.

Generally, the glass fibers comprise between about 10% and about 60% by weight of the polymer composite. In specific non-limiting embodiments, the glass fibers comprise at least 20% by weight of the polymer composite. In a preferred embodiment, the glass fibers comprise between 20±1% and 50±2.5% by weight of the polymer composite, advantageously between 40±2% and 50±2.5% by weight of the polymer composite, and more advantageously 40±2% by weight of the polymer composite.

Generally, the GnPs comprise between 0.1±0.001% and 5±0.5% by weight of the polymer composite. In a preferred embodiment, the GnPs comprise between 0.25±0.01% and 1±0.2% by weight of the polymer composite, and advantageously 0.5±0.025% by weight of the polymer composite.

Herein, the compositions of various embodiments will be denoted by indicating the polymer matrix, the amount of glass nanoplatelets by weight or volume, and the amount of glass fiber (GF) by weight or volume. It should be understood that the remainder of the weight or volume, although not specified, comprises the polymer matrix.

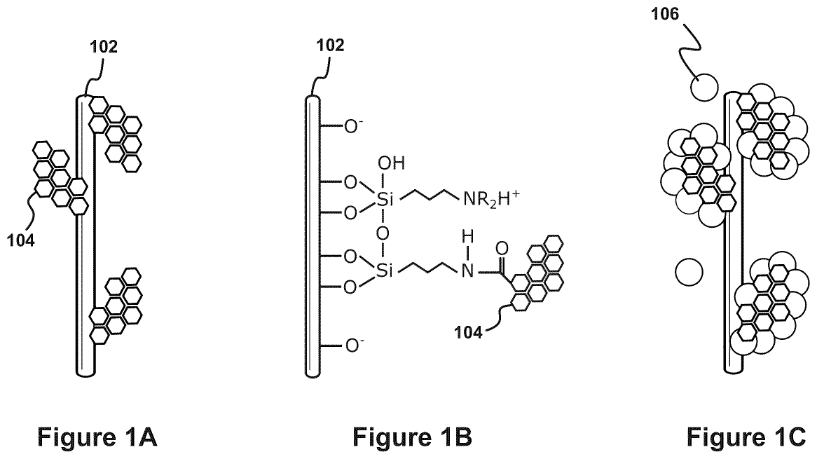

When the glass fibers are combined with the GnPs, the graphene may coat the glass fibers, as represented in FIG. 1A. FIG. 1A is a schematic diagram showing a plurality of GnPs 104 coating a glass fiber 102. The GnPs may coat the glass fibers via chemically bonding, electrostatic adherence, or a combination thereof. A mechanism by which the GnPs may chemically bind the glass fiber is shown in FIG. 1B. FIG. 1B is a schematic diagram illustrating a chemical bond formed between the GnP 104 and an aminosilane group on the surface of the glass fiber 102, according to one non-limiting example. After crystallization, spherulitic crystals 106 of polypropylene form around the GnP 104. FIG. 1C is a schematic diagram showing the binding of spherulitic crystals to the GnP 104, according to one non-limiting example.

The glass fiber may bind to any suitable number of GnPs. In some examples, the GnPs form a coating on the surface of the glass fibers. In some examples, the GnPs encapsulate the glass fibers. The binding may be triggered when the glass fibers and GnPs are contacted under the high shear force imposed by the injection molding process.

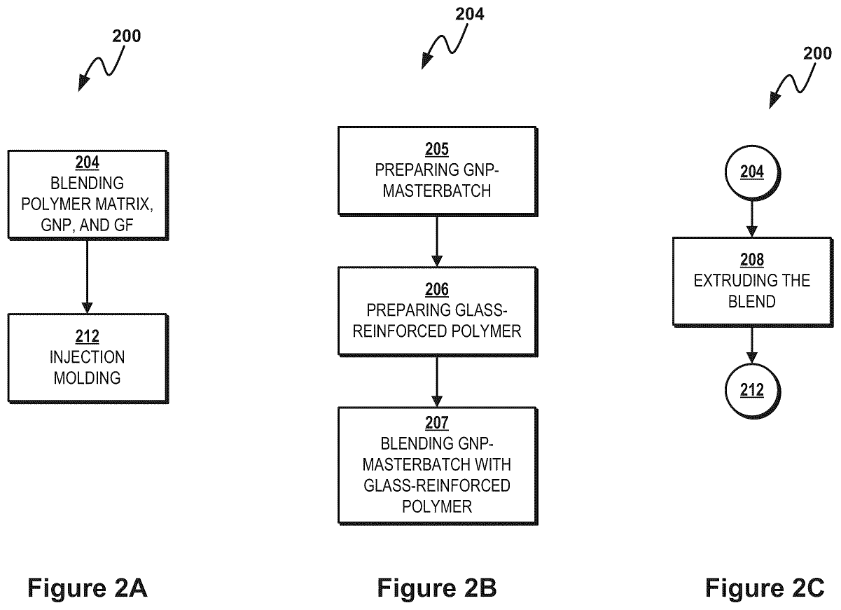

FIG. 2A shows a method 200 of preparing the polymer composite according to an example embodiment.

At block 204, the polymer matrix, glass fibers, and GnPs are blended together. A variety of blending of blending techniques are contemplated, including but not limited to dry blending and melt mixing. In preferred embodiments, the blending at block 204 is a melt mixing technique.

In some examples, the polypropylene, glass fiber, and GnPs are blended in a single blending step, however the method 200 is not particularly limited, and in other examples, the blending occurs in multiple stages. The order of blending the constituents is not particularly limited. In examples where the blending occurs in multiple stages, each blending stage comprise the same or different blending techniques.

In one embodiment, the GnPs are blended with the polymer matrix to form a polypropylene-graphene-nanoplatelet (PP-GnP) masterbatch which is subsequently blended with the glass fibers. In other embodiments, the glass fibers are blended with the polymer matrix to form a glass-reinforced polymer which is subsequently blended with the GnP. In further embodiments, the PP-GNP masterbatch is blended with the glass-reinforced polymer matrix. Additional polymer matrix may then be added to achieve the desired concentration of glass fiber and GnPs.

A specific non-limiting embodiment of block 204 is shown in FIG. 2B. FIG. 2B is a flowchart depicting exemplary performance of block 204 from FIG. 2A.

Block 205 comprises preparing a GnP-masterbatch. Block 205 may be performed by wet mixing or dry blending the GnPs with the polymer matrix. Suitable GnP-masterbatches may be commercially available, for example from NanoXplore Inc. (Quebec, Canada).

Block 206 comprises preparing a glass-reinforced polymer. Block 206 may be performed by wet mixing or melt mixing the glass fiber with the polymer matrix. Suitable glass-reinforced polymers may be commercially available. Non-limiting examples of a glass-reinforced PP include KompoGTe® LE1G60 and LE1G40 produced by Kolon Plastics (Gimcheon, South Korea) and Celstran® PP-GF60-02 Natural, produced by Celanese Corporation (Texas, United States). KompoGTe® LE1 G60 comprises 60 wt. % of E-glass fibers with a specific gravity of 1.42 g/cm³. KompoGTe® LE1 G40 comprises 40 wt. % of E-glass fibers with a specific gravity of 1.18 g/cm³. Celstran® PP-GF60-02 Natural comprises 60 wt. % of E-glass fibers having an average length of 10 mm and an average diameter of 14 μm, with an overall masterbatch density of 1.43 g/cm³.

Although FIG. 2B shows that block 205 is performed before block 206, blocks 205 and 206 may be performed in any order.

At block 207, the GF-reinforced PP mixture is blended with the GnPs. As part of block 207, additional polymer matrix may be added to achieve a desired concentration of glass fiber and GnPs.

As shown at block 208 in FIG. 2C, the blend obtained at block 204 may be extruded. FIG. 2C is a flowchart depicting exemplary performance of method 200. At block 208, the blend comprising the polymer matrix, the glass fiber, and the GnPs is extruded. Block 208 is performed by an extruder. A non-limiting example of an extruder is a Leistritz® twin-screw extruder (27 mm, L/D: 40)(Leistritz, Nuremberg, Germany). The melt extrusion temperature may be selected according to the polymer matrix. Generally, the melt extrusion temperature is between 100±5° C. to 350±18° C. In a specific embodiment, the extrusion process is conducted at 45±2 RPM with a temperature profile of 140±7° C. to 190±10° C. Returning to FIG. 2A, block 212 comprises injection molding and is performed by an injection molding machine. Block 212 may be performed on the blend obtained at block 204 using an injection molding machine that both heats and mixes the blend. In embodiments where the blend is extruded, block 212 is performed on the extrusion obtained at block 208. A non-limiting example of an injection molding machine is a 50-ton Arburg Allrounder™ 270/3200 injection molding machine (Lossburg, Germany) with a 30 mm diameter screw. In certain other non-limiting examples, the injection molding machine is equipped with MuCell® Technology (Trexel Inc., Woburn, Massachusetts).

The mold temperature may be selected according to the polymer matrix. Generally, the mold temperature is between 40±2° C. and 180±9° C. In a specific embodiment, the injection is conducted at a mold temperature of 80±4° C. In another specific embodiment, the injection is conducted at a mold temperature of 65±4° C.

Reducing the mold temperature may decrease the molding processing cycle time. In one non-limiting example, the mold temperature is 80° C. and the injection molding processing time is 123 seconds. In another non-limiting example, the mold temperature is 65° C. and the injection molding processing time is 93 seconds. While the shorter processing cycle may sacrifice crystallization degree in the small articles, for a large article (such as a battery encasement), the cooling time is sufficiently high to allow appropriate crystallization to happen and to improve the properties of the final article. As such, reducing the mold temperature can decrease the overall time and cost of manufacturing an article.

The mold may be shaped to form pellets comprising the polymer composite or to form an article. In examples where the mold is shaped to form pellets, the pellets may be sized and shaped to be used in subsequent injection molding to form an article. In examples where the mold is shaped to an article, the article is not particularly limited. Examples articles include but are not limited to automotive parts, aerospace parts, packaging, construction materials, and electronics. In specific examples, mold is shaped to form a component for a vehicle such as an automotive vehicle or an aerospace vehicle. In particular examples, the mold is shaped to form an encasement for a battery.

Articles formed from the polymer composite exhibit improved thermal conductivity, flexural strength, tensile strength, stiffness-to-weight ratios, and strength-to-weight ratios. Thus, vehicles assembled with articles comprising the polymer composite operate with improved fuel efficiency.

In view of the above, it will now be apparent that variant, combinations, and subsets of the foregoing embodiments are contemplated. As described herein, particular embodiments of the polymer composite further provide electromagnetic interference (EMI) shielding.

In embodiments that provide EMI shielding, the polymer composite comprises between 10±2% and 30±6% by weight of the composite of glass fibers and between 1±0.2% to 3±0.6% by weight of the composite of GnPs. In some embodiments, the glass fibers comprises 12% to 28% by weight of the composite. In further embodiments, the glass fiber comprises about 20 to 26% and advantageously 25±1% by weight of the composite. In some embodiments, the GnP comprises about 1.4% to 2.8% by weight of the composite and advantageously 1.8±0.4% by weight of the composite. In a particular non-limiting embodiment, the GnP comprises 1.8±0.4% by weight (10±2% by volume) of the composite and the glass fibers comprise 25±1% by weight (10±2% by volume) of the composite.

Glass fibers advantageously contribute to both the tensile strength and the EMI shielding of the polymer composite, however glass fibers are considerably heavier than either polymers or GnPs, and thus disadvantageously contribute to the weight of the polymer composite. Particularly for vehicle applications, it is advantageous to minimize the glass fiber content of the polymer composite. Furthermore, there is an upper limit to the EMI shielding contributions of glass fibers. Composites comprising more than about 26 wt % GF may exhibit decreased EMI shielding as compared to composites comprising less than or equal to 26 wt % glass fiber.

The size and quantity of the GnPs may be selected to optimize cost, conductivity, and physical properties. Smaller GnPs improve dispersion and surface area, however there is a trade-off with cost. Furthermore, overlapping GnPs form current pathways in the polymer composite, which improve the thermal and electrical conductivity. While higher contents of GnPs advantageously increase the tensile strength and EMI shielding of the polymer composite, GnPs are typically more expensive than glass fiber or the polymer matrix. Furthermore, there is an upper limit to the EMI shielding contributions of GnPs. Composites comprising more than about 10 wt % GnP may not demonstrate EMI shielding that is any more effective than a composite comprising about 10 wt % GnP.

The polymer composite may exhibit Kᵤ-band EMI shielding effectiveness of at least about 19 dB to about 24 dB. In particular non-limiting examples, the polymer composite exhibits Ku-band EMI shielding effectiveness of at least about 20 dB.

The polymer composite may exhibit a thermal conductivity of about 0.84 W/m·K to about 1.24 W/m·K. In particular non-limiting examples, the polymer composite exhibits a thermal conductivity of about 1.09 W/m·K.

The polymer composite may exhibit a tensile strength of about 60 to about 85 MPa. In particular non-limiting examples, the polymer composite exhibits a tensile strength of about 80 MPa.

The polymer composite may exhibit a tensile modulus of about 7 GPa to about 10 GPa. In particular non-limiting examples, the polymer composite exhibits a tensile modulus of about 9.4 GPa.

The polymer composite may have a density of about 0.92 g/cm³ to about 1.02 g/cm³. In specific non-limiting examples, the polymer composite has a density of about 0.99±0.1 g/cm³. In further non-limiting examples, the polymer composite has a density of about 1.0±0.1 g/cm³.

EMI shielding provided by the polymer composite can prevent malfunction or miscommunication between various electric devices.

In specific non-limiting embodiments, the polymer composite is molded into a coating for a conductor. The conductor can include, but is not limited to, a fiber optic cable, a communications cable, a power cable, a power charger, a computer data cord, a power cord, wiring (including wiring for home interiors, devices, appliances or electric vehicles), a consumer electronic accessory cord, and any combination thereof.

In specific non-limiting embodiments, the polymer composite is molded into an enclosure for an electric component. The electric component may include a battery or battery management system, an electric motor, an inverter, an ignition system, an LED light, a wireless charging device, a sensor (such as radar, light detection and ranging (LIDAR), an ultrasonic sensor, an infrared sensor, a camera, or a temperature sensor), electronic controls for an HVAC (heating, ventilation, and air conditioning) system, a keyless entry system, a global positioning system (GPS), an analog or digital instruments panel on a vehicle, a communications system (such as Bluetooth™, Wi-Fi, or cellular), an electronic control system, a radio, a computer display, a multi-media device, and any combination thereof.

The GnPs provide advantages over composites of the prior art. In contrast to composites comprising graphene oxide, the composite described herein demonstrates improved electrical and thermal conductivity and mechanical properties due to the reduced oxygen content of the GnPs. Furthermore, the dimensions and quantity of the GnP is selected to improve dispersion while maintaining the overlap between GnPs that give rise to current pathways.

Thus, the present disclosure provides a polymer composite that is both lightweight and effectively shields electric devices from EMI. Due to the reduced weight of the polymer composite, the polymer composite provides significant environmental benefits as compared with EMI shielding materials of the prior art. Lighter vehicles require less energy to accelerate, improving fuel efficiency or extending the life of the battery. In hybrid and electric vehicles that include a regenerative braking system, lighter vehicles can recover more kinetic energy through braking. Moreover, lighter vehicles place less strain on roads and other vehicular infrastructure, reducing maintenance costs and energy required for road construction and repair.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

The polymer composite will now be described with respect to the examples herein.

### Example 1

### 1.1 Materials and Methods

### 1.1.1 Materials and Sample Preparation

A commercially available polypropylene (PP) homopolymer, HIVAL® 2435, with a melt flow rate of 35 g/10 min (230° C./2.16 kg) and a specific gravity of 0.902 g/cm³ produced by Nexeo Plastics® (Texas, United States) was used as the polymer matrix. The glass-filled polypropylene masterbatch, with commercial name Celstran® PP-GF60-02 Natural, produced by Celanese Corporation (Texas, United States), was filled with 60 wt. % of E-glass fibers sized with a proprietary formula of aminosilane, having an average length of 10 mm and an average diameter of 14 μm, with an overall masterbatch density of 1.43 g/cm³. The graphene nanoplatelets (GnPs), with commercial name GrapheneBlack™ 3X, was provided by NanoXplore Inc. (Quebec, Canada), having an average flake diameter of 38 μm, with approximately 6-10 layers, and a bulk density of 0.18 g/cm³.

The PP-GF composites with various GF concentrations were prepared by diluting the as-received Celstran® PP-GF60-02 Natural masterbatch with the as-received HIVAL® 2435 Neat PP using a dry blending technique in order to avoid damage and/or breakage of the GFs. The PP-GnP composites with various GnP concentrations were prepared by melt-mixing the as-received GrapheneBlack™ 3X powder and the as-received HIVAL® 2435 Neat PP in a Leistritz® twin-screw extruder (27 mm, L/D: 40) (Nuremberg, Germany), in order to ensure thorough mixing of the nanomaterial. The extrusion process was conducted at 45 RPM with a linear temperature profile across the 10 heating zones, from 140° C. (feeding) to 190° C. (die). The hybrid composites were prepared by mixing the previously diluted blends from the biphasic composites into the desired concentrations, through the dry blending.

A 50-ton Arburg Allrounder 270/320C injection molding machine (Lossburg, Germany), with a 30 mm diameter screw equipped with MuCell® Technology (Trexel Inc., Woburn, Massachusetts) was used to fabricate the composite samples at a mold temperature of 80° C. The samples were injected into a custom dual tensile and flexural mold, designed to create ASTM D638—Type IV standard and ASTM D790 standard specimens, respectively.

The composites were designated by indicating the matrix, the amount of GnP, and the amount of GF according to this format: PPGnPζGFζ, where the ζ corresponds to the amount of reinforcing material by weight of the whole composite. For instance, the biphasic composite containing 5 wt. % GnP is labelled as PPGnP5. Similarly, the hybrid composite containing 5 wt. % GnP and 10 wt. % GF is labelled as PPGnP5GF10. Additionally, all of the prepared and fabricated samples are tabulated with respect to their reinforcement concentrations in Table 1.

TABLE 1

| | T_{c} | Tₘ | ΔT | | |
|---|---|---|---|---|---|
| Sample Name | (° C.) | (° C.) | (° C.) | (X_{c})_{DSC} | (X_{c})_{XRD} |
| Neat PP | 120 | 162 | 42 | 49 | 50 |
| PPGnP0.25 | 125 | 164 | 39 | 51 | 51 |
| PPGnP0.5 | 126 | 164 | 38 | 55 | 56 |
| PPGnP1 | 126 | 164 | 38 | 53 | 53 |
| PPGF10 | 122 | 162 | 41 | 52 | 50 |
| PPGF20 | 121 | 165 | 44 | 51 | 52 |
| PPGF30 | 121 | 165 | 44 | 51 | 52 |
| PPGF40 | 121 | 164 | 43 | 52 | 50 |
| PPGF50 | 121 | 163 | 42 | 51 | 50 |
| PPGF60 | 123 | 167 | 44 | 52 | 52 |
| PPGnP0.5GF10 | 125 | 164 | 39 | 55 | 56 |
| PPGnP0.5GF20 | 125 | 164 | 39 | 55 | 56 |
| PPGnP0.5GF30 | 125 | 164 | 39 | 55 | 55 |
| PPGnP0.5GF40 | 125 | 164 | 39 | 56 | 56 |
| PPGnP0.5GF50 | 125 | 164 | 38 | 55 | 55 |

### 1.1.2 Morphological and Crystallographic Characterization

The molecular interactions and chemical adhesion were assessed using Fourier-Transform Infrared Spectroscopy (FTIR) and X-Ray Photoelectron Spectroscopy (XPS), on the as-received sized GFs obtained from the PPGF60 masterbatch and on the fabricated hybrid composite PPGnP0.5GF40, which were both almost completely etched in boiling Xylene for 1-hour to remove the PP matrix. Additionally, the un-sized GFs were collected by placing the sized GFs in a high-temperature oven at 600° C. for 2 hours, to remove the aminosilane surface modification. The instrument used for FTIR was a Bruker Platinum-ATR (Bruker, Billerica, United States) with a spectral range of 500-4000 cm⁻¹, and the instrument used for XPS was a high-resolution Thermo Fisher Scientific™ K-Alpha (Thermo Fisher, Waltham, United States).

The electrostatic interactions between the GnP, un-sized GFs, and sized GFs were evaluated using the Brookhaven Instruments Corporation ZetaPlus™ Zeta Potential Analyzer (Brookhaven Instruments Corporation, Holtsville, New York, United States) with deionized water (pH˜7) as the common solution and red laser light source (660 nm wavelength).

The microstructure and crystalline morphologies of PP composites were investigated using a Phenom ProX™ Scanning Electron Microscope (SEM) (Thermo Fisher, Waltham, United States). The fabricated injection molded composites were cryo-fractured by immersing the samples in liquid nitrogen for approximately 1-hour. Then, select samples were partially etched in boiling Xylene for 5 minutes, to better visualize the crystalline morphology, without dissolving the entire PP matrix. Finally, the composites were sputter-coated with platinum before observation in the SEM. Additionally, an Olympus™ BX51 P Polarized Optical Microscope (POM), equipped with a Linkam™ Scientific Instruments Ltd. Hot-stage (THMSG600) and an Olympus™ U-TP530 wave plate, was used to observe the crystalline morphologies under a Nitrogen (N₂) atmosphere. Thin films of ˜50 μm were heated from room temperature to 250° C. at a rate of 10° C./min, at which they were held isothermally for 5-minutes to fully melt the PP crystals and remove all thermal history. Then, the samples were rapidly cooled at a rate of 50° C./min to 140° C., in order to minimize the formation of crystals during this cooling step and held isothermally for 10 minutes to allow the PP composites to fully crystallize. Select composites were analyzed using this temperature profile, at which images were captured every 5 seconds, to compare the nucleation densities observed with varying composite morphology. Furthermore, Image J software (National Institutes of Health, Bethesda, MD, USA) was used to quantify the crystal nucleation densities from the POM images and approximate the crystal spherulite diameters from the SEM images of etched specimens.

The crystallization kinetics of the composites were evaluated using non-isothermal Differential Scanning Calorimetry (DSC, TA Instruments DSC 250) under an inert N₂ atmosphere at atmospheric pressure. First, the samples were equilibrated at −50° C. and then heated at a rate of 10° C./min to 250° C., at which they were held isothermally for 5 minutes to remove all thermal history. The samples were then cooled back to −50° C. at a rate of 10° C./min and held isothermally for 5 minutes. This moderate cooling rate was selected to observe the effect of the reinforcing materials on the crystal growth and polymorphism independently, as a higher cooling rate can affect the crystal polymorphism of PP. Finally, the samples were heated again to 250° C. at a rate of 10° C./min. The crystallinity of the composites was calculated from the DSC thermograms using Formula 1:

$${( {𝒳}_{c} )}_{D S C} = \frac{Δ {H}_{f}}{ϕ Δ {H}_{0}} \times 100 \% \qquad Formula 1$$

In Formula 1, ΔH_{f} is the measured enthalpy of fusion of the sample, ΔH₀ is the enthalpy of fusion for perfectly (100%) crystalline PP (ΔH₀=209 J/g), and ϕ is the weight fraction of PP.

The crystalline microstructures of the composites were assessed using 1D-X-Ray Diffraction (1D-XRD). The instrument used was a D8 Davinci™ diffractometer (Bruker, Billerica, United States) with a Cobalt-sealed tube (λ=1.79026 Å) parallel beam line source (0.2 mm slit, 2.5° Soller) and an Eiger2 R 500K area detector (Dectris, Philadelphia, United States) in 1D mode (2.5° Soller, 2θ 10°, γ2θ) with a 0.02° step size and 30 min scans of 2θ from 10° to 60° in reflection mode. The crystallinity of the composites was calculated from the 1D-XRD diffractogram using Formula 2.

$${( {𝒳}_{c} )}_{X R D} = \frac{{H}_{c}}{{H}_{c} + {H}_{a}} \times 100 \% \qquad Formula 2$$

where H_{c} is the intensity of the crystalline peaks, and Hₐ is the intensity of the amorphous peaks. The β-phase fraction formed was characterized by Formula 3, according to the method of Turner-Jones et al. (A. T. Jones and J. Aizlewood, “Crystalline forms of isotactic polypropylene,” Die Makromol. Chemie, vol. 75, no. 1, pp. 134-158, 1964, doi: 10.1002/macp.1964.020750113; P. Juhász, J. Varga, K. Belina, and & G. Belina, “Efficiency of β-nucleating agents in propylene/α-olefin copolymers,” J. Macromol. Sci. Part B, vol. 41, pp. 1173-1189, 2002, doi: 10.1081/MB-120013090).

$${β}_{} = \frac{{H}_{β ( 300 )}}{{H}_{β ( 300 )} + {H}_{α ( 110 )} + {H}_{α ( 040 )} + {H}_{α ( 130 )}} \times 100 \% \qquad Formula 3$$

In Formula 3, H_{α(110)}, H_{α(040)}, H_{α(130)} are the intensities of the (110), (040), and (130) diffraction peaks of the α-form, respectively, and H_{β(300)} is the intensity of the (300) peak of the β-form.

### 1.1.3 Mechanical Properties

The specific tensile mechanical properties of Neat PP and the fabricated composites were measured in accordance with the ASTM D638 and ASTM D792 standards, using an Instron® 5965 (Instron, Norwood, United States) with a load cell of 5 kN at a crosshead speed of 5 mm/min, and a gauge length of 25 mm, as well as an analytical balance with a precision of 0.1 mg for the density measurements, all at ambient conditions, and the material densities. Prior to testing, the samples were kept at atmospheric conditions for at least 48 hours. At least five replicate samples were tested, and the average values with corresponding standard deviations were obtained.

The flexural mechanical properties of Neat PP and the fabricated composites were measured in accordance with the ASTM D790 standard, using an Instron® 5965 (Instron Norwood, Massachusetts, United States) with a load cell of 5 kN at a crosshead speed of 1.3 mm/min, and a span length of 48 mm at ambient conditions. Prior to testing, the samples were kept at atmospheric conditions for at least 48 hours. At least three replicate samples were tested, and the average values with corresponding standard deviations were obtained.

### 1.1.4 Thermal Conductive Properties

Thermal conductivity measurements for Neat PP and the fabricated composites were conducted using the transient hot disk method, according to ISO/DIS 22007-2.2. A transient plane source (TPS 2500, Therm Test Inc., Sweden) thermal constants analyzer with a Kapton sensor (C7577) was employed to measure the thermal conductivity of the samples under ambient conditions. In this method, an electrically conductive double spiral disk-shape sensor made of nickel foil is placed in between two identical samples with planar surfaces. The sensor works as both a heater and a dynamic thermometer to simultaneously increase and record the temperature variations in the samples as a function of time. The isotropic measurement module was used to measure the bulk/average thermal conductivity of the fabricated samples. Therefore, the values were calculated by measuring the dissipated heat in all directions (i.e., both in-plane and through-plane).

### 1.1.5 Synergistic Effect Evaluation

A quantitative method to evaluate the synergistic effect, or percent synergy was used to determine the improvement in the mechanical properties of a composite due to the co-supporting network within various composites. Formula 4, defined below, takes into account the varying concentration of the matrix between hybrid composites and compensates for the changing filler loadings:

$${S}_{E}^{\%} = \frac{k - ( p + q )}{( p + q )} \times 100$$

In Formula 4, k represents the magnitude of the enhancement of the hybrid composite relative to the matrix material, and p and q represent the magnitude of the enhancements of the individual reinforcing materials alone relative to the matrix material.

It is important to note, that this equation eliminates the baseline enhancement of the matrix without eliminating the enhancement due to the interaction of the fillers with the matrix material, as this is known to contribute to the synergistic effect. A positive S_{E}^{%} is indicative of a synergistic enhancement generated within the hybrid composite, while a negative S_{E}^{%} suggests a discord within the hybrid system resulting in an undesirable decrease in its properties.

### 1.2 Results and Discussion

### 1.2.1 Morphology and Interfacial Interactions

In order to understand the interfacial interactions between the glass fibers and the graphene nanoplatelets within the hybrid composites, the physical, chemical, and electrostatic interactions were investigated. (Herein, the glass fibers may be referred to as “micro-sized filler” and the graphene nanoplatelets may be referred to as “nano-sized filler”. The glass fibers and the graphene nanoplatelets may be referred to collectively as “fillers”.) The physical interactions are associated with the composite's morphology, whereby the GFs induce a volume exclusion effect. This effect physically constrains the motion of the graphene nanoplatelets within the hybrid mixture as it rapidly flows into the mold cavity, during the injection molding process. As a result, the graphene nanoplatelets inevitably accumulate and align themselves around the glass fibers. This physical interaction is more significant at the melt front, whereby the fountain effect disturbs the orientation of the fillers. Further discussion on the physical interaction involving the volume exclusion effect and correlated microstructure is elucidated in Section 2.4 (Mechanical Properties and Synergistic Effect Elucidation).

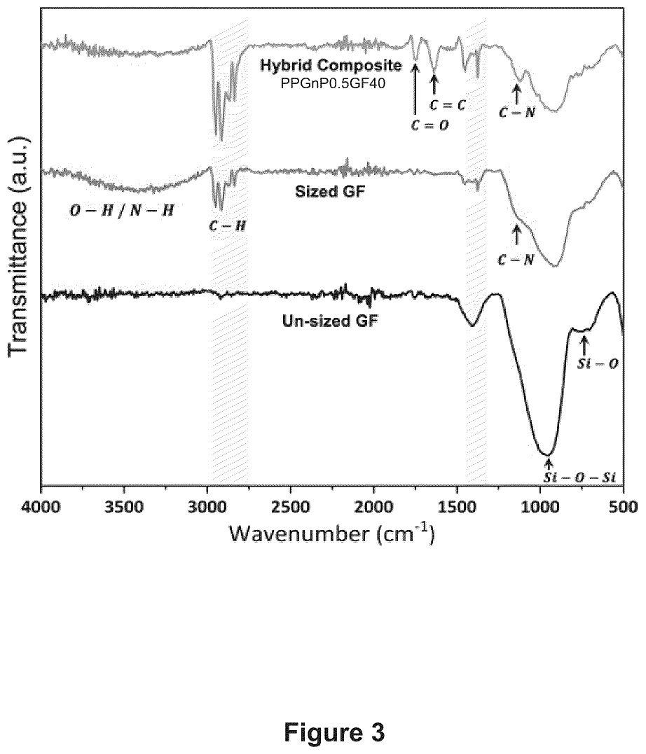

FIG. 3 shows the FTIR spectra of unsized GF, sized GF, and a hybrid composite (PPGnP0.5GF40). Note: The PP matrix in the hybrid composite PPGnP0.5GF40 was almost completely etched, to expose the proposed hierarchical reinforcement structure.

The chemical interfacial interactions relate to the chemical bonding of the GnPs onto the sized GFs (i.e., chemically modified surface with aminosilane), thereby forming a desirable reinforcement system, known as a hierarchical structure. Generally, hierarchically structured composites, that are chemically bonded (or grafted) and/or electrostatically attached, are known to provide greater mechanical properties and functionalities compared to those that only possess physical interactions. The FTIR spectra in FIG. 3, showcase the variabilities in the chemical structure of the un-sized and sized GFs, as well as the interfacial interaction of the sized GFs in the presence of GnPs within the hybrid composites. The un-sized GF spectrum illustrates the characteristic broad bands inherent to GF, with the Si—O—Si stretching peak at 1,000 cm⁻¹ and the Si—O bending peak at 730 cm⁻¹, as well as the onset of the Si—O rocking vibrations peak normally around 450 cm⁻¹. The sized GF spectrum is comprised of the same characteristic peaks as the un-sized GF, with the addition of the broad band from 3,000-3,850 cm⁻¹ inherent to amine N—H stretching and/or intermolecular O—H bonding, which are representative of the sizing. Furthermore, the peaks at 1,376, 1,456, 2,870, 2,920 and 2,950 cm⁻¹ are related to CH₂ and CH₃ bonds, and the shoulder present at 1,125 cm⁻¹ is indicative of the presence of amine C—N stretching.

The hybrid composite spectrum, represented by PPGnP0.5GF40 (almost completely etched PP), shows an increase in the CH₂ and CH₃ bond peaks, which is a result of the remaining PP matrix that is primarily composed of these chemical bonds. The emergence of the peaks at 1,760 cm⁻¹ and 1,638 cm⁻¹ correspond to the C═O stretching and C═C stretching bonds, respectively, which are associated with graphene 47,50-52. Additionally, the evolution of the peak at 1,125 cm-1 could be indicative of an increase in C—N bonding within the hybrid composites, which would suggest the formation of a chemically bonded hierarchical structure. Moreover, the reduction in the broad band from 3,000-3,850 cm-1 reveals a clear trade-off of the N—H and O—H bonding, to favor C—N bonding between the carbon atoms along the surface of the GnPs and nitrogen atoms along the surface of the sized GFs. In other words, these results imply that the increased C—N bonding can be attributed to the electrophilic carbon atoms on the GnPs that form new C—N bonds with the GF's sizing.

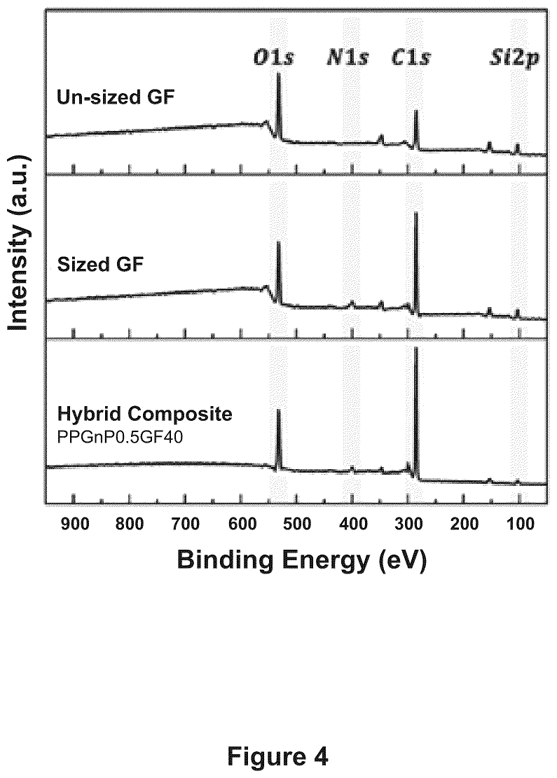

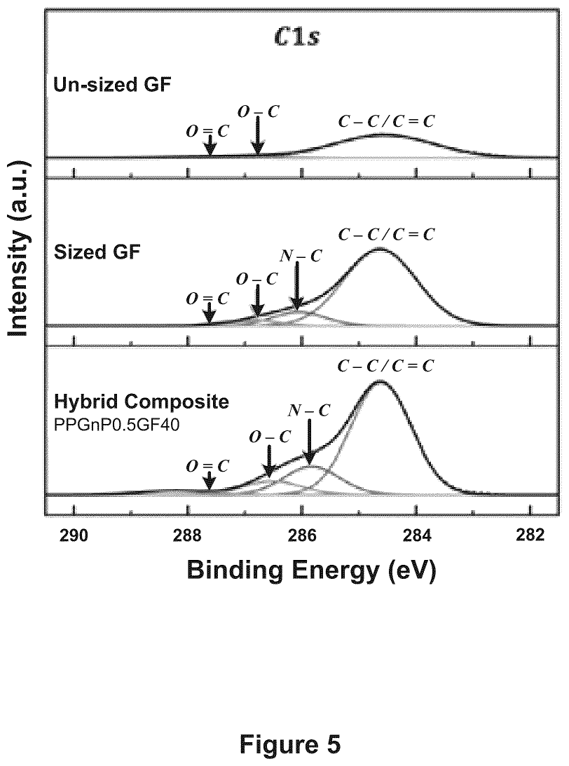

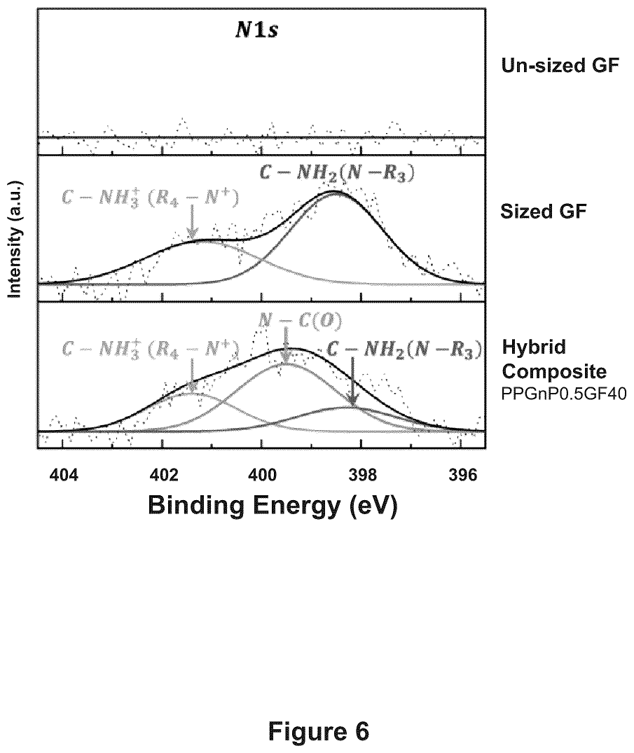

XPS was conducted to analyze the surface chemical composition of the un-sized and sized GFs, as well as to validate the FTIR results that suggest the formation of a covalently bonded hierarchical structure within the hybrid composites. Additionally, XPS was conducted on the as received GnPs. FIGS. 4 to 6 show the XPS full-spectra, high-resolution C1 s region spectra, and high-resolution N1 s region spectra, for the un-sized GF (top), sized GF (middle), and PPGnP0.5GF40 (bottom). Note: The PP matrix in the hybrid composite PPGnP0.5GF40 was almost completely etched, to expose the proposed hierarchical reinforcement structure. As shown in FIGS. 4 to 6, the XPS results for the sized GF and hybrid composite spectra, indicate a distinct N1s peak at ˜400.1 eV, while undetectable in the un-sized GF spectra, confirming the presence of amino functional groups within the sizing. The high-resolution C1 s peaks were deconvoluted into four specific peaks: C—C or C—H bonds (˜284.6 eV), C—N bonds (˜286.1 eV), C—O bonds (˜286.8 eV), and C═O bonds (˜287.7 eV). The C—N bond intensity for the hybrid composite is greater than that of the sized GF, while it is not present for the un-sized GF, directly correlating to the FTIR results.

For the sized GF, two chemical bonding peaks were deconvoluted and attributed to protonated (˜401.3 eV) amine groups in the form of N⁺—R₄ (a result of the NH2-silane groups reacting with the OH groups on the GF's surface and/or other silane molecules) and non-protonated (˜398.4 eV) amine groups in the form of N—R₃. The majority of the amino groups within the sized GF were found to be non-protonated, implying that they are free amino groups oriented away from the GF's surface and are readily available to react. For the hybrid composite, an additional bonding peak at ˜399.5 eV is evident, which is indicative of the formation of amide bonds, along with the protonated (˜401.3 eV) and remaining non-protonated (˜398.4 eV) amine groups 56,57. Simply, the emergence of the amide (N—C(O)) peak at ˜399.5 eV along with the decrease in intensity of the non-protonated amine (N—R₃/NH₂) peak at ˜398.4 eV, demonstrates that the carboxylic acid groups (R—COOH) on the GnPs' surface have reacted with the non-protonated amine groups on the sizing to produce amide bonds, thereby creating a hierarchical reinforcement structure. The driving force for this chemical reaction may be promoted during the injection molding process, whereby the hybrid mixture is subjected to high shear and extensional deformation at elevated temperatures, combined with (1) the volume exclusion effect induced by the GFs, that physically constrains the motion of the GnPs, and (2) the presence of an electrostatic affinity between the reinforcements.

The electrostatic affinity between the reinforcements was characterized using Zeta Potential measurements, highlighting the electrostatic charge of the un-sized GFs, sized GFs, and GnPs. The un-sized GFs have a negative electrostatic charge of −9 mV, the sized GFs have a positive electrostatic charge of +32 mV, induced by the aminosilane surface modification, and the GnPs have a negative electrostatic charge of −38 mV, due to the ionization of the remaining oxygen-containing functional groups on the surface of the GnPs. It is evident that the GnPs and sized GFs have opposite charges, therefore, this facilitates their assembly under electrostatic interactions, creating a hierarchical interface.

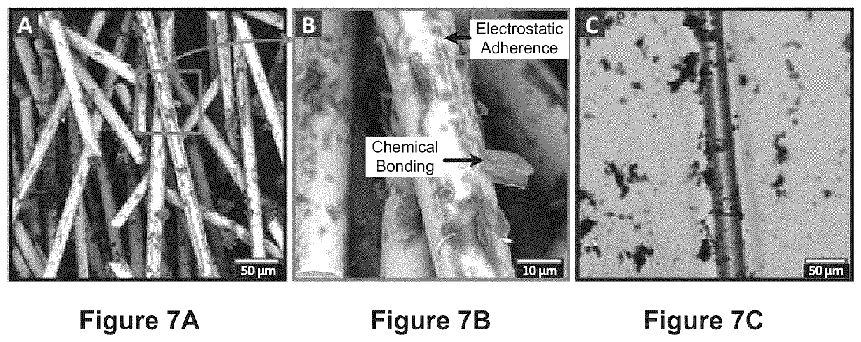

FIGS. 7A and 7B are SEM images of the chemical bonding and electrostatic adhesion of the GnPs onto the sized GFs. FIG. 7C is a POM image highlighting the hierarchical reinforcement structure in the hybrid composite.

The hierarchical reinforcement system is illustrated in the SEM images of FIGS. 7A and 7B and previously shown in the schematic of FIGS. 1A to 1C, whereby the GnPs are shown to coat the GFs, emphasizing the combined effect of electrostatic adherence and chemical bonding. Further proving the effects of these mechanisms, the POM image for the hybrid composite of FIG. 7C showcases a similar pattern, whereby the majority of the GnPs are encapsulating the GFs, with minimal GnPs dispersed in the bulk of the matrix. As a result, these images provide sufficient evidence to support the presence of interfacial interactions and the mechanisms for the successful formation of a hierarchical hybrid composite system. The following sections will overview the structure-property relations of these hybrid composites, with a focus on how varying concentrations of the reinforcements affects the crystalline morphology, in order to optimize the synergistic effect and bulk properties.

### 1.2.2 Crystalline Microstructure and Crystallization Behavior

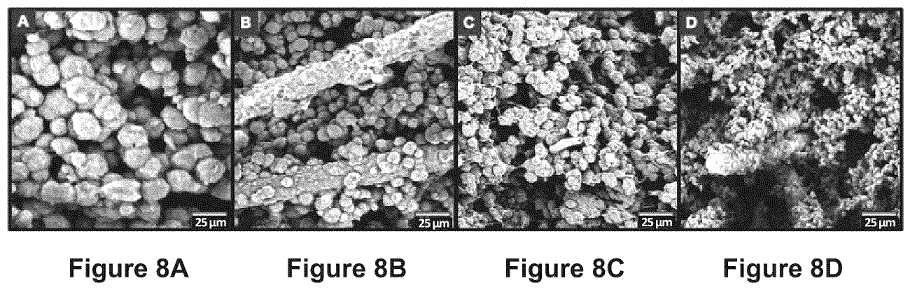

FIGS. 8A to 8D are SEM images for the core region of Neat PP (FIG. 8A), PPGF10 (FIG. 8B), PPGnP0.5 (FIG. 8C), and PPGnP0.5GF10 (FIG. 8D).

The SEM images for select etched composites, illustrated in FIGS. 8A to 8D, provide insights into the varying crystalline morphology. The etched amorphous regions in FIG. 8A, display the spherulitic crystal growth of Neat PP, whereby the average crystal diameter is ˜17 μm. For PPGF10, shown in FIG. 8B, the average crystal diameter is 10 μm. These smaller crystals are a result of the increased nucleation density (2.60·10¹⁰ nuclei/cm²), leading to an ˜48% increase relative to Neat PP (1.76·10¹⁰ nuclei/cm²). Similarly, for PPGnP0.5, shown in FIG. 8C, the average crystal diameter is ˜8 μm due to the increased nucleation density (4.08·10¹⁰ nuclei/cm²) resulting in an ˜132% increase relative to Neat PP. The hybrid composite PPGnP0.5GF10, shown in FIG. 8D, contains the smallest average crystal diameter of ˜3 μm, owing to the highest nucleation density (5.46·10¹⁰ nuclei/cm²) which is ˜210% greater than Neat PP.

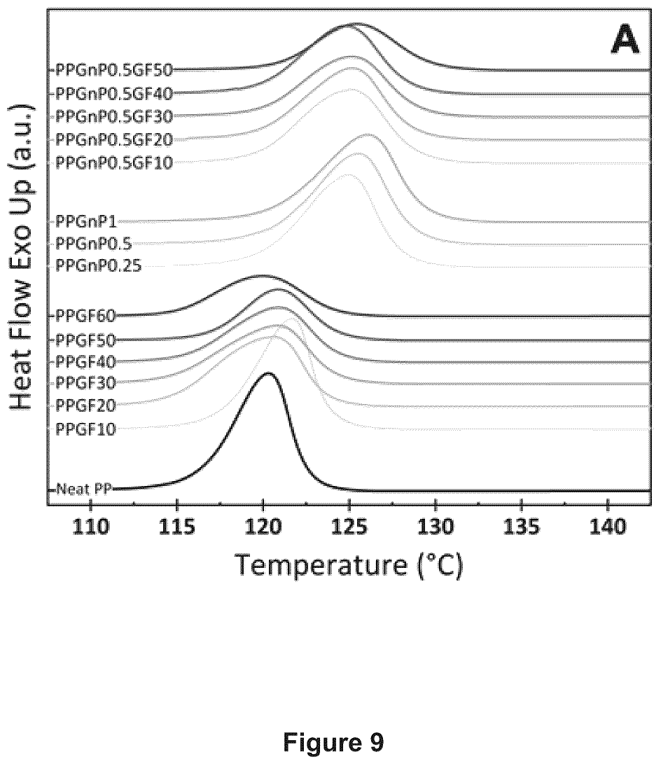

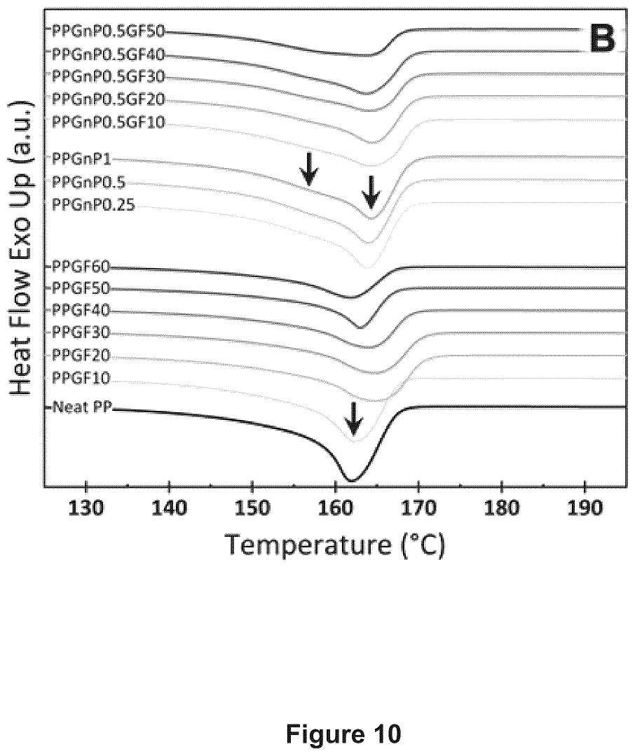

FIGS. 9 and 10 are thermograms for crystallization (FIG. 9) and second heating (FIG. 10) for select fabricated composites, highlighting the bimodal crystallization behavior for the samples containing GnPs. For the biphasic composites reinforced with GnP, the crystallization temperature (T_{c}) increased with increasing amounts of filler, indicating that the crystallization of PP was accelerated in the presence of GnPs. An increase in T_{c} corresponds to a decrease in the degree of super-cooling (ΔT=Tₘ−T_{c}), whereby the degree of super-cooling is proportional to the free energy of melting. Since the free energy of melting is associated with the driving force for nucleation, a decrease in the degree of super-cooling implies that crystallization was achieved at a lower driving force, as GnPs act as seeds for heterogeneous nucleation. Furthermore, the crystallinity increased from 49% (Neat PP) to a maximum of 55% for the PPGnP0.5 composite, shown previously in Table 1. The crystallization thermograms are indicative of unimodal curves, while the second melting thermograms display a bimodal pattern, whereby the greatest shoulder is seen for PPGnP0.5.

On the contrary, for the biphasic composites reinforced with GF, the T_{c} was not affected with increasing concentration of GF. The invariable T_{c} demonstrates that the presence of GF does not lower the driving force for nucleation, as the inferior aspect ratio, when compared to GnP, results in less preferred sites for heterogeneous nucleation.

The DSC thermograms for the hybrid composites, show that they inherit the crystallization behavior of the biphasic GnP composites of the same concentration. Specifically, T_{c} increased with increasing concentration of GnP regardless of GF concentration, further proving that GnP is the dominating factor affecting the crystallization behavior. Moreover, a similar trend is observed for the (χ_{c})_{DSC}, in which the hybrid composites inherited the crystallinity of the biphasic GnP composites with the same concentration, whereby the maximum (χ_{c})_{DSC} of ˜55% was observed with 0.5 wt. % GnP for all concentrations of GF. While the crystallization thermograms show a unimodal pattern, the second melting thermograms display bimodal curves, similar to what was observed in the GnP biphasic composites. However, for the hybrid composites with constant GnP content, increasing the concentration of GF makes the bimodal pattern less prominent. Since these bimodal curves can be indicative of the existence of crystals other than the most common α-form, XRD was conducted to elucidate the crystalline microstructure inherent to these composites.

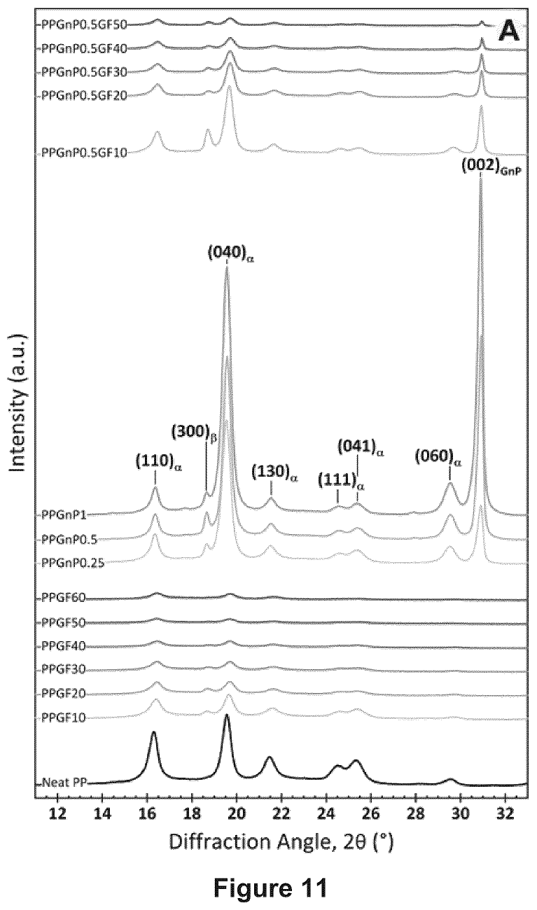

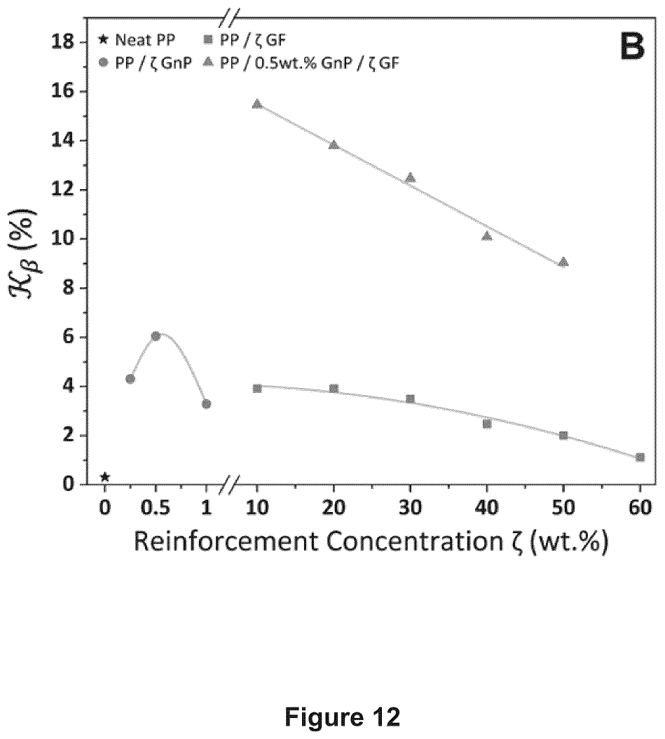

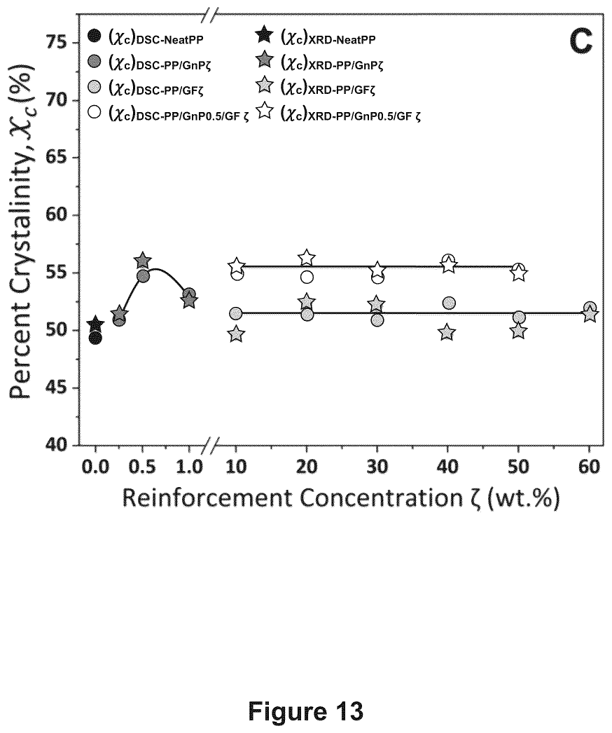

FIG. 11 shows XRD diffractograms for select fabricated composites. FIG. 12 shows Cp as a function of reinforcement concentration. FIG. 13 shows χ_{c} as a function of reinforcement concentration, for select fabricated composites. Note that the trendlines are only present to guide the reader.

The XRD scattering patterns for the biphasic and hybrid composites, shown in FIG. 11, emphasize the efficacy of the different reinforcements to alter the crystalline microstructure of Neat PP. Specifically, the presence of the (300)_{β} crystallographic plane is indicative of β-crystals in the crystalline microstructure. Since the melting temperature of β-crystals is approximately 10.9° C. lower than α-crystals, the presence of these crystals explains the shoulder observed on the DSC melting peaks in FIG. 9. Generally, β-crystals provide excellent mechanical properties, such as toughness, tensile strength, elongation at break, and impact strength, compared to α-crystals and can be induced by different processing conditions through: shear-induced crystallization, directional crystallization in a temperature gradient field, vibration-induced crystallization, and the addition of specific nucleating agents.

During a conventional injection molding process with a room temperature mold, the polymer melt experiences high shear stresses near the mold cavity walls. Hence, shear-induced crystallization and directional crystallization in a temperature gradient field, from the skin to the core region of the mold, are the conditions favoring β-phase formation for the samples containing GF. However, a mold with an elevated temperature of 80° C. was used in this study. Therefore, the effect of the temperature gradient field is relatively less pronounced, suggesting that shear-induced β-phase crystallization is the dominant mechanism. As a result, the β-phase can be initiated by growth transformations along the oriented α-phase front. The total fraction of β-phase formed within these composites is highlighted using the semi-quantitative [symbol] _{β} method, as shown in in FIG. 12. For the biphasic GF composites, with <30 wt. % GF, [symbol] _{β} was constant at ˜4%, while the composites with >30 wt. % GF decreased with increasing concentration. Since the GFs used in these examples are estimated to have a thermal conductivity of 1.3 W/m×K, which is approximately 6 times higher than that of the Neat PP matrix (see Section 2.4), the thermal conductivity of the composite would be enhanced as the concentration of GF increases. Therefore, the heat of the composite will be dissipated at a higher rate, so that the polymer melt experiences a lower temperature during crystallization within the mold cavity. This effect could lead to a shift of T_{c} to domains below the lower critical temperature for the formation of the β-phase (Tap), at which the α-phase growth rate is dominant. Moreover, secondary crystallization occurs when the polymer melt is cooled below Tap, which is attributed to the α-phase growing on the β-phase during cooling, as α- and β-crystals are based on the same helix geometry. These effects explain why [symbol] _{β} steadily decreases, as the concentration of GF increases, beyond 30 wt. % GF. This decreasing trend of κ_{β}, from ˜16% to ˜9%, is more significant for the hybrid composites. This can be attributed to the significantly higher thermal conductivity of the GnPs, resulting in a further shift of T_{c}.

Additionally, for the biphasic GnP composites, the presence of β-crystals is enhanced due to the addition of GnPs which act as β-nucleating agents. The optimum formation of [symbol] _{β} was found in PPGnP0.5, where it reached a maximum of 6%. The dispersion and distribution of the GnPs is reduced within polymer composites containing >0.5 wt. % GnP, as they form agglomerates due to the strong π-π interactions and van der Waals forces. As such, the agglomerates reduce the heterogeneous nucleation efficiency of the GnPs. Also, it is important to note that the (χ_{c})_{DSC} and (χ_{c})_{XRD} are in strong accordance with each other, emphasizing the reliability of the experiments and characterization processes.

The XRD diffractograms for the hybrid composites depict the variations in crystalline microstructures, with different reinforcement concentrations. The intensity of the GnP crystallographic plane (002)_{GNP}, is suppressed with the introduction of GF, implying that the volume exclusion effect imparted by the GFs, provides a mechanism for a more effective dispersion and distribution of the GnPs, compared to their biphasic counterparts. A maximum [symbol] _{β} of ˜16% was found in PPGnP0.5GF10, which is greater than the additive sum ( [symbol] _{β}=˜10%) of PPGnP0.5 and PPGF10, demonstrating a clear synergistic effect. Therefore, the tailored crystalline microstructure that promotes the formation of β-crystals is a result of the heightened dispersion and distribution of the GnPs, induced by the volume exclusion effect. However, [symbol] _{β} decreases with increasing concentration of GF, suggesting that the reduced volume of crystallizable material allows for the rigid body motion of the GnPs to constrain the movement and alignment of the PP chains more effectively, thus limiting the further formation of β-crystals. Another hypothesis is that the melt material, within the mold cavity, is subjected to a shorter period of time within a temperature range favourable for β-phase formation, since the heat dissipation rate of the melt material increases proportionally with increasing GF content.

Additionally, based on the XRD patterns shown in FIG. 11, the (002)_{GnP}: crystallographic plane increases exponentially, as the GnP content increases. This is accompanied with an increase and decrease in the intensities of the (040)_{α} and (110)_{α} crystallographic PP planes, respectively, emphasizing the effectiveness of GnP in promoting trans-crystallization. The proposed model for the governing mechanism of trans-crystallization is based on the epitaxial growth (i.e., perpendicular) of α-crystals on the surface of the platelets. Furthermore, the GnP c—axis would merge with the PP b—axis in such a way that the (002)_{GnP}: plane is matched with the (010)_{α} PP planes, specifically the (040)_{α} and (060)_{α} planes. The effect of the reinforcements to induce epitaxial growth is quantified by considering the ratio of (040)_{α} and (110)_{α} intensities (i.e., I_{(040)α}/I_{(110)α)}. For instance, I_{(040) α}/I_{(110) α} increases to 7.92 and 3.18 for PPGnP0.5 and PPGnP0.5GF10, respectively, relative to Neat PP (1.28). However, for the GF-reinforced biphasic counterpart (i.e., PPGF10) this ratio is equal to 1.25, indicating that GF has no effect on epitaxial growth of PP. As a result, the successful formation of trans-crystals within the hybrid composites promotes load transfer from the PP matrix to the hierarchically structured reinforcement system, leading to the mechanical properties enhancements described in the following section.

### 1.2.3 Mechanical Properties and Synergistic Effect Elucidation

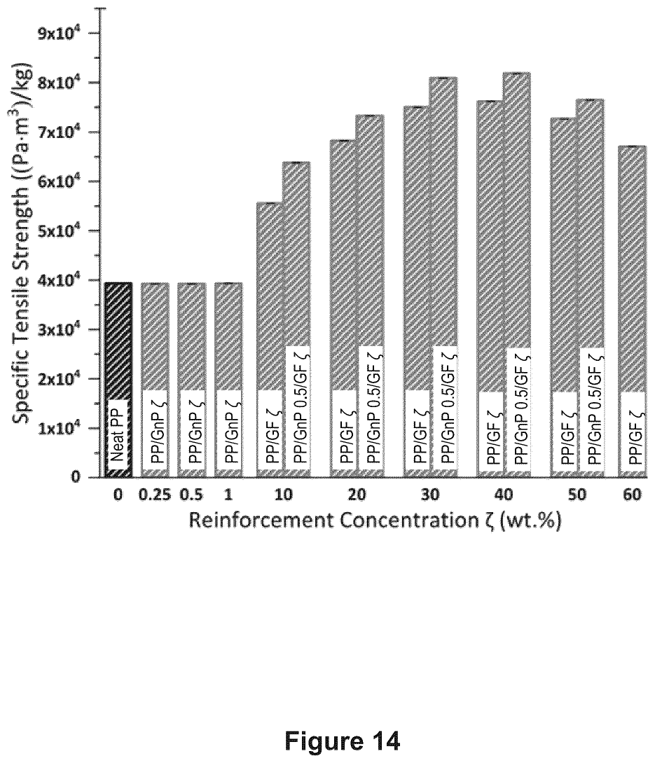

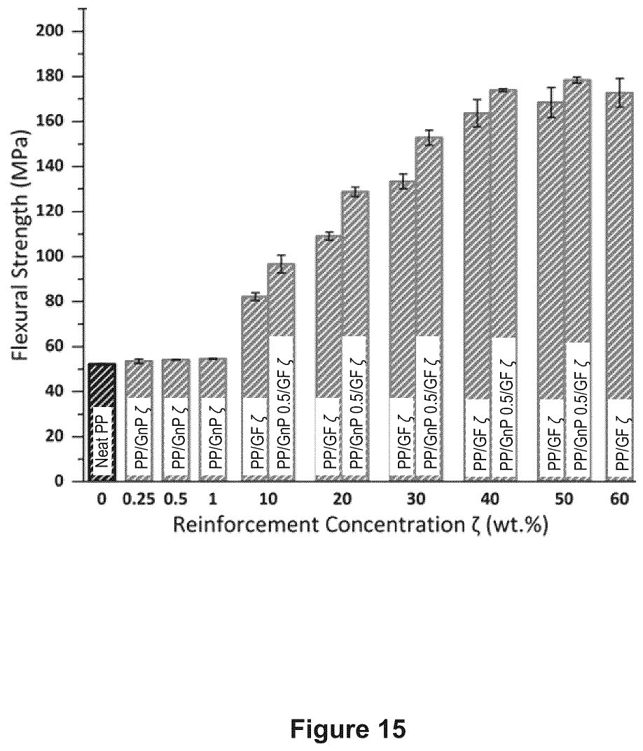

The specific tensile strength and flexural strength were evaluated for all of the fabricated samples, in order to highlight the degree of enhancement generated by the individual fillers in the biphasic composites, and the degree of enhancement generated by the combination of fillers in the hybrid composites. The results for select samples are displayed in FIGS. 14 and 15, in which the (represents the concentration by weight of the corresponding reinforcement, as indicated by the legend.

FIG. 14 is a graph of specific tensile strength versus reinforcement concentration plots for select fabricated composites. FIG. 15 is a graph of flexural strength versus reinforcement concentration plots for select fabricated composites.

The specific tensile and flexural strengths of the hybrid composites containing ξ1 wt. % GnP, perform better than the corresponding biphasic composites with the same concentration of GF. In particular, an optimum concentration of GnP is observed in the hybrid composites with 0.5 wt. % GnP, yielding the highest specific tensile strength of 8.18·10⁴ (Pa×m³)/kg for PPGnP0.5GF40 and flexural strength of 178 MPa for PPGnP0.5GF50. In order to validate the efficacy of these hybrid composites, PPGF60 was selected as a baseline, as it is used for high-performance automotive applications. For example, PPGnP0.5GF50 exceeds the specific tensile and flexural strengths of PPGF60 by 14% and 3.3%, respectively, while providing a 9% weight reduction. Furthermore, PPGnP0.5GF40 obtained a specific tensile strength of 22% greater than PPGF60 and the same desirable flexural strength, while providing an 18% weight reduction.

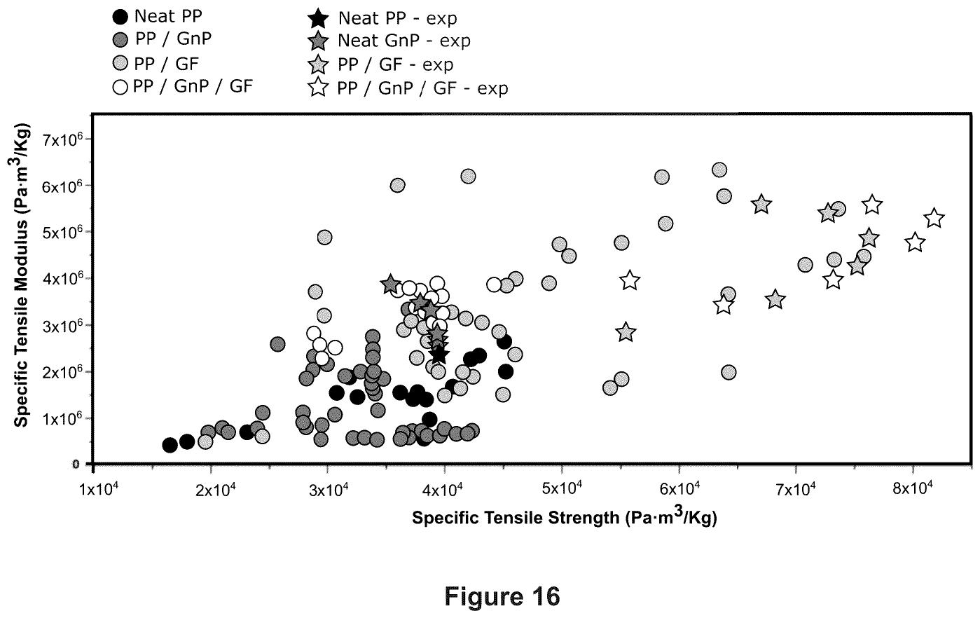

FIG. 16 is a material selection chart for specific tensile modulus versus specific tensile strength of collected literature data with superimposed experimental results.

The material selection chart, shown in FIG. 16, showcasing the specific tensile modulus versus specific tensile strength for collected literature data and the experimental data presented in this work, emphasizes the effectiveness of this hybrid system on lightweighting. This is attributed to the advantageous stiffness-to-weight and strength-to-weight ratios of these composites. It is observed that the optimum performing composite is PPGnP0.5GF40, whereby its stiffness-to-weight (5.57×10⁶ (Pa×m³)/kg) and strength-to-weight (8.18×10⁴ (Pa×m³)/kg) ratios are maximized. In general, it can be observed that the hybrid composites presented in this work outperform the specific tensile properties of the ones previously published in literature, with comparable GF concentrations (i.e., ≤20 wt. %). For example, PPGnP5GF10 presented in this work exceeds the previously recorded literature value, for the same hybrid system and concentration of fillers, by 26.5%, and PPGnP0.5GF10 presented in this work exceeds it by 44% while using significantly less GnP.

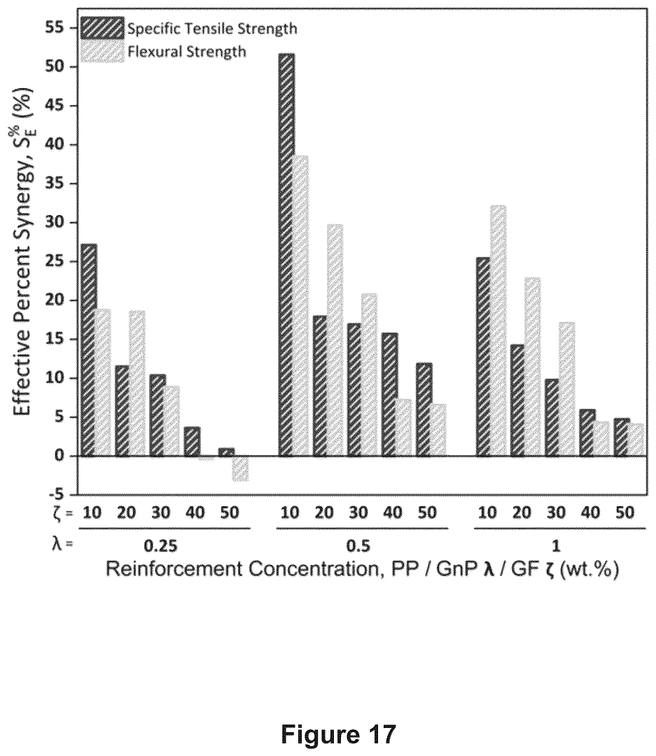

FIG. 17 is a graph showing the effective synergistic effect for the specific tensile strength and flexural strengths of select hybrid composites.

The synergistic effect, in the mechanical properties of these hybrid composites, can be attributed to the implementation of optimum concentrations of the two geometrically different reinforcements, thereby creating a hierarchically structured reinforcement system with improved interfacial interactions that facilitate load transfer and simultaneously enhance the crystalline microstructure of the matrix. It has been demonstrated that creating a hierarchical structure, between the micro-sized filler and the matrix material, with the addition of nano-additives, facilitates better interfacial stress transfer, leading to improved mechanical properties. This is attributed to the high-aspect ratio of the nano-sized fillers, leading to improved bonding at the interface, as a result of the increased surface area. In this work, it has been demonstrated that during processing the GnPs become chemically bonded and/or electrostatically attached to the sized GFs, thereby creating a hierarchical structure. This hierarchical structure promotes greater load transfer from the matrix to the GFs, due to the greater surface area of the improved interface, leading to an increased degree of trans-crystallization, as schematically illustrated in FIG. 1 and elucidated by the XRD results FIG. 11. Trans-crystallization has been shown to favorably improve the interface between fillers and matrix materials owing to absorption/adsorption of polymer chains along the fillers, promoting the translation of stress. Furthermore, the trans-crystallization encapsulating the hierarchical structure induces crystallites that are ˜70% smaller than those of the biphasic GF composites, as illustrated in FIGS. 8A to 8D. The larger specific surface area of these refined crystallites consume more energy when subjected to strong mechanical forces, leading to improved stress transfer at the interface. As a result, the synergistic effect is directly correlated to the tailored interface within these hybrid composites, resulting in superior mechanical performance.

Additionally, the action of GnPs as seeds of heterogeneous nucleation promoting the formation of β-crystals nucleation. As previously mentioned, β-crystals are known to provide excellent mechanical properties, compared to α-crystals. Generally, as a load is applied to the β-crystals, beyond the yield strength, the banded lamellae start to separate and de-fold, undergoing a β to α phase transition. This results in an increase in strength due to the mechanisms of strain hardening, as well as an increased resistance against crack propagation.

The effective percent synergy (S₁%) was evaluated for the hybrid composites to elucidate the trends associated with the various combinations of filler loadings, as shown in FIG. 17 for the specific tensile and flexural strengths of select samples. For the specific tensile and flexural strengths, the S₁% for the hybrid composites with constant GnP concentration decreases with increasing concentration of GF. The optimum S₁% was found in the hybrid composites with 0.5 wt. % GnP at all GF concentrations, in which hybrid composites with <0.5 wt. % GnP and hybrid composites with >0.5 wt. % GnP have a lower S₁%. As a result, the maximum S₁% is approximately 52% and 39% for the specific tensile strength and flexural strength of PPGnP0.5GF10, respectively.

According to the DSC thermograms shown in FIGS. 9 and 10 and XRD diffractograms shown in FIG. 11, the maximum formation of β-crystals and crystallinity occurs with GnP concentrations of 0.5 wt. %. Since the maximum S₁% for the mechanical properties of the hybrid composites also occurs with 0.5 wt. % GnP, the enhanced mechanical performance must be directly correlated to the formation of β-crystals and increased overall crystallinity. Thus, the decrease in mechanical performance for the hybrid composites with GnP concentrations above 0.5 wt. % may be a result of the greater degree of agglomeration, combined with a lower content of the β-phase. Furthermore, the synergistic effect decreases with increasing GF concentration, corresponding to the decreasing trend of κ_{β}.

It is evident that there are two main mechanisms of improvement that contribute to the synergistic effect of this hybrid system: (1) The creation of a hierarchically structured reinforcement system that directly improves the mechanical properties by facilitating load transfer at the interface due to the increased degree of trans-crystallization as a result of the greater surface area in contact with the PP matrix, and (2) the development of a crystalline microstructure with increased crystallinity and β-crystal formation, enabling the matrix to absorb a substantial amount of energy and promote the stress transfer to the reinforcements when exposed to strong mechanical forces.

### 1.2.4 Thermal Conductive Properties and Synergistic Effect Elucidation

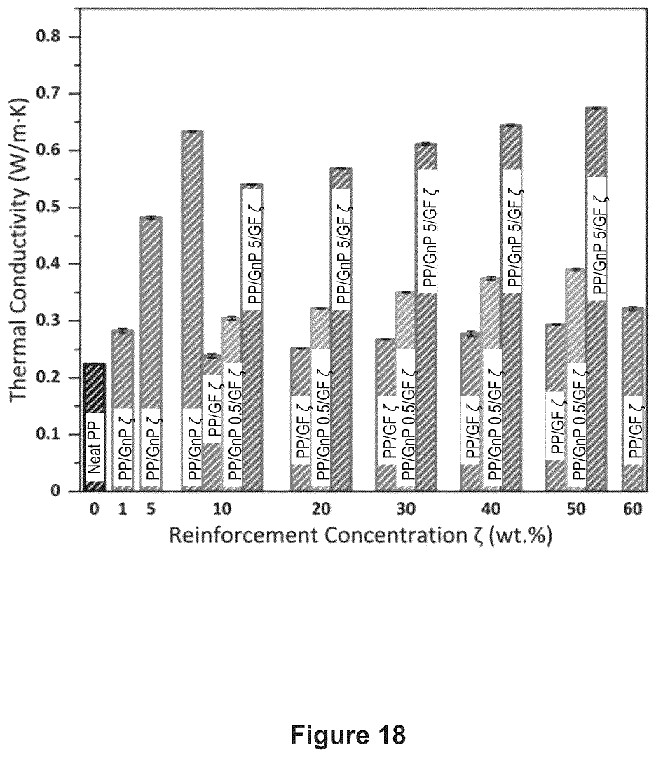

The thermal conductivity was evaluated for all fabricated samples, in order to highlight the degree of enhancement generated by the individual fillers in the biphasic composites, and the degree of enhancement generated by the combination of fillers in the hybrid composites. The results for select composites are displayed in FIG. 18, in which the ζ represents the concentration by weight of the corresponding reinforcement, as indicated by the legend.

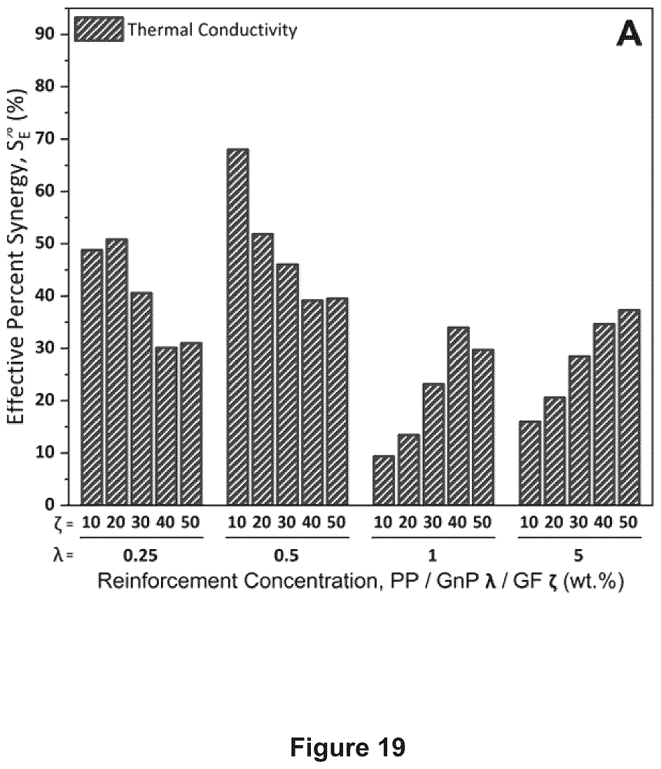

FIG. 18 shows the thermal conductivity data for select composites, and FIG. 19 shows the effective synergistic effect for the thermal conductivity of all fabricated composites.

As expected, increasing the concentration of GnP in the biphasic composites, increased the thermal conductivity, while increasing the concentration of GF had minimal effect on its biphasic composites. Specifically, the biphasic composites with 10 wt. % reinforcement, show a thermal conductivity improvement of 183% with GnP and 7% with GF, compared to Neat PP. This high thermal conductivity in the biphasic GnP composites is attributed to the large surface area of the GnPs, due to their high aspect ratios, enabling them to easily form bridges of percolating networks. As a result, the thermal conductivity increases significantly with increasing GnP concentration, as phonon transfer through the conductive pathways is facilitated.

While the maximum thermal conductivity improvement for the biphasic GnP composites occurred in PPGnP10, the maximum thermal conductivity improvement for the biphasic GF composites occurred in PPGF60, with a 44% increase relative to Neat PP. The thermal conductivity of the hybrid composites with 5 wt. % GnP, show the greatest improvement compared to those of the biphasic composites with the same GnP concentration. Specifically, PPGnP5GF50 has the highest thermal conductivity, exceeding that of PPGnP10 by approximately 6.5% and increasing that of Neat PP by 201%.

The S₁% was evaluated, as shown in FIG. 19, for the thermal conductivity of the hybrid composites to elucidate the trends associated with the various combinations of filler loadings. S₁% for the thermal conductivity with constant GnP concentrations s 1 wt. %, decreases with increasing concentration of GF. However, for the composites with constant GnP concentrations >1 wt. %, the S₁% increases with increasing concentration of GF. The optimum S₁% was found in the hybrid composites with 0.5 wt. % GnP at all GF concentrations. However, the increasing trend with higher concentrations of GnP (i.e., >1 wt. %), suggests that there could be an optimum S₁% beyond the data presented in this work. Overall, the maximum S₁% is approximately 68% corresponding to PPGnP0.5GF10.

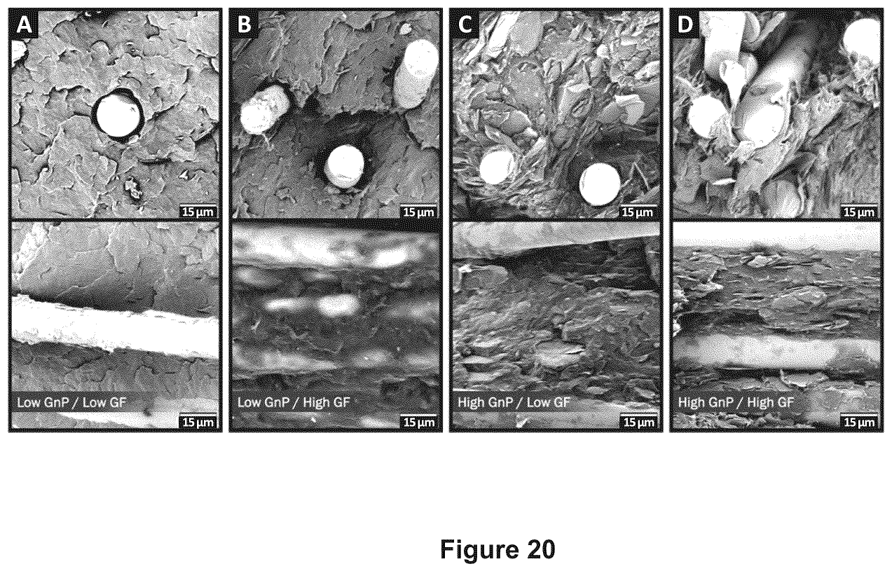

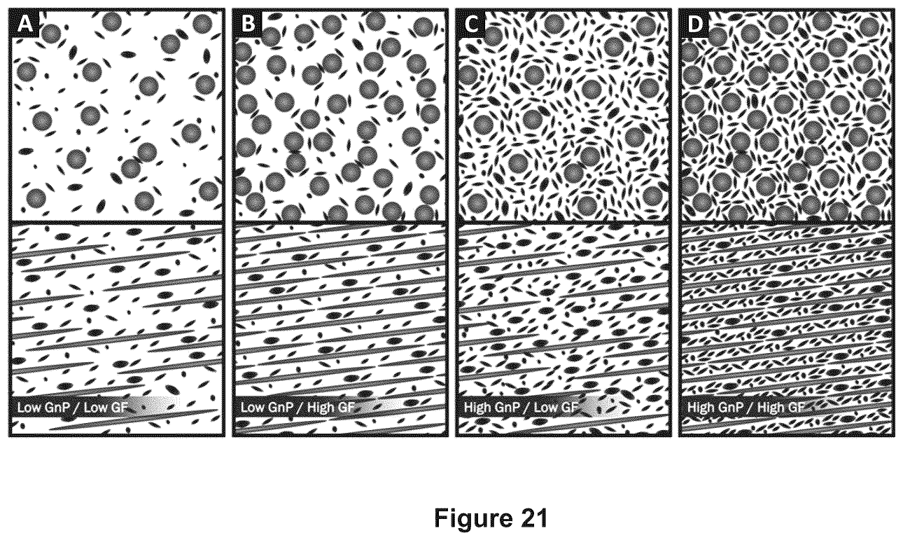

The synergistic effect of the thermal conductivity is primarily attributed to the implementation of optimum concentrations of the two geometrically different reinforcements. This leads to a tailored composite morphology that promotes the formation of thermal conductive pathways, with the crystalline microstructure playing a supporting role. The conductive pathways are generated through the volume exclusion effect induced by the presence of the GFs within the hybrid composites. The four scenarios associated with this behavior are captured in the SEM images shown in FIGS. 20A to 20D and schematically shown in FIGS. 21A to D.

FIG. 20A is a transverse (the upper one) and a longitudinal (the lower one) SEM images of a non-etched sample in concentrations of low GnP and low GF. FIG. 20B is a transverse (the upper one) and a longitudinal (the lower one) SEM image of a non-etched sample in concentrations of low GnP and high GF. FIG. 20C is a transverse (the upper one) and a longitudinal (the lower one) SEM image of a non-etched sample in concentrations of high GnP and low GF. FIG. 20D is a transverse (the upper one) and a longitudinal (the lower one) SEM image of a non-etched sample in concentrations of high GnP and high GF.

FIGS. 21A to 21D are schematics illustrating the mechanisms of thermal conductive synergy via the volume exclusion effect. FIG. 21A depicts concentrations of low GnP and low GF, FIG. 21B shows low GnP and high GF, FIG. 21C shows high GnP and low GF, and FIG. 21D shows high GnP and high GF.

For the hybrid composites with low concentrations of GnP (i.e., <1 wt. % GnP) and low concentration of GF (i.e., <30 wt. % GF), as shown in FIG. 20A and FIG. 21A, the volume exclusion effect maximizes the potential of the GnPs by bringing those dispersed in the bulk closer to those adhered to the GFs, forming a GnP-based conductive network. The SEM micrographs showcase that the GnPs are either attached directly to the GFs or oriented around them, rather than being uniformly scattered throughout the matrix, boosting the formation of thermal conductive pathways. A similar behavior has been observed, in which the addition of secondary reinforcements promotes the formation of conductive pathways, as a result of the volume exclusion effect, generated by the different geometric fillers. For these composites, the greatest synergistic effect was observed for the hybrid composites containing 0.5 wt. % GnP, which is attributed to the crystalline microstructure with a higher degree of crystallinity (55% compared to 49% of Neat PP), compared to the hybrid composites with 0.25 wt. % GnP. The degree of crystallinity directly affects the thermal conductivity of polymer composites, in which a higher crystallinity results in a greater thermal conductivity.

On the contrary, for the hybrid composites with low concentrations of GnP (i.e., <1 wt. % GnP) and high concentrations of GF (i.e., ³ 30 wt. % GF), increasing GF content decreases the synergistic effect. However, the degree of crystallinity is only dependent of GnP content, suggesting that it has a minimal contribution to the synergistic effect, as the concentrations of GF increases. As a result, the dominating mechanism contributing to the reduction of the synergistic effect is the insufficient quantity of GnPs, compared to the quantity of GFs, leading to an inability to form continuous thermal conductive pathways as shown in FIG. 20B and FIG. 21B.

For the hybrid composites with high concentrations of GnP (i.e., >1 wt. % GnP) and low concentrations of GF, shown in FIG. 20C and FIG. 21C, the increased concentration of GnP directly induces the formation of conductive pathways, resulting in a less pronounced volume exclusion effect, thereby reducing the overall synergistic effect in these composites. Moreover, these composites are more susceptible to agglomeration due to the higher GnP concentrations, which is detrimental to the phonon transfer through the conductive pathways.

Lastly, for hybrid composites with high concentrations of GnPs and high concentrations of GF, shown in FIG. 20D and FIG. 21D, the synergistic effect begins to increase as this system better exploits the volume exclusion effect compared to the previous scenario, as the GFs force the excess GnPs that are not attached to the GFs, to be confined and oriented along the direction of the fibers. High concentrations of nano-sized fillers preferentially and independently oriented themselves between the spaces of micro-sized fillers, thereby developing network-like pathways. Overall, the synergistic effect for the thermal conductivity of these hybrid composites, is predominately attributed to the volume exclusion effect induced by the GF with a contribution from the degree of crystallinity, at low concentrations of GF.

### 1.3. Conclusion

The examples elucidate how the hybrid approach can produce synergistic effects capable of achieving properties and functionalities not possible in biphasic composites. The synergistic effect for the mechanical properties was attributed to the chemically and/or electrostatically assembled hierarchical reinforcement system, which facilitates load transfer at the interface, due to the increased degree of trans-crystallization and the smaller crystallites with greater surface area. This is accompanied with an increased degree of crystallinity and β-crystal formation, enabling the matrix to absorb a greater amount of energy. It was demonstrated that the optimal concentration of 0.5 wt. %. GnP in the hybrid composites, producing the greatest mechanical properties and synergistic effect, corresponds to the highest degree of crystallinity and peak formation of β-crystals within the PP matrix. Specifically, PPGnP0.5GF50 exceeded the flexural strength of PPGF60 by 3.3% while providing a 9% weight reduction and PPGnP0.5GF40 obtained the same desirable flexural strength as PPGF60, while providing an 18% weight reduction. The same optimal concentration was found to produce the highest synergistic effect for thermal conductivity; however, it was attributed to the joint action of the volume exclusion effect induced by the GFs, and the tailored crystalline microstructure, promoting the formation of thermal conductive pathways. Ultimately, the mechanisms contributing to the synergistic effect presented in this work, can be used to maximize the performance of hybrid composite systems, giving them the potential to be used in a variety of high-performance applications, where mechanical performance, thermal conductivity, and lightweighting are imperative to meet the energy efficiency requirements of the future.

### Example 2

In Example 1, the mold temperature was 80° C. to promote crystallization of samples. In Example 2, a battery encasement (or “battery tub”) was manufactured according to method 200 and injected molded at different temperatures.

### 2.1 Materials and Sample Preparation

A commercially available GnP-PP masterbatch was dry blended with a glass-reinforced-PP. The 30 wt % GNP-PP masterbatch containing graphene nanoplatelets with an average diameter of 38 μm (GrapheneBlack™ 3X), was provided by NanoXplore Inc. (Quebec, Canada)). The glass-reinforced-PP, with commercial name Celstran® PP-GF60-02 Natural, produced by Celanese Corporation (Texas, United States) comprises 60 wt. % of E-glass fibers sized with aminosilane, having an average length of 10 mm and an average diameter of 14 μm, with an overall masterbatch density of 1.43 g/cm³.

Additional polypropylene (PP) homopolymer, HIVAL® 2435, with a melt flow rate of 35 g/10 min (230° C./2.16 kg) and a specific gravity of 0.902 g/cm³ produced by Nexeo Plastics® (Texas, United States) was added to achieve the desired concentrations of GnP and GF, as indicated in Table 2 (below).

After dry-blending the GnP-PP master-batch and glass-reinforced PP, the blended mixture was melt-mixed and injected into a mold using an injection molding machine.

Alternatively, in a development step, Celstran® PP-GF60-02 Natural was replaced with KompoGTe® LE1 G60 natural, comprising 60 wt. % of E-glass fibers with a specific gravity of 1.42 g/cm³.

Alternatively, in another development step, KompoGTe® LE1G60 natural was replaced with KompoGTe® LE1 G40 natural, comprising 40 wt. % of E-glass fibers with a specific gravity of 1.18 g/cm³. Therefore, HIVAL® 2435 was omitted from the blend to simplify the procedure further.

A 650-ton Kawaguchi KM650B2, model 2003, injection molding machine (Japan), with a 100 mm diameter screw, was used to fabricate an automobile battery encasement particle at a mold temperature of 80° C. or 65° C.

The composites were designated by indicating the matrix, the amount of GnP, and the amount of GF according to this format: PPGnPζGFζ, where the ζ corresponds to the amount of reinforcing material by weight of the whole composite.

### 2.2 Results

Decreasing the injection molding processing cycle time reduced the injection molding processing cycle. As shown in Table 2 below, decreasing the mold temperature from 80° C. to 65° C. caused the cycle time to decrease from 123 seconds to 93 seconds. While the shorter processing cycle might sacrifice crystallization degree in the small articles, for a large article like a battery tub or encasement, the cooling time is sufficiently high to allow for appropriate crystallization and to improve the properties of the manufactured article. Thus, by reducing the mold temperature, the overall manufacturing time and cost can be decreased.

TABLE 2

| Polymer | | | | | |
|---|---|---|---|---|---|
| Composite | | | | | |
| (Automotive | Mould | Cycle | Flexural | Flexural | |
| Battery | Temperature | Time | Strength | Toughness | Weight |
| Encasement) | (° C.) | (s) | (MPa) | (MPa) | (kg) |
| PPGF60 | 65 | 93 | 139.16 ± 1.49 | 2.94 ± 0.26 | 1.76 |
| PPGF40 | 80 | 123 | 121.88 ± 1.20 | 3.63 ± 0.52 | 1.44 |
| PPGF40GnP0.5 | 80 | 123 | 140.63 ± 2.68 | 3.65 ± 0.18 | 1.42 |
| PPGF40GnP0.5 | 65 | 93 | 140.67 ± 2.16 | 3.47 ± 0.42 | 1.42 |

### Example 3

### 3.1 Materials and Sample Preparation

For the matrix of the composites, a PP homopolymer, HIVAL® 2435 (melt flow rate=35 g/10 min (230° C./2.16 kg), density ρ=0.902 g/cm³) produced by Nexeo Plastics (Texas, United States) was used. A 60 wt. % aminosilane-sized E-glass fiber-filled PP masterbatch produced by Celanese Corporation (Texas, United States) was utilized to introduce a micro-sized filler with an average length of 10 mm and an average diameter of 14 μm into the composites. The 30 wt. % GnP-filled PP masterbatch having graphene flakes with an average diameter of D_{avg.}≈ 38 μm and about 6-10 layers of graphene, GrapheneBlack™ 3X, was provided by NanoXplore Inc. (Quebec, Canada).

A 50-ton Arburg Allrounder 270/320C injection molding machine (Lossburg, Germany) was employed to fabricate series of biphasic composites, PPGFζ and PPGnPζ, and hybrid composites, PPGnPζGFζ, where ζ corresponds to the volume percent of the fillers (see Section 3.5: Supplementary Information). The biphasic and hybrid samples were manufactured with GnP contents ranging from 7.5-15 vol %. In the cases of PPGFζ and PPGnPζGFζ which contain GF as the micro-sized filler, the samples consist of two different GF concentrations (i.e., 5 and 10 vol %). The composites were injected into a custom dual hot mold set at 80° C. to create ASTM D638-Type IV tensile and ASTM D790 flexural standard specimens. In order to ensure that the aspect ratios of the fillers were maintained, the GF and GnP masterbatches were diluted into the desired concentrations using a dry blending technique, prior to the injection molding process.

### 3.2 Characterizations

The arrangement and orientation of the fillers in biphasic and hybrid composites were investigated using a Quanta FEG 250 Scanning Electron Microscope (SEM). Before conducting SEM observations, the injection molded samples were cryo-fractured by immersion in liquid nitrogen for approximately 1-hour, and subsequently sputter-coated with platinum. To further investigate orientations of GnPs as well as PP crystals in the bulk composite, 1 D and 2D analyses were conducted using X-ray diffraction (XRD) spectroscopy. A diffractometer (Bruker™ D8 Davinci) equipped a with a cobalt sealed tube (λ=0.179 nm) parallel beam line source (0.2 mm slit, 2.5° Soller) was used to record (002) pole figure of GnP (texture analysis) for the biphasic PPGnP10 and hybrid PPGnP10GF10 composites. The Z-axis being the normal direction of the specimen (perpendicular to the flow direction) was located at the center of the pole figures. The samples were rotated for full circle 0=0-360° and tilted at ψ=0-20°, and intensity of reflections from the GnP crystallographic plane (002) were collected every ϕ=8°. Moreover, in order to investigate the chemical adhesion between the fillers, a Fourier-Transform Infrared (FTIR) spectrometer (Bruker, Platinum-ATR) was used. For FTIR spectroscopy over a spectral range of 500-4,000 cm⁻¹, the biphasic (PPGF10) and hybrid composite (PPGnP10GF10) were etched in boiling Xylene for 5 minutes.

An Alpha-A high performance dielectric impedance analyzer (Novocontrol Technologies GmbH & Co. KG) was employed to measure the broadband through-plane electrical conductivity and permittivity (ε=ε′−iε″, ε′: real permittivity, Σ″: imaginary permittivity) of the composite samples with 20 mm diameter×3 mm thickness at frequencies ranging from 1×10⁻¹ to 1×10⁵ Hz. The measured electrical conductivity at a frequency of 10⁻¹ Hz was reported as the direct current (DC) electrical conductivity (σ_{DC}). Also, comparative analyses of ε′ and dielectric loss (tan (=ε″/ε′) of the composites were conducted at a frequency of 1×10³ Hz. The EMI shielding performance of the composites with dimensions of 15.8 mm×7.8 mm×3 mm were measured using the waveguide method by means of a vector network analyzer (Agilent N5234A) in the Kᵤ-band frequency range (12.4-18 GHz). The S-parameters (S₁₁ and S₂₁) were recorded, and the total shielding effectiveness SE_{T} of the composites were calculated using Formula 5:

$$S {E}_{T} ( dB ) = {\underbrace{10 {log}_{10} ( \frac{1}{1 - {\vert {S}_{11} \vert}^{2}} )}}_{{SE}_{R}} + {\underbrace{10 {log}_{10} ( \frac{1 - {\vert {S}_{11} \vert}^{2}}{{\vert {S}_{21} \vert}^{2}} )}}_{{SE}_{A}} \qquad Formula 5$$

Thermal conductivities of the fabricated samples were measured using a transient plane source (TPS) 2500 (Therm Test Inc., Sweden) thermal constants analyzer which works based on transient hot disk method according to ISO/DIS 22007-2.2. The analyzer is equipped with a C7577 Kapton sensor made of double spiral disk-shape nickel foils which is placed between two identical samples with flat surfaces to simultaneously heat the samples and record their temperature variations as a function of time. In this study, the measured values are composites' isotropic thermal conductivities, which represent the average dissipated heat in both in-plane and through-plane directions. Since the degree of defect density of GnP flakes significantly affects its inherent thermal conductivity, the relative defects of the GnP powder were evaluated using Raman spectroscopy (Renishaw, 532 nm laser excitation).

Formula 6 was used to calculate the percent synergy S^{%}, in order to quantify the synergistic enhancements in a hybrid composite, relative to the biphasic composites with the same contents of the individual fillers.

$${S}^{\%} = \frac{{M}_{h} - ( {M}_{p} + {M}_{s} )}{( {M}_{p} + {M}_{s} )} \times 100 \qquad Formula 6$$

where Mₕ, Mₚ and Mₛ respectively represent the magnitudes of the enhancements of the hybrid composite, the biphasic composite reinforced with the primary filler and the biphasic composite reinforced with the secondary filler, relative to the matrix material.

The tensile and flexural mechanical properties of the fabricated samples were measured using an Instron 5965 with a load cell of 5 kN. Five replicate samples were tested by setting the crosshead speeds of 5 and 1.3 mm/min for tensile and flexural modes, respectively.

### 3.3 Results and Discussions

### 3.3.1 Microstructure and Fillers' Arrangements

In general, the electrical percolation threshold of conductive polymer composites (CPCs) is determined by the conductive fillers' ability to form current pathways. In addition to their concentrations, the arrangement of the conductive fillers is an important factor, as the randomly orientated fillers are more likely to intersect, in comparison to the fillers with preferred orientations. Shear-induced orientation of the fillers in the flow direction is a well-known characteristic of injection-molded composites, preventing their effective interconnection. Hence, the arrangement of the GnP flakes within the biphasic PPGnP10 and hybrid PPGnP10GF10 composites, as representative cases, was quantitatively and qualitatively investigated using XRD-assisted fiber texture and SEM analyses, respectively.

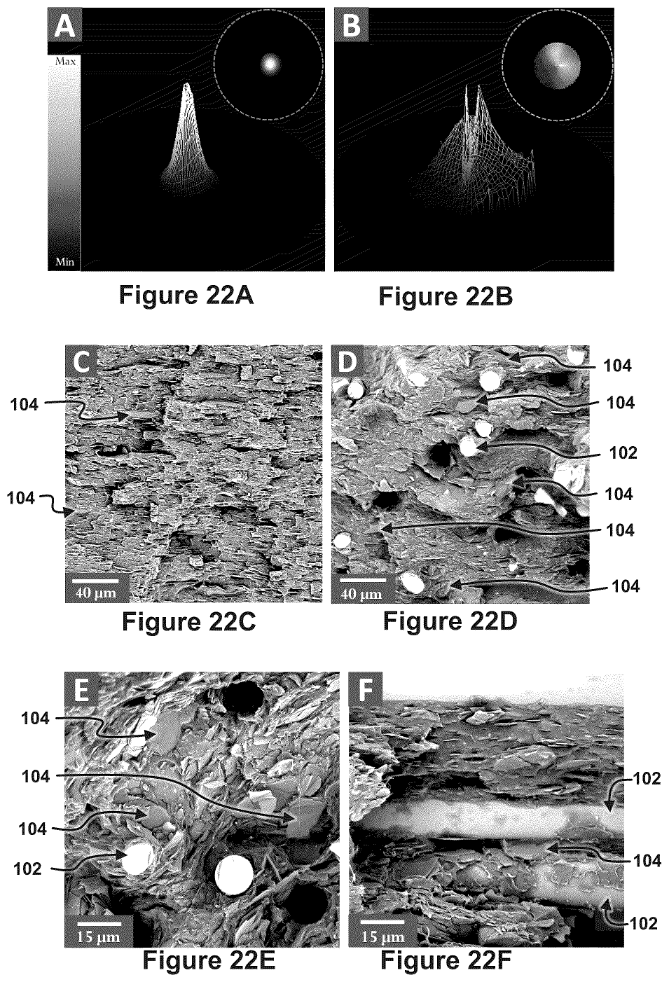

FIG. 22A is an XRD pole figure illustrating the texture analysis based on the reflection intensity of the (002) GnP crystallographic plane in PPGnP10. FIG. 22B is an XRD pole figure illustrating the texture analysis based on the reflection intensity of the (002) GnP crystallographic plane in PPGnP10GF10.

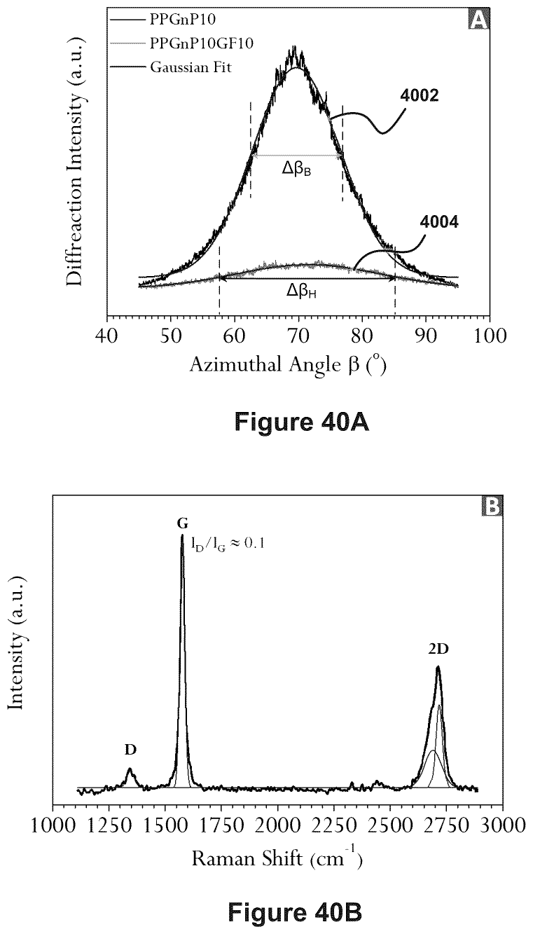

The contours of intensity of reflections from the GnP crystallographic plane (002) in PPGnP10 shown as a pole figure in FIG. 22A present completely circular and centered iso-intensity lines, denoting highly oriented GnP flakes 104 being parallel to the surface of the sample. In contrast, the pole figure of its hybrid counterpart in FIG. 22B indicates the random orientation of GnPs 104 by considering its asymmetrical pattern of the reflection intensities over the measurement tilt and rotation angle ranges. The orientation of GnPs can also be further analyzed by considering full-width at half-maximum (FWHM), Δβ, of azimuthal intensity distribution of the (002) diffraction. In general, a narrower Δβ of the azimuthal intensity peaks implies a higher degree of GnPs orientation. As shown later in FIG. 40A, Δβ increases from 16.29 in the azimuthal intensity profile of the biphasic composite 4002 to 27.82 in the hybrid composite 4004 with more randomly oriented GnPs.

FIG. 22C is a representative SEM micrograph of the cross-sections of PPGnP10. FIG. 22CD is a representative SEM micrograph of the cross-sections of PPGnP10GF10. FIG. 22E is another representative SEM micrograph of the cross-sections of PPGnP10. FIG. 22F is another representative SEM micrograph of the cross-sections of PPGnP10GF10.

The SEM micrograph of the cross section with a normal vector in the flow direction (FIG. 22C) confirms the findings of the fiber texture analysis, indicating the highly oriented GnP flakes 104 in the biphasic PPGnP10 composite. In contrast, the GnP flakes 104 are more randomly oriented in the hybrid PPGnP10GF10 composite shown in FIGS. 22D and 22E, especially in areas surrounding GFs 102, where GnP flakes 104 need to change their orientations to fit in. In the SEM images of the hybrid samples, GFs 102 could be simply traced by noting both the remained and the pulled-out fibers, following the fracturing, during SEM sample preparation. The SEM analysis of the hybrid composite's cross section with a normal vector perpendicular to the flow direction, as shown in FIG. 22F, reveals altered orientations of GnPs 104 located in the interstitial space between the parallel GFs 102. The combination of the high shear rate (≈10³ to 10⁴ s⁻¹) existing during the injection molding process, and the spatial obstacles induced by the GFs 102, while flowing in the mold cavity, forces the GnP flakes to reorient because of the filler-filler interactions. Therefore, by introducing GFs 102 as secondary micro-sized fillers, a segregated structure containing the conductive GnP fillers 104 is formed, serving as the current pathways.

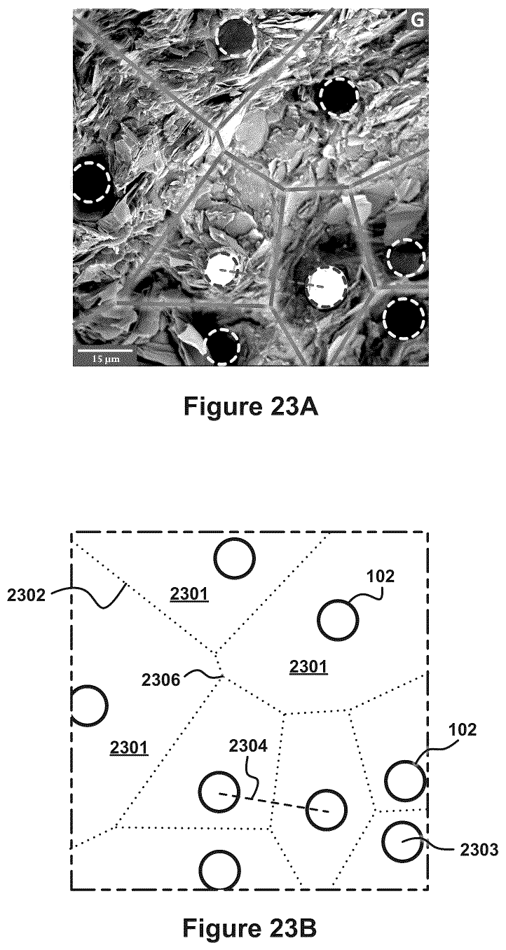

FIG. 23A is an SEM of a hybrid CPC including an illustrated overlay of a Voronoi tessellation. FIG. 23B is an illustration of the Voronoi tessellation of FIG. 23A.

Through-plane electrical conductivity of CPCs with a segregated structure could be analyzed by defining Voronoi tessellation in a 2D cross section, to identify all possible current paths within the hybrid CPCs. According to the example shown in FIGS. 23A and 23B, a 2D cross section of the hybrid composite can be divided into different cells 2301 having the center points of GFs 102 as “site points” 2303 in the Voronoi tessellation. In FIGS. 23A and 23B, Voronoi edges 2302 are drawn perpendicular to lines 2304 which connect the site points 2303. Voronoi edges 2302 intersect at nodes named Voronoi vertices 2306. The 2D cross section is divided in such a way that the distance of each Voronoi edge 2302 to the center point 2303 of the corresponding cell 2301 is less than or equal to any other center points 2303. Thus, the integrated combinations of different Voronoi edges 2304 indicate the collection of potential current paths. Based on this framework, electrical conductivity of the composites is analyzed in the following sections.

### 3.3.2 Electrical Conductivity of the Composites

To have a comprehensive understanding of the dielectric properties of CPCs, their electrical conductivities need to be studied in an alternating current (AC) field over a broadband frequency range, which is defined by Formula 7.

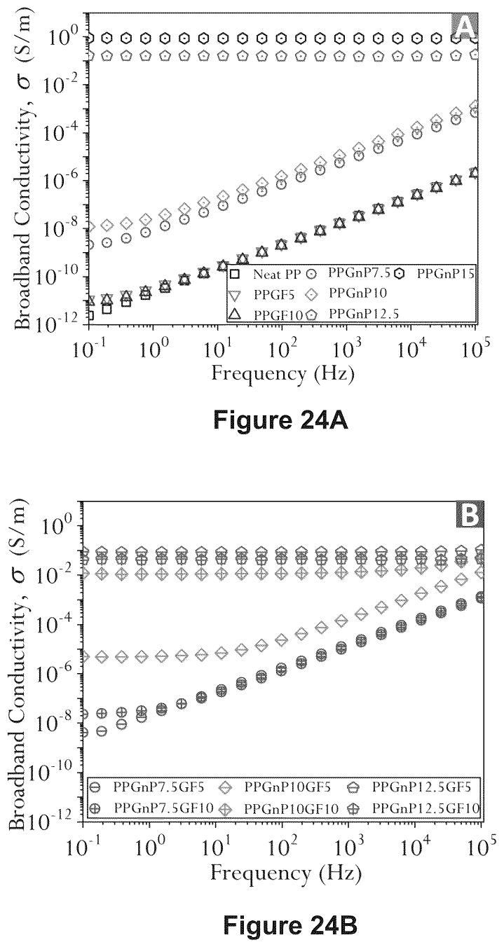

σ=σ_{DC}+A(ω)^{s} Formula 7

where, ω=2πf is the angular frequency, A and s are constant parameters which are related to the temperature, the type and concentration of the filler. Based on Formula 7, the broadband electrical conductivity, a consists of two components: 1) σ_{DC} which is associated with the resistive (conduction) current, and 2) σ_{AC}=A(ω)^{s} which is the alternating current electrical conductivity originating from capacitive (displacement) current. Accordingly, σ_{AC} has a frequency-dependent behavior, so that it shows an ascending trend with frequency increase. However, σ_{AC} gradually diminishes at lower frequencies where the time for free electrons to sweep the half cycle of the AC field increases. Hence, σ_{DC} shows a frequency-independent behavior, which is usually measured under a low-frequency AC voltage, where resistive current is dominant. The transition from frequency-independent behavior (σ_{DC}) to a frequency-dependent behavior (σ_{AC}) occurs at a certain frequency, known as the critical frequency (f_{c}). Generally, materials with more insulative characteristics exhibit more frequency-dependent behavior, showing lower or even no f_{c}. FIG. 24A shows the broadband electrical conductivity of the biphasic composites containing various concentrations of GF or GnP over a frequency range of 10⁻¹ to 10⁺⁵ Hz. Neat PP, PPGF5 and PPGF10 show an ascending and frequency-dependent conductivity over the whole frequency range, indicating the fully insulative nature of the composites. The marginal increase in the electrical conductivities of the GF-reinforced composite at 10⁻¹ Hz, can be attributed to the lower volume resistivity of E-glass than that of PP which respectively are around 10⁺¹⁴ and 10⁺¹⁶ Ω·cm. Also, the frequency-dependent conductivities of PPGnP7.5 and PPGnP10 demonstrate their insulative characteristics. However, it can be noticed that PPGnP10 starts to show a f_{c} at very low frequencies (˜3×10⁻¹ Hz) below which resistive current through the GnP networks in the composites starts to become comparable to the capacitive current. This is an indicator that the electrical percolation threshold of the CPCs occurs at GnP contents of approximately 10 vol %. As shown in FIG. 24A, increasing GnP content to 12.5 and 15 vol % causes the CPCs to transition to a fully frequency-independent behavior, with electrical conductivities of 0.16 and 0.85 S/m, respectively. Therefore, in PPGnP12.5 and PPGnP15, nomadic charges flow through the interconnected conductive network formed within the CPCs, and the capacitive current (σ_{AC}) is negligible as compared to the resistive current (σ_{DC}).

The broadband electrical conductivities of the hybrid composites are presented in FIG. 24B. The hybrid composite PPGnP7.5GF5 exhibits a very similar trend to that of its corresponding biphasic CPC (i.e., PPGnP7.5), shown in FIG. 24A. However, by increasing GF to 10 vol % in PPGnP7.5GF10, a f_{c} at 8×10⁻¹ Hz appears, indicating the effective role of GF in the formation of an interconnected GnP conductive network. This is much more pronounced in the cases of PPGnP10GF5 and PPGnP10GF10, where adding GF shifts f_{c} from 3×10⁻¹ Hz (in PPGnP10 shown in FIG. 24A) to 3×10⁺¹ and 2×10⁺⁴ Hz, respectively. Hence, despite insulative characteristic of GF, the introduction of 10 vol % GF causes a transition from almost fully σ_{AC}-dominated in PPGnP10 (FIG. 24A) to almost fully σ_{DC}-dominated conductivity in PPGnP10GF10 (FIG. 24B). This effect can be considered equivalent to the effect of the introduction of foaming into the carbon-based nanocomposites, where the growing cells induce a volume exclusion effect as well as a rearrangement (displacement and rotation) of the nanofillers. Theoretical and experimental studies show that the conductive network formation in microcellular structures (with 7-16% void fraction at the percolation threshold in injection molded CPCs) would be enhanced if the cells' diameter and the fillers' length are comparable (equal or up to 2-fold larger filler). This indicates that GFs with an average diameter of 14 μm effectively contribute to the conductive network formation, especially with 10 vol % GF, since most of the GnP flakes' diameters fall within the aforementioned optimal filler size range, after the injection molding process (see FIGS. 23A and 23B).

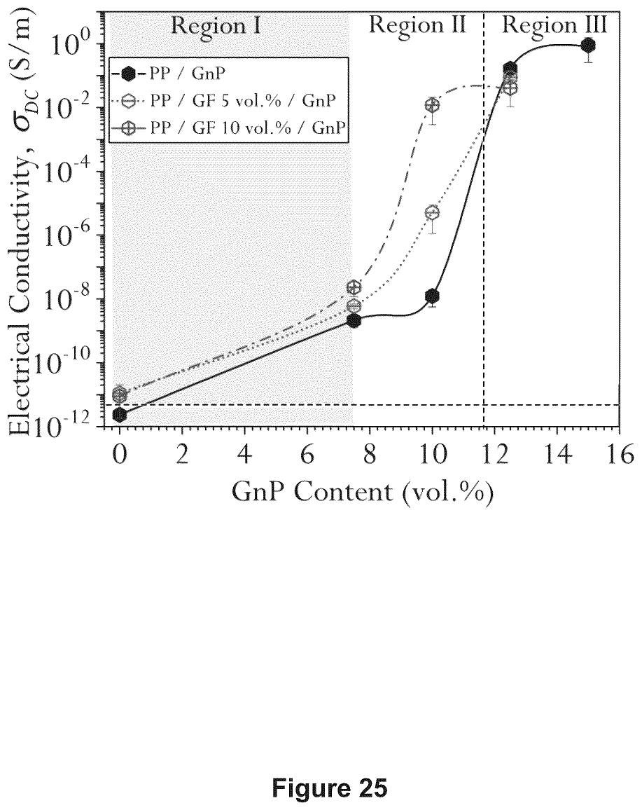

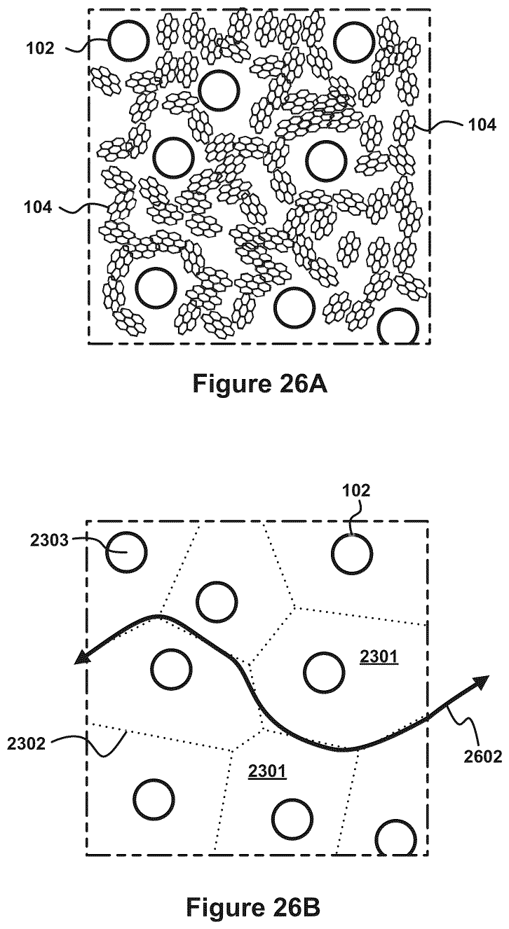

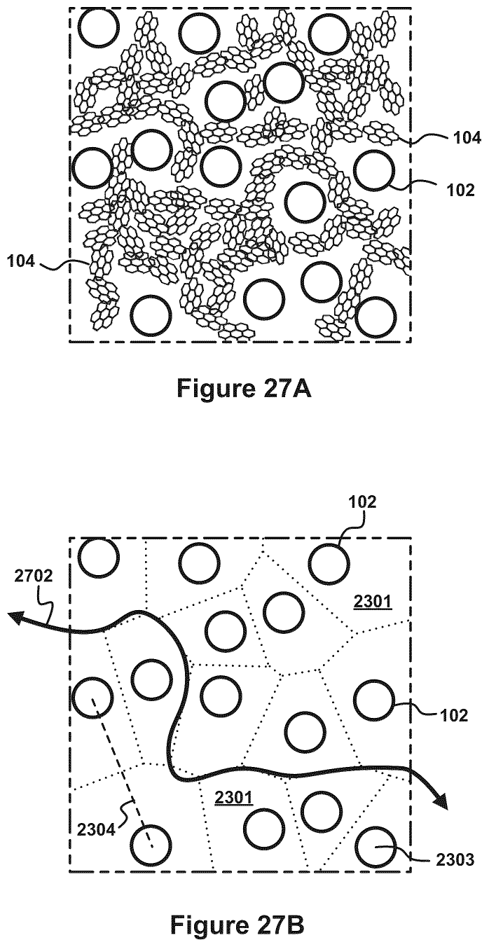

In order to clarify the effects of the introduction of GF at various GnP contents, composites' σ_{DC} (measured at 0.1 Hz) are presented in FIG. 25. FIG. 25 is a graph showing DC electrical conductivities of the biphasic and hybrid composites. In this regard, to qualitatively analyze σ_{DC} of the composites at a fixed GnP content, schematics of Voronoi tessellations in cross sections of GnP-based CPCs with low contents of GF are illustrated in FIGS. 26A and 26B, and CPCs with high contents of GF are illustrated in FIGS. 27A and 27B. FIG. 26A is a schematic illustrating the arrangement of GF 102 and GnP 104 in a low-GF composite, while FIG. 26B is a schematic of the Voronoi tessellation corresponding to FIG. 26A with a current path 2602. FIG. 27A is a schematic illustrating the arrangement of GF 102 and GnP 104 in a high-GF composite, while FIG. 27B is a schematic of the Voronoi tessellation corresponding to FIG. 27A with a current path 2702.

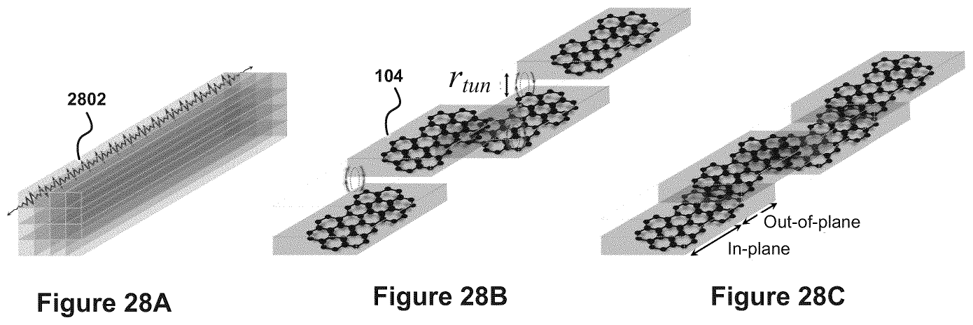

In the mentioned framework, the current paths defined by Voronoi edges 2302 are assumed as cuboids consisting of multiple identical but independent conduction channels 2802, shown in FIGS. 28A to 28C. FIG. 28A is a schematic illustrating a simplified model of the current paths in a CPC consisting of multiple identical but independent conduction channels 2802. Each conduction channel is composed of a series of GnPs 104 with an identical distance of rₜᵤₙ, as illustrated in FIG. 28B.

In FIG. 25, three distinct regions are observed in through-plane DC conductivity curves of the biphasic and hybrid CPCs. Based on the percolation theory concept, these regions indicate the evolution of the conductive networks within the composites, according to the following sequence: (1) insulative, (II) percolation, and (111) conductive regions.

The gray-shaded zone (Region I) in FIG. 25 indicates the insulative region where the electrical conductivity is mainly dominated by the polymer matrix. The baseline is defined at 5×10⁻¹² S/m corresponding to the average σ_{DC} of the neat PP and the biphasic GF-based composites. In Region I where the GnP content is lower than the concentration required for the formation of a conductive network within the composites, the σ_{DC} of the biphasic PPGnP7.5 composite increases to approximately 2×10⁻⁸ S/m. Interestingly, adding 5 and 10 vol % of GF as an insulative micro-sized filler into the PPGnP7.5 causes ˜132% and ˜985% enhancement in the σ_{DC} of the hybrid composites, respectively. For such cases, the metal-insulator transition model can be used to explain the conductivity mechanism based on electron tunneling between the isolated GnP clusters in a continuous dielectric environment (i.e., the PP matrix). The quantum tunneling conductivity (σₜᵤₙ) is exponentially dependent on the interstitial space between GnP clusters, which is equal to the tunneling distance (rₜᵤₙ), according to the following equation:

$${σ}_{tun} = {σ}_{0} exp ( - \frac{4}{3} {( \frac{4 α {r}_{tun}}{a} )}^{3 / 4} {( \frac{{W}_{0}}{κ T} )}^{1 / 4} ) \qquad Formula 8$$

where, σ₀ is a pre-exponential normalization constant related to the conductivity of the dielectric matrix, a is the critical percolation probability constant, a is the characteristic radius of the conductive clusters, and W₀, κ and T are the characteristic potential barrier for electron tunneling, the Boltzmann constant and the temperature, respectively. Accordingly, the effect of introducing GF on σ_{DC} of the hybrid composites containing 7.5 vol % GF can be explained in terms of the interstitial distance between the GnP clusters, rₜᵤₙ. In FIG. 28B, the schematic of a single conduction channel being active in Region I is illustrated. It is hypothesized that, in this mode, the electrical transport is conducted through two mechanisms: (1) in-plane charge transfer, and (2) tunneling via the GnP clusters' edges, where the latter controls the total conductivity of the composites. Calculations using Formula 8 (see Section 3.5.4: Electrical Conductivity Calculations) show that the excluded volumes induced by adding 5 and 10 vol % GF, result in a ˜1.5% and ˜3.1% enhancement in electrical conductivity of PPGnP7.5GF5 and PPGnP7.5GF10, respectively. In this case, a uniform simplified state of distribution is assumed, in which the GnP flakes are arranged in parallel planes with the same orientation at an identical distance in X- and Y-axis directions, while the volume exclusion is only applied in the Z-axis direction. However, at region I, the superior experimental results, compared to the estimated theoretical enhancements, can be attributed to the non-uniformly localized GnPs with more random orientations. This would cause a lower average rₜᵤₙ the variation of which at the nanometer scale induces electrical conductivity changes by orders of magnitude in nanocomposites.

In Region II, σ_{DC} of the biphasic PPGnP10 follows the same trend as observed in Region I, so that its σ_{DC} reaches ˜1.2×10⁻⁸ S/m. This can be attributed to the decreased average rₜᵤₙ by increasing the GnP loading. However, in the cases of the hybrid CPCs in Region II, a spike in their σ_{DC} is observed by the introduction of GF. As demonstrated in FIG. 25, the additions of 5 and 10 vol % GF to PPGnP10 have caused approximately 3 and 6 orders of magnitude conductivity enhancements in the corresponding hybrid composites, respectively. The comparable σ_{DC} of the hybrid composite PPGnP10GF10 (˜0.1×10⁻¹ S/m) and that of PPGnP12.5 (˜1.6×10⁻¹ S/m) indicate the effective role of GFs in the reduction of the GnP content required for the formation of a conductive percolated network. This effect can be associated with a substantial change in the interaction mode of the GnP flakes in each conduction channel. Considering the GnP content of 10 vol % as the threshold for the formation of an interconnected GnP network, the excluded volume induced by the GFs could further bring the flakes into contact. In such instances, it can be hypothesized that a transition from a tunneling-dominated conduction channel, depicted in FIG. 28B, to the channels composed of a series of overlapping GnP flakes (FIG. 28C) takes place. Accordingly, the charge transport mechanism between the GnP flakes switches from quantum tunneling to out-of-plane conductivity. Thus, as illustrated in FIG. 28C, the conductivity of a single conduction channel in the out-of-plane mode (σ_{⊥}) can be described using Formula 9. In this framework, a single channel consists of a series of overlapping GnP flakes with alternating in-plane and out-of-plane connections.

$${σ}_{⊥} = {( {( p . {σ}_{i n} )}^{- 1} + c \times \frac{2 {t}_{gr}^{2}}{{\overline{l}}_{i n} \sqrt{{\overline{A}}_{out}}} {σ}_{out}^{- 1} )}^{- 1} \qquad Formula 9$$

The first term in Formula 9 is attributed to the in-plane current transport which is defined by the GnPs' uniform in-plane conductivity (σᵢₙ) and the packing density (p) of the channel. The second term relates the out-of-plane conduction to the thickness of the GnP flakes (t_{gr}), the average in-plane distance between overlaps (l̅ᵢₙ), the average overlap area (Āₒᵤₜ) and the out-of-plane electrical conductivity (σₒᵤₜ). In Formula 9 c is a nonideality factor compensating for the simplifications and assumptions. Calculations, using Formulas 8 and 9, for the electrical conductivity of a quantum tunneling-dominated conduction channel in PPGnP10 and in its hybrid counterparts having conduction channels with overlapping GnP flakes, show σ_{⊥}≈10⁴-10⁶ σₜᵤₙ (see calculations in Section 3.5.4: Electrical Conductivity Calculations). Therefore, the denser GnP clusters generated by the volume exclusion effect of the GFs are responsible for the significant conductivity enhancements in Region II, due to the induced transition to the out-of-plane conductivity mode. Moreover, the superior σ_{DC} of PPGnP10GF10, compared to PPGnP10GF5, can be related to a larger Āₒᵤₜ in Formula 9, indicating that the larger excluded volume by 10 vol % GF could further force GnPs to be arranged in a denser fashion.

In Region III (conductive region), the biphasic composites (i.e., PPGnP12.5 and PPGnP15) follow the electrical conductivity increasing trend occurred in the hybrid cases in Region II. As shown in FIG. 25, the electrical conductivity enhancement is marginal in Region III, and shows a plateau region which is predominantly governed by the contact resistance at the GnP-GnP junctions (tunneling/out-of-plane conductivity). In contrast to the trend observed in Region II, hybrid CPCs having the GnP content of 12.5 vol % exhibit no σ_{DC} enhancement (with a slight decrease) compared to their corresponding biphasic CPC, as PPGnP12.5 and PPGnP12.5GF10 show conductivities of 1.6×10⁻¹ S/m and 4.1×10⁻² S/m, respectively. Qualitatively, the total conductivity of the composite system can be understood by thinking of two factors: the number of the current paths (N̅) formed by connecting the Voronoi edges 2304, and the average resistivity of the paths (R̅), i.e., σ=f(N̅,R̅). Generally, a is directly proportional to N and inversely to R. As described in Section 3.1, the oriented GFs can generate a segregated structure, leading to an increase in the number of the current paths N shown schematically as a Voronoi tessellations, in FIG. 23B. On the one hand, comparing to the schematic depicted in FIG. 26B, related to a composite with a low GF concentration, a higher content of GF (Voronoi site points 2303 shown in FIG. 27B) results in a greater number of Voronoi edges 2304 which can form more possible current pathways. On the other hand, the addition of GFs causes the average resistivity of the paths R to increase. To be specific, R is determined by the number of the filler-filler contact resistors, traversed by the current through the paths. By adding more secondary fillers, the average length of the current paths increases, due to the presence of a larger number of smaller Voronoi edges 2304, leading to a greater number of GnP-GnP contact resistors passed by the current. Simulation studies on a hybrid CPC indicate that the average number of the conductive nanofillers in the paths (which is normalized by the average path width) increases approximately 1.6 times, when silica micro-filler content is increased from 5 to 10 vol %. Therefore, it can be hypothesized that the total conductivity of CPCs is controlled by either N or R, depending on the fillers' concentration. Accordingly, with low GnP contents of 7.5 and 10 vol %, the total conductivity of CPCs is governed by the increased number of current paths, as a result of incorporating GFs. However, with GnP contents beyond the percolating limit (12.5 vol %), the average resistivity of the paths R is the governing factor which controls the electrical conductivities of the hybrid composites.

### 3.3.3 Permittivity of the Composites

Permittivity E is the second most important parameter affecting the EMI shielding efficiency of CPCs. Both the real and imaginary parts of permittivity, which are respectively associated with the electric polarizability and dielectric losses, show frequency-dependent behavior (i.e., ε=ε′(ω)−iε″(ω)). Generally, composites with higher conductivities have a more significant frequency-dependent permittivity, in contrast to the broadband a which exhibits more frequency independency as the conductivity increases.

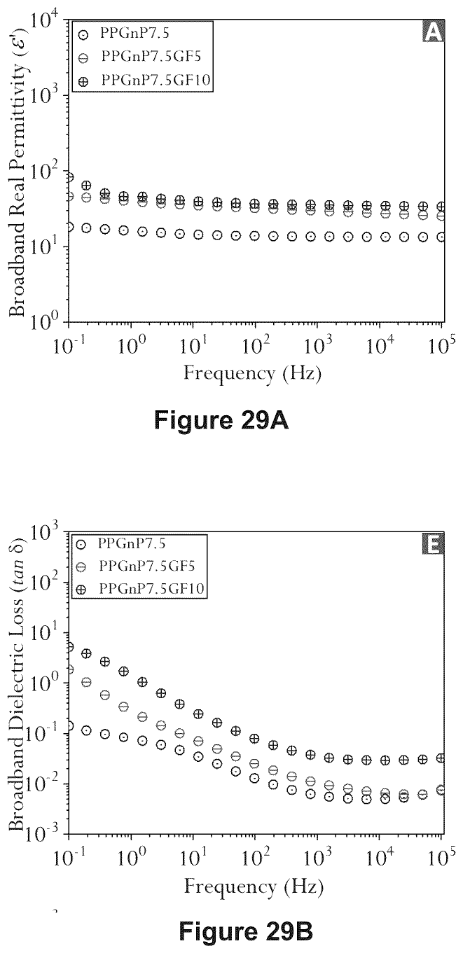

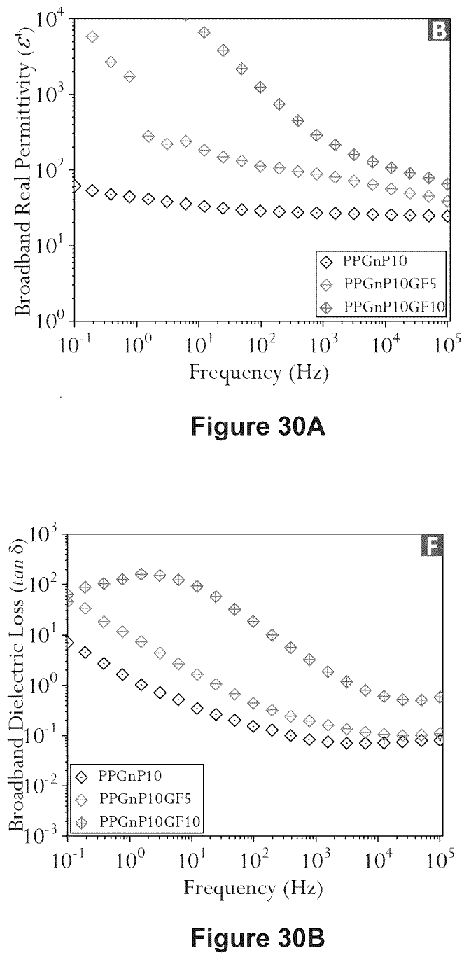

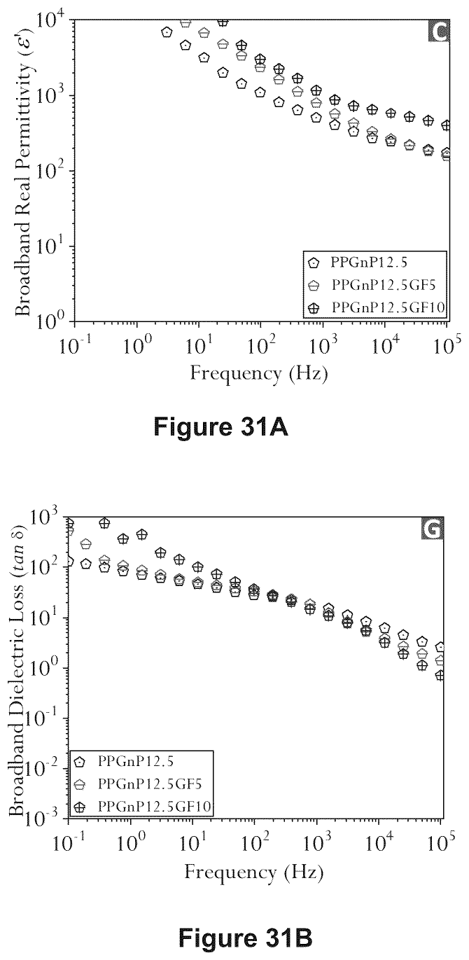

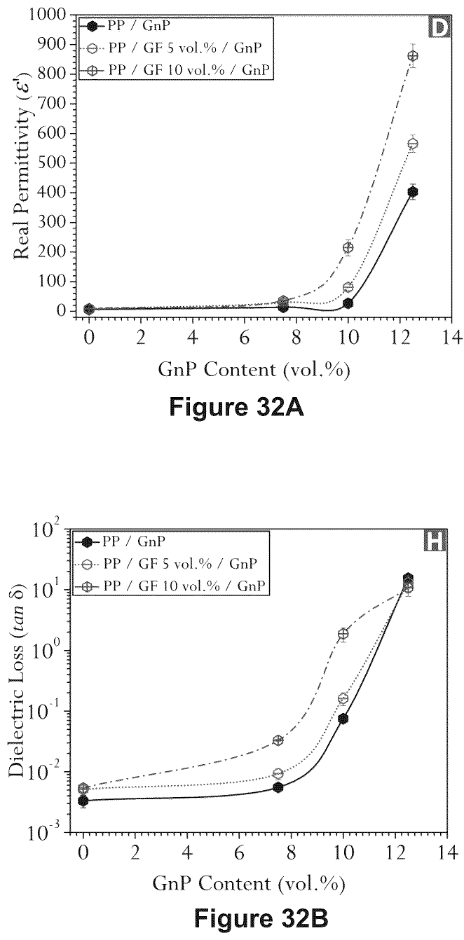

FIGS. 29A and 29B are graphs of the broadband real permittivity (ε′) and broadband dielectric loss (tan δ) of the biphasic and hybrid composites containing the GnP content of 7.5 vol %. FIGS. 30A and 30B are graphs of the broadband real permittivity (ε′) and broadband dielectric loss (tan δ) of the biphasic and hybrid composites containing the GnP content of 10 vol %. FIGS. 31A and 31B are graphs of the broadband real permittivity (ε′) and broadband dielectric loss (tan δ) of the biphasic and hybrid composites containing the GnP content of 12.5 vol %. FIG. 32A is a graph of the real permittivity of composites' ε′ measured at 1×10³ Hz. FIG. 32B is a graph of the dielectric loss of composites' tan δ measured at 1×10³ Hz.

FIG. 29A shows the broadband real permittivity ε′ of the hybrid and biphasic composites consisting of a GnP content of 7.5 vol %. It can be noticed that by the introduction of GF into the hybrid composites, not only ε′ increases to the higher values over the frequency range, but also a more frequency-dependent behavior is emerging at low frequencies. These trends are more pronounced in broadband ε′ of the hybrid CPCs with 10 and 12.5 vol % GnP, which are shown in FIGS. 30A and 31A, respectively. Real permittivity ε′ represents the charge polarization in the PP/GnP CPCs, which is governed by the following three mechanisms: (1) Interfacial polarization, (II) GnP polarization, and (Ill) Dipole polarization. Interfacial polarization (I), known as MW effect, occurs at the mesoscopic scale at interfaces of the composites' constituents (GnP and PP). This is one of the dominant polarization mechanisms at the low frequency ranges (10⁻⁶ to 1 Hz), because the nomadic charge carriers require sufficient time to migrate at the interface of the constituents and form large dipoles. However, at high frequencies, the relatively large relaxation times of the induced dipoles with respect to the alternation of the applied electric field, causes interfacial polarization to weaken. Therefore, the decreasing trend of composites' ε′ with the frequency is due to the interfacial polarization, which gradually gives up with frequency increase. GnP polarization (II) pertains to any types of polarizations which occur within GnP layers or clusters. Crystallographic defects of the GnP flakes are centers at which regional conductivity variations could facilitate charge polarization. In addition, an excess domain polarization might occur due to the electron displacement between the adjacent flakes within GnP clusters. These mechanisms are more noticeable at high frequency ranges (>1 Hz) where interfacial polarization diminishes. Dipole polarization (III) of the dielectric matrix is another polarization mechanism which governs ε′ of the CPCs at higher frequencies. Considering the non-polar nature of PP, this polarization slightly occurs due to the movement of electrons in the electric field direction. In CPCs, the combinations of the conductive fillers and the insulative matrix form a large number of parallel-plate nanocapacitors, where the GnP flakes are nanoelectrodes and the PP matrix is the nanodielectric material. In these nanocapacitors, a very strong electric field can be locally built up in the narrow gaps of the PP matrix between the GnP nanoelectrodes, which is significantly higher than the macroscopically applied field. The magnitude of the locally built-up electric field is dependent on a defined factor of M which is the ratio between the average size of GnP nanoelectrodes (D_{avg.}) and the average polymer gap width (d̅) of the nanodielectric material. Hence, these nanocapacitors are effective spots for charge polarization, since the locally built-up electric field induces the electronic polarization in the PP matrix, contributing to the real permittivity. Therefore, as more GnP is added, all three mentioned mechanisms are involved in the overall enhancements of the composites' ε′. However, in the hybrid cases with a given GnP content (FIGS. 29A, 30A, and 31A), the real permittivity enhancement is mainly attributed to the contribution of the electronic polarization of the dielectric matrix. Accordingly, the decreased d of the PP nanodielectric, due to the volume exclusion effect of GFs, results in a larger M, thereby causing a higher value of the real permittivity.

The real permittivity values measured at 1×10³ Hz, as the representative frequency, can be compared in FIG. 32A. The considerable volume exclusion effect of the GF on ε′ enhancement is observed at the GnP contents close to and beyond the percolation threshold (10 vol % GnP). Correspondingly, compared to their biphasic counterparts, around 703% and 114% ε′ enhancements occur in PPGnP10GF10 and PPGnP12.5GF10, respectively.

The broadband dielectric loss spectra, tan δ=ε″/ε′, of the biphasic and hybrid composites, shown in FIG. 28B, illustrates a more frequency-dependent behavior with higher tan δ values in the hybrid cases (PPGnP7.5GF5 and PPGnP7.5GF10). Similar trends are more significantly observed in FIG. 30B presenting tan d spectra of the CPCs containing 10 vol % of GnP. These effects demonstrate the more conductive characteristics of the hybrid composites, which are developed by the formation of the conductive GnP networks in the GF-reinforced hybrid CPCs. Under an alternating current field, dielectric loss of the CPCs originates from two main loss mechanisms, Ohmic loss and relaxation polarization loss. In CPCs, Ohmic loss expresses the energy dissipation through the free charge transport at contact points between the GnP flakes. Therefore, as the conductive networks develop, the nomadic charge carriers find more mean free paths in which to follow the alternating applied electric field. As a result, more electrical energy would be dissipated through Ohmic loss, especially at low frequencies. However, at higher frequencies, charge carriers have shorter available time frames to sweep the network in each half cycle of alternating field, so that the Ohmic loss gradually decreases. This explains the general descending trends of CPCs' tan S with increasing frequency (FIGS. 29B, 30B, and 31B). Moreover, the relaxation loss represents dielectric loss in the form of relaxation types of polarization which occur at higher frequencies. The combination of these loss mechanisms not only explains higher tan δ of the hybrid CPCs at 7.5 vol % (FIG. 29B) and 10 vol % GnP (FIG. 30B), compared to their biphasic counterparts, but also the overall tan d augmentation with the GnP content increase. Hence, as shown in FIG. 31B, CPCs with 12.5 vol % GnP demonstrate approximately 1 and 2 orders of magnitude higher tan δ values compared to their counterpart CPCs having 10 and 7.5 vol % GnP, respectively.

FIG. 32B summarizes the dielectric loss results of the CPCs representing the tan δ values measured at a representative frequency of 1×10³ Hz. According to the abovementioned analyses, the jump in tan δ values of CPCs with 10 vol % GnP, is attributed to the developing GnP network formed at the filler loading around the percolation threshold. Hence, the maximum dielectric loss increase takes place at the percolation regime where enhancement rates of 1.17 and 24.1 can be seen respectively in PPGnP10GF5 and PPGnP10GF10, compared to PPGnP10. These findings are consistent with the trend of electrical conductivity results (FIG. 29A), since Ohmic loss is the dominant loss mechanism at the GnP percolation threshold and beyond it, so that the dielectric loss and conductivity are related as tan δ=σ/fε₀ε′. Accordingly, a slight tan S decrease is also observed at a GnP content of 12.5 vol %, where PPGnP12.5GF10 shows an approximate 1.2 times smaller tan δ than PPGnP12.5 (FIG. 32B).

### 3.3.4 EMI Shielding Effectiveness of the Composites

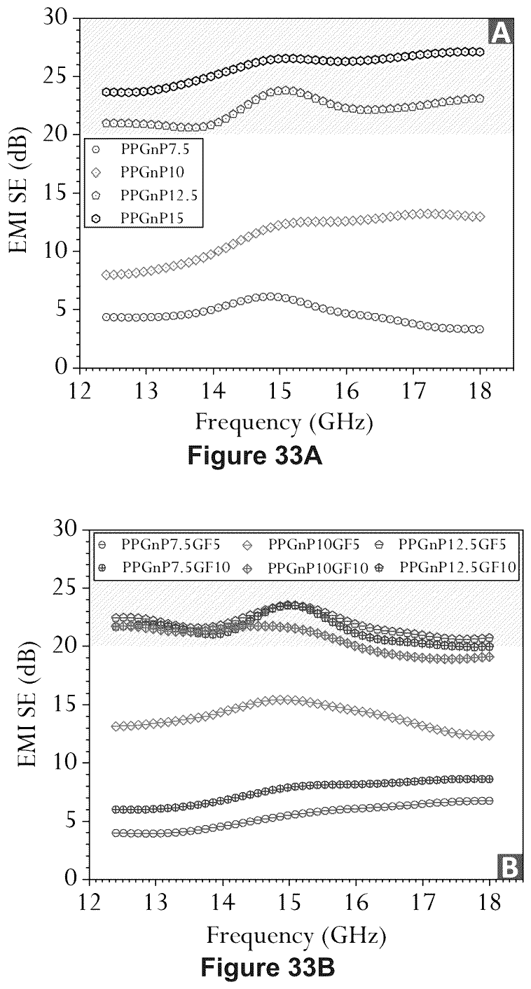

The total EMI shielding effectiveness (SE_{T}) of the biphasic and hybrid composites over the Kᵤ band frequency range (12.4-18 GHz) are presented in FIGS. 33A and 33B, respectively. The shaded regions in these figures (EMI SE 20 dB) correspond to the values at which the composites block 99% of the EM radiations. As shown in FIG. 33A, GnP12.5 and GnP15 are the only biphasic CPCs which reveal the target shielding efficiency. However, the spectra of the hybrid CPCs illustrated in FIG. 33B, demonstrate a significant enhancement in the total EMI shielding performance. Specifically, the hybrid CPC consisting of 10 vol % GnP and 10 vol % GF, satisfies the aforementioned criteria over the frequency range of 12.4-16 GHz. It is worth mentioning that 13.8-14.5 GHz is the exclusive frequency band for Fixed Satellite Service (FFS), according to International Telecommunication Union (ITU) Regulations. Therefore, there exists the possibility of interference with mobile satellite systems, which are mainly used for bringing Internet connectivity to remote areas.

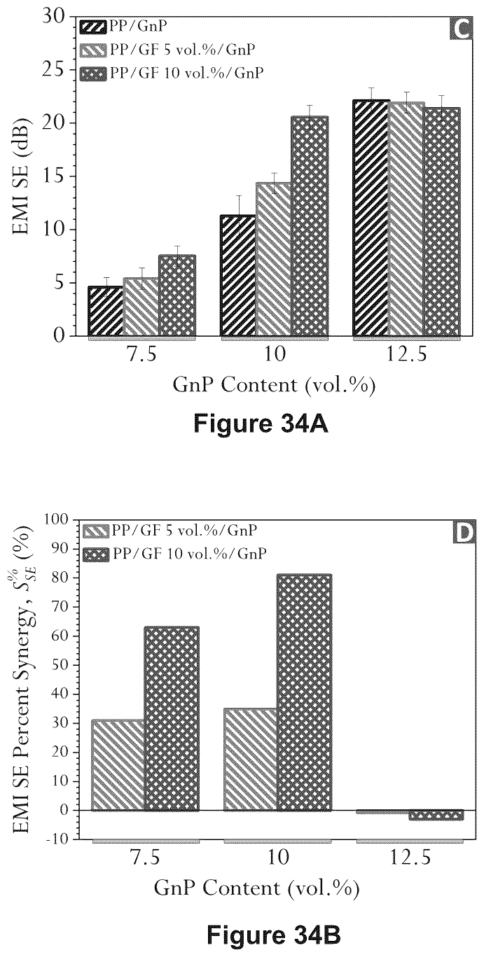

In order to analyze the EMI SE of the hybrid composites, FIGS. 34A and 34B represent respectively, the average values of the total EMI SE of CPCs over Kᵤ-band and the EMI SE synergistic effect S_{SE}^{%} calculated using the percent synergy equation (Formula 6). As FIG. 34A demonstrates, the EMI SE increase with increasing GnP content, as the biphasic composites' SE increase from 4.6 dB in PPGnP7.5 (insulative region) to 22.1 dB in PPGnP12.5 (conductive region). Interestingly, the introduction of GF, as an insulative secondary filler, manipulates the microstructure to favor EMI shielding enhancement. For example, the hybrid composites with 5 and 10 vol % GF exhibit a 32% and 64% synergy at a GnP loading of 7.5 vol %, respectively (FIG. 34B). The maximum synergistic effect (81% with an average EMI SE of 20.5 dB) occurs in PPGnP10GF10, which showed the maximum enhancements in σ and ε, among all the fabricated composite samples (see Sections 3.2 and 3.3). At the GnP loading of 12.5 vol %, all the composites reveal almost the same shielding effectiveness (≈23 dB) with a marginal decrease in the hybrid cases.

In CPCs with negligible magnetic interactions, SE_{R}, SE_{A} and SE_{M} are defined as the following equations:

SE_{R}(dB)=20 Log₁₀(|1+n|²/4|n|) Formula 10

SE_{A}(dB)=8.68αt Formula 11

SE_{M}(dB)=20 Log₁₀|1−e^{i2γt}(1−n)²/(1+n)²| Formula 12

where t is the thickness of the shielding material and γ=(1+i)α. Also, n is the complex index of refraction and α is the absorption coefficient which are calculated by Formulas 13 and 14, respectively.

n=\sqrt{(|ε′|/2)\sqrt{1+tan²δ}±1}+i\sqrt{(|ε′|/2)\sqrt{1+tan²δ}±1} Formula 13

α=(2π/λ)\sqrt{(|ε′|/2)1+tan²δ}±1 Formula 14

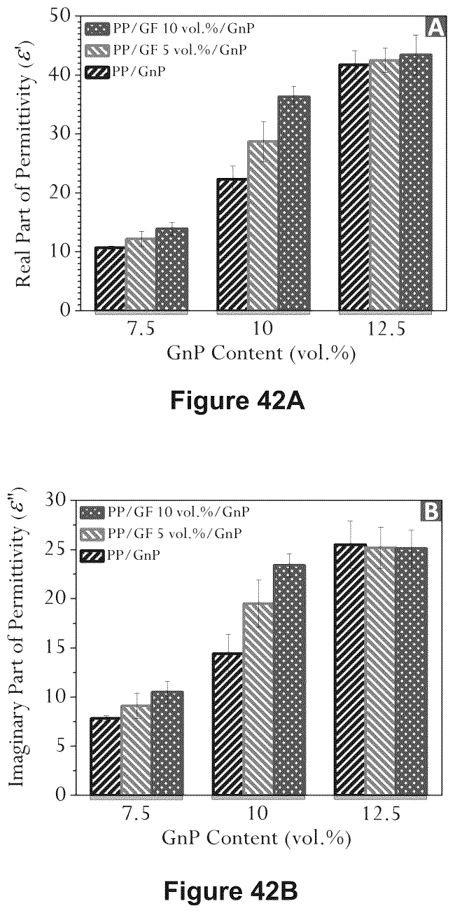

According to Formulas 10-12, the EMI SE of CPCs is proportional to the complex index of refraction (n) and the absorption coefficient (α). In Formulas 13 and 14, assuming (|ε′|/2)\sqrt{1+tan²δ}>>1, the absolute value of the index of refraction is approximated to (ε′²+ε″²)^{1/4}. With a similar assumption, the absorption coefficient can be considered as α≈(\sqrt{2}π/λ)(ε′²+ε″²)^{1/4}. These indicate that the total EMI SE is proportional to the absolute value of the complex permittivity of the composite (i.e., EMI SE∝(ε′²+ε″²)^{1/2}). Calculations using the permittivity values measured at a representative frequency of 15 GHz (described later with reference to FIGS. 42A and 42B), show that the absolute value of the complex permittivity for the CPCs having 10 vol % GnP increases from 25.8 in the biphasic case to 44.1 in the hybrid composite with 10 vol % GF. These close absolute values for the complex permittivity of PPGnP10GF10 and PPGnP12.5 (≈49.9) can be correlated to their comparable EMI SE values (FIG. 34A). In conclusion, the development of a segregated microstructure in the hybrid composite, with a GnP loading at the percolation threshold (PPGnP10GF10), causes the significant improvement in EMI SE due to the induced enhancements in the electrical conductivity and permittivity of the CPC.

### 3.3.5 Thermal Conductivity of the Composites

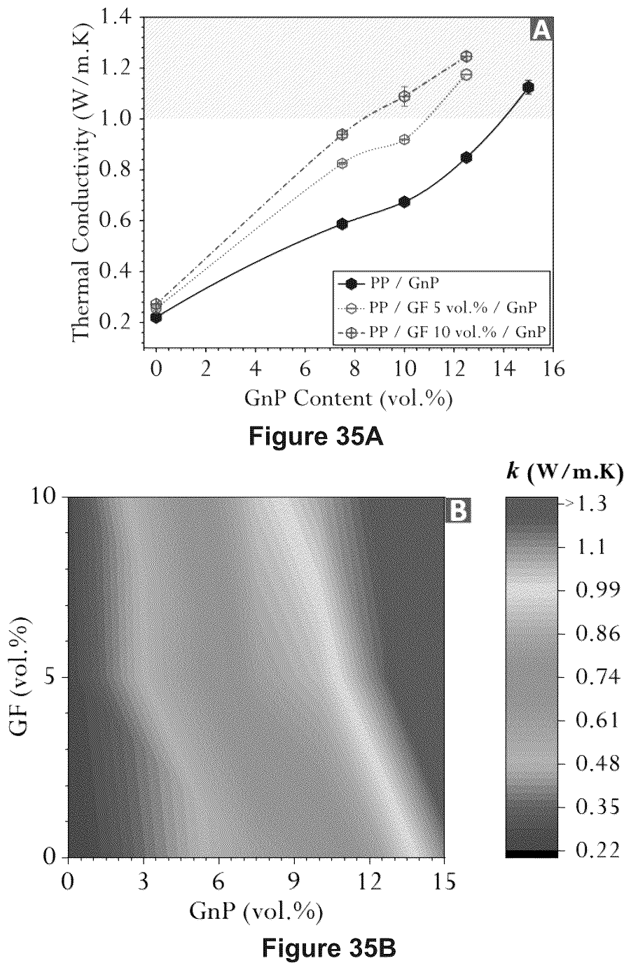

As described before, the dielectric loss, which considerably contributes to the EMI SE of the CPCs (see Formulas 10-14), is mostly governed by the Ohmic loss at GnP loadings close to and beyond the percolation threshold along with other forms of losses. This results in a conversion from the electrical to the thermal energy, which needs to be effectively dissipated. Hence, adding thermally conductive fillers like graphene into polymers has been a common practice to elevate their thermal conductivity. In this work, the target thermal conductivity has been defined as k>1 W/m·K, which denotes more than 400% enhancement in heat dissipation capability of the composites to that of the major polymers in a given thickness and temperature gradient. As shown in FIG. 35A, the thermal conductivity of the biphasic composites improves with increasing GnP content, exceeding the thermal conductivity of 1 W/m·K at a GnP loading of around 14 vol %. It is noted that several factors are causing considerable deviation of the biphasic CPCs' thermal conductivity from the intrinsic thermal conductivity of graphene (k_{G}=2,000-5,000 W/m·K). In practice, at a given concentration, the thermal conductivity of the graphene-based composites is governed by two general factors: (1) characteristics of the graphene used, such as its lateral flake size, its defect density, and the number of layers, and (2) the arrangement and the state of the dispersion of graphene within the polymer matrix. In general, the thermal conductivity in non-metallic materials, including graphene, is dominated by the lattice vibrations which are well-known as phonons. Accordingly, the thermal conductivity through phonon transfer is associated with the uniform oscillations of a lattice of atoms or molecules at a certain frequency. Based on literature, the mean free path of the phonons in graphene is approximated to 750-800 nm. The average diameter of GnP used in this study is D_{avg.}≈38 μm, being greater than the minimum required lateral flake size which is equal to the mean free path of the phonons for an effective phonon transfer. Moreover, as listed above, the level of the defect density in GnPs significantly affects their inherent thermal conductivity. In this regard, the defect density of GnP was evaluated using Raman spectroscopy, where the GnP's D-to-G peak intensity ratio is below 0.3 (i.e., I_{D}/I_{G}<0.3 is the criterion indicating its low defect density). For the GnPs used in this study, I_{D}/I_{G} is about 0.1, as shown in FIG. 40B. Thus, the GnPs possess the appropriate characteristics in terms of the lateral dimension and the level of defect density. However, measurements have revealed that the GnPs show much lower thermal conductivity than a perfect single layer of graphene. For instance, the thermal conductivity of GnPs having around 30 layers with a lateral dimension of 10 μm has been estimated as 290 W/m·K. Therefore, the GnP's number of layers is the first factor causing the comparatively low thermal conductivity of the fabricated biphasic composites. The second factor is attributed to the arrangement of the fillers in the GnP-based biphasic composites. Generally, the more randomly dispersed GnPs can induce a higher interconnectivity of the GnPs with lower phonon scattering due to the direct GnP-GnP contacts, resulting in higher thermal conductivity. However, the flow-induced orientation of GnPs, as shown in FIG. 22C, minimizes their interconnectivity. On the contrary, more random dispersions with lower interstitial distance between the GnP flakes, as displayed in FIGS. 22E and 22F, are a source of the thermal conductivity enhancements in the hybrid cases (FIG. 35A). This behaviour has been previously observed in the studies, where the addition of a secondary micro-sized filler with a different geometry promotes the formation of the conductive pathways for phonon transfer, as a result of the volume exclusion effect. As a result, the thermal conductivity of PPGnP10 (k≈0.67 W/m·K) jumps to k≈1.09 W/m·K with the addition of 10 vol % GF and the same amount of 10 vol % GnP. This indicates that PPGnP10GF10 possesses a thermal conductivity of approximately the same as that of the biphasic composite with 15 vol % GnP (≈1.12 W/m·K). The dependency of the thermal conductivity on concentration of both fillers is demonstrated by a 2D-contour in FIG. 35B. Following the yellow contour line corresponding to a thermal conductivity of 1 W/m·K, the required amount of GnP to achieve the target conductivity decreases from approximately 14 to 9 vol %, while the GF content increase from zero to 10 vol %, respectively. As displayed in FIG. 35A, the thermal conductivity variation as a function of the GF content is marginal with zero GnP content, since the thermal conductivity of the GF used (E-glass) is estimated to be around 1 W/m·K (almost 10³ times smaller than that of GnP). Consequently, the significant enhancements in the thermal conductivity of the hybrid composites are principally caused by the promotion of GnPs' interconnectivity as a result of their rearrangements.

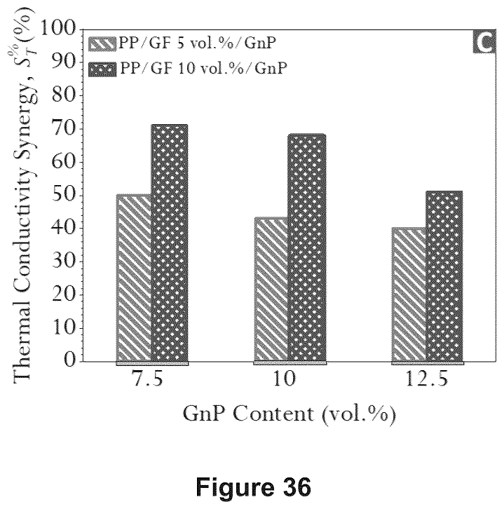

In order to quantify the synergistic effect for the hybrid composites, their thermal conductivity percent synergy S_{T}^{%} calculated by Formula 6 is illustrated in FIG. 36. The greatest synergistic effect occurs at a GnP concentration of 7.5 vol %, where 71% synergy is observed in PPGnP7.5GF10. However, there is a descending trend in S_{T}^{%} with the increase in the GnP content. This behavior has been previously reported, where the volume exclusion effect plays a more effective role in the formation of thermal conductive pathways by bringing the GnPs closer together at lower GnP concentrations. It is worth mentioning that the synergistic effects induced by GnP and GF (FIGS. 34B and 36) have different trends for the EMI shielding efficiency versus the thermal conductivity of the composites. As described earlier, the EMI shielding efficiency is a function of the electrical conductivity which is predominantly governed by the electron transfer controlled by tunneling. On the other hand, in GnP, the heat is mainly transferred by uniform lattice vibrations (i.e., acoustic phonons). Therefore, the difference between electron and heat transfer mechanisms might be the reason for the different trends of the synergistic effects observed in the EMI SE and thermal conductivities of the hybrid composites.

### 3.3.6 Tensile Properties of the Composites

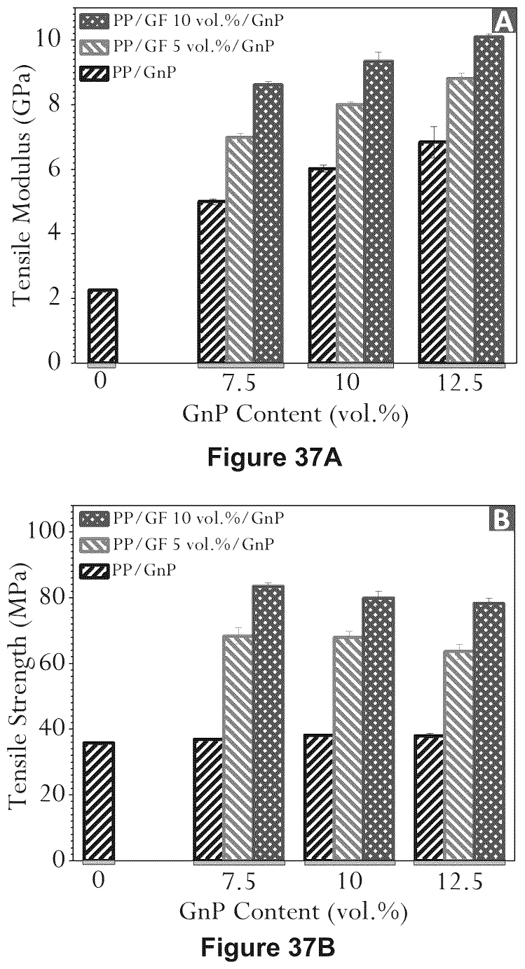

In this study, mechanical properties of the composites were investigated in terms of their tensile modulus and tensile strength. FIG. 37A is a graph of tensile modulus versus reinforcement concentrations for fabricated composites. FIG. 37B is a graph of tensile strength versus reinforcement concentrations for fabricated composites.

The Young's modulus (E) results shown in FIG. 37A demonstrate an ascending trend from the neat PP with a modulus of ˜2.2 GPa to a maximum corresponding to a tensile modulus of 10.1 GPa for PPGnP12.5GF10. According to the rule of mixtures, Young's modulus of a composite material falls in a range where the lower bound (Eₗ) is theoretically estimated by assuming a transverse loading to the fibers orientation, and the upper bound (Eᵤ) which corresponds to the theoretical modulus in axial loading. Accordingly, the upper- and lower-band moduli of the composites are calculated using the volume fractions and tensile moduli of each constituent (E_{GF}≈75 GPa and E_{GnP}≈100 GPa). For instance, Eₗ≤E_{PPGnP10GF10}=9.4 GPa≤Eᵤ where Eₗ=2.7 GPa and Eᵤ=19.2 GPa are calculated by assuming the perpendicular and parallel fillers orientation to the loading direction, respectively. Thus, the modulus enhancements displayed in FIG. 37A are attributed to the further addition of both relatively stiffer nano- and micro-filler than the matrix.

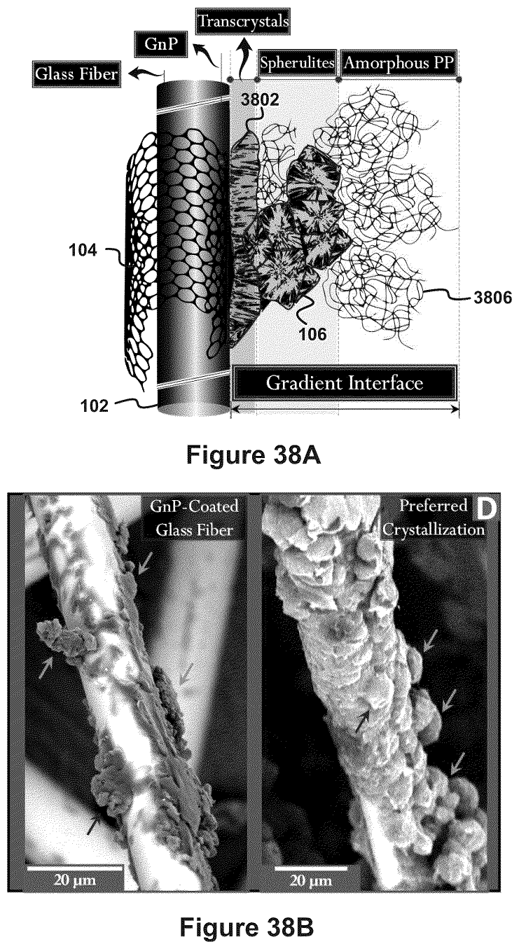

Although the development of the segregated structure effectively facilitated the electrical and thermal conductive network formation, the GnP flakes agglomerated at the interstitial space between GFs are prone to form stress concentrated regions and crack propagation. Hence, up to 30% tensile strength deterioration has been observed in studies focusing on the development of composites with segregated structures. However, in order to resolve conductivity versus mechanical property trade-offs, a hierarchical approach was taken in this study to further facilitate the stress transfer from the matrix to GFs. According to the tensile strength results shown in FIG. 37B, the hybrid composite PPGnP7.5GF10 shows 196% enhancement, compared with the PP matrix. More importantly, the transition from PPGnP7.5GF10 (insulative region) with a tensile strength of 83.4 MPa is accompanied with minimized deteriorations of about 4% to PPGnP10GF10 (percolation region), and 5% to PPGnP12.5GF10 (conductive region). Such effect is mainly associated with the formation of gradient interfaces, as represented in the schematic of FIG. 38A. An example of the hierarchical structure is shown in the SEM image of FIG. 38B. FIG. 38B is a pair of SEM micrographs of GnP-coated GFs with epitaxially grown PP crystals.

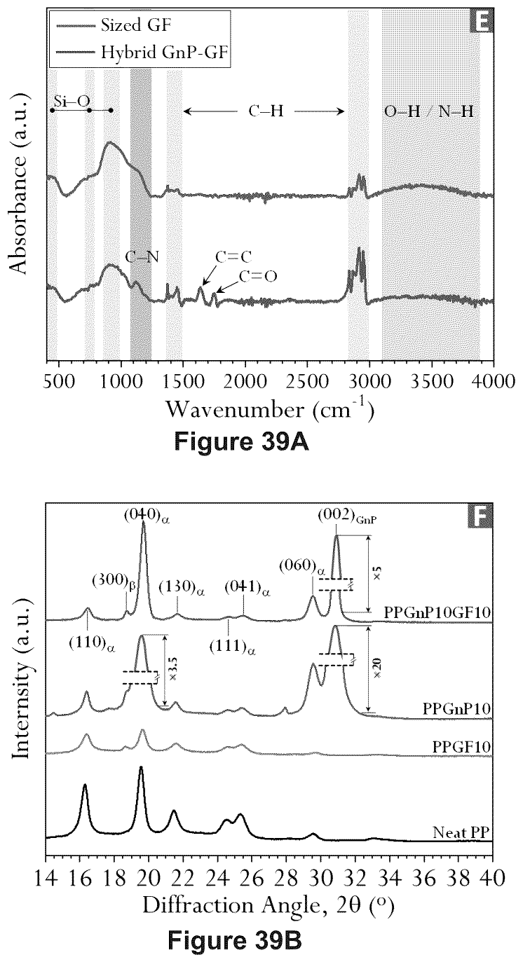

The chemical bonding of the GnPs onto the as-received chemically modified surface of GFs with aminosilane (sized GF) was analyzed by FTIR spectroscopy. FIG. 39A comprises the FTIR spectra of the sized GF and partially etched PPGnP10GF10. As shown in FIG. 39A, Si—O stretching peak (890-920 cm⁻¹), Si—O bending peak (730 cm⁻¹), Si—O rocking vibrations peak (450 cm⁻¹), as well as C—H, CH₂ and CH₃ bond peaks of the partially etched PP are observed in the FTIR spectra of both sized GF and the hybrid GnP-GF. The N—H stretching and/or intermolecular O—H bonding broad band(s) (3,100-3,800 cm⁻¹) are inherent to amine groups of the sized GF. For the GF-GnP chemical bonding, (1) nucleophilic addition with the GnP's carboxyl groups and/or (2) ring-opening of epoxides are the potential reaction(s). However, the former is the more probable reaction in this injection molded hybrid system, as shown in our previous study. Therefore, the generated hierarchical structure through chemical bonding of GnPs onto GFs, leads to the consumption of O—H/N—H in the sized GFs, and the promotion of a C—N stretching peak (1,020-1,250 cm⁻¹) in the spectrum of the hybrid GF-GnP, as shown in FIG. 39A.

FIG. 38A is a schematic showing the hierarchical structure of hybrid composites which include GF 102 coated by GnP 104. Unlike GF 102, GnP 104 is an effective substrate for the heterogeneous nucleation and formation of a crystalline phase of PP, referred to herein as “transcrystals” and indicated at 3802. The transcrystals 3802 form onto GnP planes 104 with a hexagonal primitive cell. As a result, the chemical adhesion of GnP 104 and GF 102 would bring PP transcrystals 3802 in the vicinity of GFs 102. Along with PP spherulites 106 and then amorphous PP chains 3806 towards the PP bulk (not shown), these layers together form a gradient interface which induces an effective stress transfer from the matrix to GFs 102. The formation of transcrystals 3802 in hybrid and biphasic composites were investigated by XRD spectroscopy. FIG. 39B comprises the XRD diffractograms for the neat PP and select fabricated composites.

The epitaxial growth of PP's α-phase onto GnP flakes is in such a way that GnP c—axis would merge with the PP b—axis, so that (040)_{α} planes are crystallized in parallel to (002)_{GnP} planes.

This effect is evident in FIG. 39B where the increase in the intensity of (002)_{GnP} plane is accompanied with a simultaneous increase of (040)_{α}, in both the biphasic (PPGnP10) and the hybrid (PPGnP10GF10) composites. The comparatively smaller intensities of the mentioned peaks in the hybrid composite, are related to the more random orientation of GnPs and, consequently, the transcrystalline layers formed on its surface (note that the diffractograms are attributed to the X-rays returning from the samples' surface being parallel to the flow direction). The PP crystalline structure's alteration in the composites containing GnP is quantified by I₍₀₄₀₎_{_{α}}/I₍₁₁₀₎_{_{α}}, which is the ratio of (040)_{α} (involved in PP transcrystallization) and (110)_{α} intensities. According to FIG. 39B, the ratio increases from approximately 1.2, in the neat PP and PPGF10, to 5.9 in the case of the hybrid composite, confirming the promotion of PP transcrystallization.

In addition to transcrystallization, the emergence of relatively stronger (300)_{β} intensity denotes a greater extent of the β-crystals formation in the GnP-containing composites, providing an extra effect in maintaining the strength of the hybrid composites. This is caused by the strain hardening induced by a β- to α-phase transition through unfolding the ring-banded lamellae of the β-crystals under loading.

### 3.4 Summary and Conclusions

This study provides a clear understanding of how the hybrid approach, in the development of multifunctional composites, can provide simultaneous enhancements in electrical, thermal, and mechanical properties. Accordingly, the effect of a secondary filler on electrical conductivity of the nanocomposites was analyzed at a broad range of filler loadings. The measurements showed that the volume exclusion effect induced by GFs at the GnP percolation threshold caused a transition from tunneling-dominated conductivity to out-of-plane mode, with an approximate 6 orders of magnitude increase in σ_{DC} enhancement. This effect, along with 723% enhancement in real permittivity, ε′, led to an average Kᵤ-band EMI SE of 20.56 dB for the hybrid composite with 7.5 vol % GnP less than that of a biphasic composite having a close EMI shielding performance. Also, the developed segregated structure exhibits a maximum synergistic effect of 82%, for the thermal conductivity of the hybrid composites. Furthermore, tensile property measurements demonstrated that the hierarchical hybrid approach was effective for the formation of gradient interfaces. This microstructure minimizes stress concentrations at the interfaces, thereby facilitating stress transfer to the GFs. Hence, the tensile strength was maintained around 80 MPa for all hybrid composites over the whole insulative-to-conductive spectrum.

### 3.5 Supplementary Information

### 3.5.1 Materials and Sample Preparation

The physical characteristics of the materials used in Example 3 are shown below in Table 3.

TABLE 3

| | | | Melting | MFI |
|---|---|---|---|---|
| | | Density | Point | (g/10 |
| Materials | Grade | (g/cm³) | (° C.) | min) |
| Polypropylene | HIVAL (2435) | 0.902 | 165 | 35 |
| Homopolymer | | | | |
| Glass Fiber | Celstran | 1.43 | 168 | N/A |
| | (PP-GF60-02) * | | | |
| Graphene | NanoXplore | 0.18 (Bulk | N/A | N/A |
| Nanoplatelets | (GrapheneBlack ™ 3X) | Density) | | |

* 60 wt % aminosilane-treated GF masterbatch

Table 4 shows the processing parameters used in the injection molding process described in Example 3.

TABLE 4

| Parameter | Value |
|---|---|
| Melt temperature (° C.) | 220 |
| Mold temperature (° C.) | 80 |
| Screw speed (rpm) | 110 |
| Injection flow rate (cm³s⁻¹) | 31.2 |
| Pack/hold time (s) | 5 |
| Pack/hold pressure (MPa) | 28 |

Table 5 shows the compositions of the composites fabricated in Example 3.

TABLE 5

| | | PP | GnP | GF |
|---|---|---|---|---|
| | Sample | (vol %) | (vol %) | (Vol %) |
| Biphasic | PPGF5 | 95 | 0 | 5 |
| | PPGF10 | 90 | 0 | 10 |
| | PPGnP7.5 | 92.5 | 7.5 | 0 |
| | PPGnP10 | 90 | 10 | 0 |
| | PPGnP12.5 | 87.5 | 12.5 | 0 |
| | PPGnP15 | 85 | 15 | 0 |
| Hybrid | PPGnP7.5GF5 | 87.5 | 7.5 | 5 |
| | PPGnP7.5GF10 | 82.5 | 7.5 | 10 |
| | PPGnP10GF5 | 85 | 10 | 5 |
| | PPGnP10GF10 | 80 | 10 | 10 |
| | PPGnP12.5GF5 | 82.5 | 12.5 | 5 |
| | PPGnP12.5GF10 | 78.5 | 12.5 | 10 |

### 3.5.2 Characterization

The arrangement and orientation of the fillers in biphasic and hybrid composites were investigated using a Quanta FEG 250 Scanning Electron Microscope (SEM). Before conducting SEM observations, the injection molded samples were cryo-fractured by immersion in liquid nitrogen for approximately 1-hour, and subsequently sputter-coated with platinum. To further investigate orientations of GnPs as well as PP crystals in the bulk composite, 1 D and 2D analyses were conducted using X-ray diffraction (XRD) spectroscopy. A diffractometer (Bruker D8 Davinci) equipped a with a Cobalt-sealed tube (λ=0.179 nm) parallel beam line source (0.2 mm slit, 2.5° Soller) was used to record (002) pole figure of GnP (texture analysis) for the biphasic PPGnP10 and hybrid PPGnP10GF10 composites. The Z-axis being the normal direction of the specimen (perpendicular to the flow direction) was located at the center of the pole figures. The samples were rotated for full circle ϕ=0-360° and tilted at ψ=0-20°, and intensity of reflections from the GnP crystallographic plane (002) were collected every ϕ=8°. Moreover, in order to investigate the chemical adhesion between the fillers, a Fourier-Transform Infrared (FTIR) spectrometer (Bruker, Platinum-ATR) was used. For FTIR spectroscopy over a spectral range of 500-4,000 cm⁻¹, the biphasic (PPGF10) and hybrid composite (PPGnP10GF10) were etched in boiling Xylene for 5 minutes.

Thermal conductivities of the fabricated samples were measured using a transient plane source (TPS) 2500 (Therm Test Inc., Sweden) thermal constants analyzer which works based on transient hot disk method according to ISO/DIS 22007-2.2. The analyzer is equipped with a C7577 Kapton sensor made of double spiral disk-shape nickel foils which is placed between two identical samples with flat surfaces to simultaneously heat the samples and record their temperature variations as a function of time. In this study, the measured values are composites' isotropic thermal conductivities, which represent the average dissipated heat in both in-plane and through-plane directions. Moreover, the tensile and flexural mechanical properties of the fabricated samples were measured using an Instron 5965 with a load cell of 5 kN. Five replicate samples were tested by setting the crosshead speeds of 5 and 1.3 mm/min for tensile and flexural modes, respectively.

### 3.5.3 Supplementary Results and Discussion

In 2D-XRD of the crystalline materials, the characteristic crystallographic planes are represented as arcs which are known as Debye-Scherrer diffraction rings corresponding to each plane. By the radial integration of the diffraction intensities within the 2D-XRD, the diffraction intensity distribution at different azimuth angles (β) can be expressed in a one-dimensional pattern. The concentrated intensities of the arcs in a 2D-XRD indicate a preferred orientation of the crystallographic planes, thereby showing a relatively narrower azimuth angle distribution curve. This effect can be quantified by considering the full-width at half-maximum (FWHM) of the azimuth angle distribution curve (Δβ). Therefore, in the case of the composites reinforced with GnP, As can be used to compare the orientation of the flakes within the biphasic and hybrid composites.

FIG. 40A shows Azimuthal intensity profiles of the XRD patterns of the (002)_{GnP} in the representative biphasic and hybrid composite. FIG. 40B shows Raman spectroscopy of GnPs.

In FIG. 40A, the representative hybrid composite demonstrates much broader azimuth angle distribution curve (Δβ_{H}=27.82), while its biphasic counterpart shows a narrower intensity distribution with Δβ_{B}=16.29. This further confirms the more randomly oriented GnPs within the hybrid composites.

The level of defect density of the GnP used in this study was analysed by means of Raman spectroscopy (FIG. 40B), as it considerably affects GnP's inherent thermal conductivity. The D band at ˜1340 cm⁻¹, as a double-resonance Raman peak, is activated due to the presence of defects in the hexagonal sp² network. The G band at 1585 cm⁻¹ also commonly appears in all the sp² carbon materials, originating from the in-plane C—C bond stretching in the hexagonal lattice. Therefore, the intensity ratio of these peaks (i.e., I_{D}/I_{G}) can express the level of defect density of GnPs, as I_{D}/I_{G}<0.3 is an indicator of their low defect density. According to the GnP's Raman spectra, it shows a peak intensity ratio of I_{D}/I_{G}≈0.1, implying that the level of its defect density does not impinge upon the thermal conductivity of the GnP-reinforced composites.

However, the 2D band at ˜2700 cm⁻¹ shows two distinct peaks with intensities of ˜0.5 and ˜0.25 of the G peak intensity, which is a typical Raman response of graphite and also GnPs with more than 10 layers. Therefore, as described in the main text, the number of the layers in GnP stacks is an important factor contributing to the overall thermal conductivity of the composites.

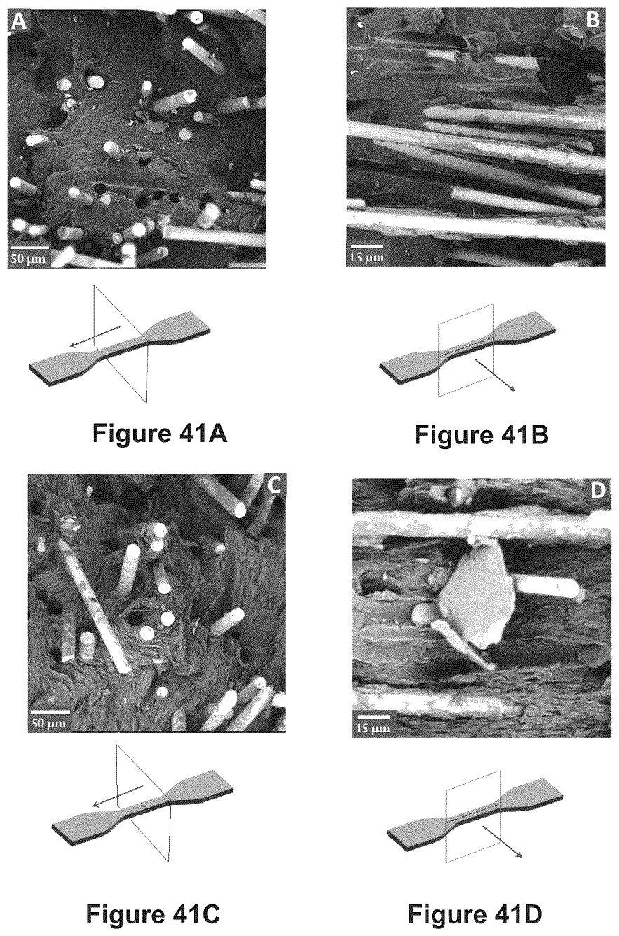

FIG. 41A is an SEM micrograph of a cross-section of the biphasic composite PPGF10. FIG. 41B is another SEM micrograph of a cross-section of the biphasic composite PPGF10. FIG. 41C is an SEM micrograph of a cross-section of the hybrid composite PPGNP10GF10. FIG. 41D is another SEM micrograph of a cross-section of the hybrid composite PPGNP10GF10.

FIG. 42A is a graph showing the real permittivity of the composites of Example 3. FIG. 42B is a graph showing the imaginary permittivity of the composites of Example 3.

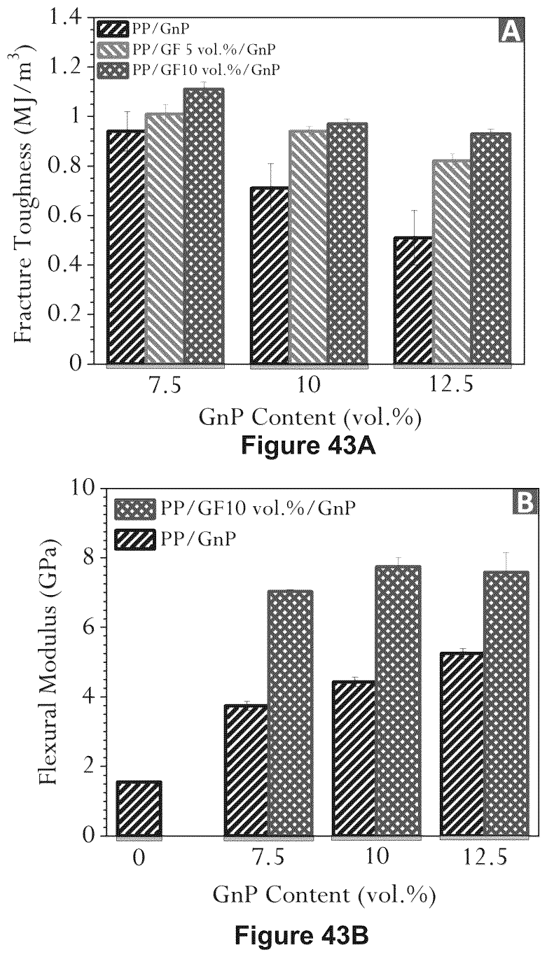

FIG. 43A is a graph showing the tensile fracture toughness for the select composites calculated from the area under the tensile stress-strain curves. FIG. 43B is a graph showing the flexural stiffness of the select composites.

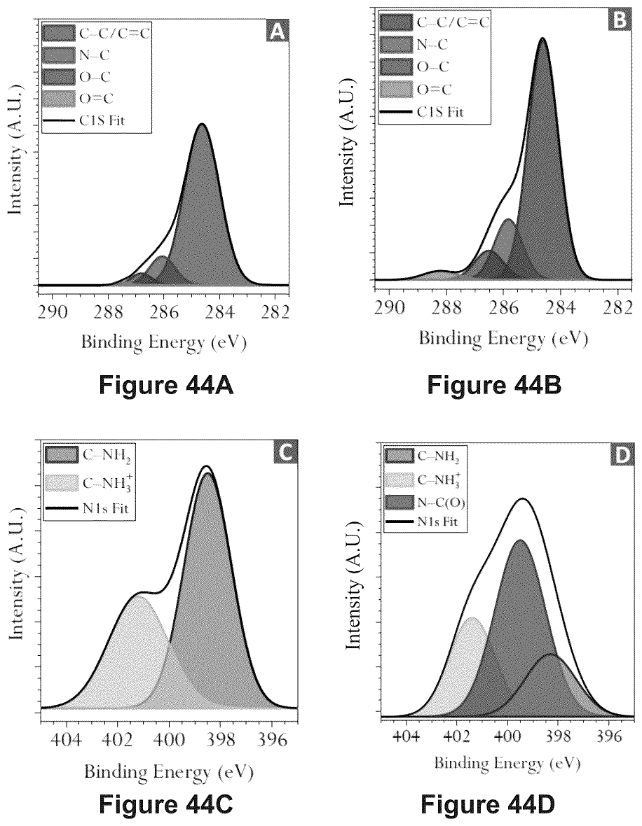

FIGS. 44A to 44D show the XPS high-resolution C1 s region spectra and high-resolution N1 s rejection spectra for the sized GF, and the sized GF with coated GNP in the hybrid composite PPGNP10GF10 with completely etched PP matrix.

According to FIG. 44A, the C1 s peaks of high resolution were deconvoluted into four distinct peaks: C—C or C—H bonds at around 284.6 eV, C—N bonds at 286.1 eV, C—O bonds at around 286.8 eV, and C═O bonds at 287.7 eV. As shown in FIG. 44B, the C—N bond intensity of the hybrid GNP-coated sized GF was greater than that of the sized GF in FIG. 44A. Based on FIG. 44C, the sized GF had two chemical bonding peaks, which were attributed to protonated amine groups (N⁺—R₄) at around 401.3 eV and non-protonated amine groups (N—R₃) at around 398.4 eV. Most amino groups on the sized GF were found to be non-protonated and oriented away from the surface, making them readily available to react. The hybrid composite (FIG. 44D) showed an additional bonding peak at around 399.5 eV, indicating the formation of N—C(O) (amide bonds), along with the protonated and remaining non-protonated amine groups. The emergence of the amide peak and decrease in intensity of the non-protonated amine peak shows that the carboxylic acid groups on the GnPs' surface (R—COOH) reacted with the non-protonated amine groups on the silane agents, resulting in the creation of a hierarchically GNP-coated GF.

In this work, the electrical properties of the fabricated composites are quantitatively evaluated through EMI shielding as a representative application. However, not limited to EMI shielding, the developed nanocomposites are suitable candidates for applications where a combination of the electrical conductivity (and/or charge storage capability) and desirable mechanical properties (tensile and flexural strength and/or stiffness) is simultaneously required. Table 6 compares both mechanical properties and electrical conductivity of the representative hybrid composite (i.e., PPGNP10GF10) and hybrid/biphasic GNP-based polymer composites studied in the literature. It is worth mentioning that Table 6 only compares the results of the works in which the mechanical property measurements were in accordance with ASTM D638 standard, making them comparable with the experimental results of the present work. Besides, the works on polymer composites containing a flexible (i.e., strength/stiffness 1) matrix, such as silicon rubber, thermoplastic polyurethane (TPU), were not considered for the comparison.

Table 6 provides a comparison of electrical conductivity and tensile properties of biphasic/hybrid polymer composites reinforced with graphene nanoplatelets.

TABLE 6

| | | | | | Electrical | Tensile | Tensile |
|---|---|---|---|---|---|---|---|
| | Primary | | Secondary | Fabrication | Conductivity | Strength | Stiffness |
| Matrix | Filler | | Filler(s) | Method | (S/m) | (MPa) | (GPa) |
| Polypropylene | GNP | (10 wt %) | — | Extrusion | 3.3 × 10⁻⁴ | ~36 | ~1.9 |
| Polypropylene | GNP | (10 wt %) | Carbon Nanotube | Batch Mixing | 5.5 × 10⁰ * | ~27 | — |
| | | | (1 wt %) | | | | |
| Epoxy | GNP | (4 wt %) | | Shear Mixing + Cold | ~10⁻⁵ | 41.9 | 3.1 |
| | | | | Molding | | | |
| Epoxy | GNP | (0.46 wt %) | | Solution Mixing | ~10⁻⁵ * | ~46 | ~1.3 |
| Epoxy | GNP | (0.5 wt %) | Nano-Alumina (0.5%) | Solution Mixing | 2 × 10⁻¹² | 35 | ~0.6 |
| Polylactic Acid | GNP | + Carbon | Nanofiber (~13 wt %) | 3D Printing | ~17 * | 25 | — |
| (PLA) | | | | | | | |
| Acrylonitrile | GNP | (~12 wt %) | — | Direct Melt Mixing | ~10⁻⁶ | 41.8 | — |
| Butadiene Styrene | | | | | | | |
| (ABS) | | | | | | | |
| Acrylonitrile | GNP | (~12 wt %) | — | Solution Pre-Mixing | ~10⁻¹ | 24.2 | — |
| Butadiene Styrene | | | | | | | |
| (ABS) | | | | | | | |
| Polyvinyl Chloride | GNP | (2 wt %) | — | Ball Milling + | ~10⁻³ | ~15 | ~0.6 |
| (PVC) | | | | Compression Molding | | | |
| Polycarbonate (PC) | GNP | (3 wt %) | | Solution Mixing | 2 × 10⁻⁷ * | 51 | ~1.4 |
| Polyamide 6 (PA6) | Graphene | | — | Mechanically | ~10 * | 55.1 | ~1 |
| | nanosheet | | | Stirring + | | | |
| | (GNS) | | | Compression | | | |
| | 1.45 | vol %) | | Molding | | | |
| Polyamide 6 (PA6) | GNP | (6 vol %) | Cu (25 vol %) + | Injection Molding | ~10900 | ~33 | ~7 |
| | | | Sn—Zn | | | | |
| | | | (19 vol %) | | | | |
| Polypropylene | GNP | (10 vol %) | Glass fiber (10 vol %) | Injection Molding | ~2 × 10⁻¹ | 81 | 9.4 |

### 3.5.4 Electrical Conductivity Calculations

In conductive polymer composites, the electrical transport occurs dominantly by tunneling between isolated clusters, especially at the conductive filler concentrations below the percolation threshold. This proposes that the probability of the penetration of electrons via a potential barrier is related to the distance and height of the potential barrier. As schematically shown in FIG. 41A, in GnP-reinforced composites, the tunneling distance (rₜᵤₙ) can be considered as the edge-to-edge distance between GnPs which act as potential wells. Accordingly, the height of the barrier can be expressed as the maximum of the potential barrier along the electron forward path (wo) which is assumed to be equal to the work function of the GnPs. The work function is the minimum energy required for removing electrons from the edge of graphene layers for tunneling.

In this study, the conductive paths within the nanocomposites are supposed as a collection of multiple but similar independent channels (FIG. 28A). Assuming a simplified state of distribution of GnPs in each channel, they are uniformly located in two parallel cuboids with a D_{ave.}+1 interparticle distance (D_{ave.} is the average diameter of the GnP flakes) and a distance of h between the parallel cuboids. The highlighted space in FIG. 41A illustrates a unit cell of the conduction channel where rₜᵤₙ is the edge-to-edge distance between GnPs each of which are shared between two neighboring unite cell.

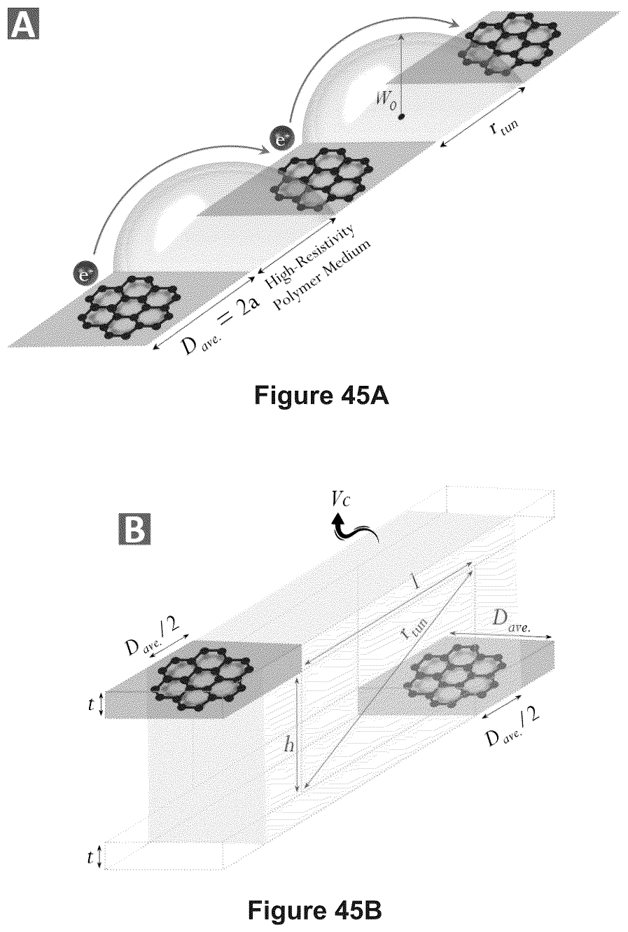

FIG. 45A is a schematic representation of the potential well model for electron tunneling between GnPs within the nanocomposites. FIG. 45B is a schematic representation of the unit cell of a conduction channel consisting of uniformly distributed GnPs with an edge-to-edge distance of rₜᵤₙ.

In general, electron tunneling would could if the tunneling distance is roughly rₜᵤₙ<3 nm. In order to estimate the GnP volume fraction (v_{GnP}) at which quantum tunneling is possible, a system of nonlinear equations can be established by considering the variables defined in FIG. 41B. Accordingly, the volume of the composite (V_{C}) corresponding to the highlighted unit cell is the sum of the volumes of the GnPs (V_{G}) and the matrix (V_{P}), i.e., V_{C}=V_{G}+V_{P}, as:

V_{C}=(D_{ave.}+l)(2t+h)D_{ave.} Formula 15

On the other hand, the tunneling distance is related to l and h as l²+h²=rₜᵤₙ².

Therefore, considering V_{C}=(100/v_{GnP})V_{G} (100/v_{GnP})πtD_{ave.}²/4, the system of the equations are as follows:

2D_{ave.}+D_{ave.}h+2tl+lh−25πD_{ave.}t/v_{GnP}=0 Formula 16

l²+h²−rₜᵤₙ²=0 Formula 17

In order to solve the system of the equations (2) and (3) for h and l, the other parameters can be considered as: rₜᵤₙ=3 nm, D_{ave.}=38 μm, and t=3.4 nm (assuming that GnPs consist of 10 graphene layers and the interlayer distance in each stack is =3.4 Å). The calculations would show that the system has a solution if v_{GnP}≥13.5%. Thus, having a completely uniform distribution of GnPs, quantum tunneling occurs between GnPs with rₜᵤₙ≤3 nm if v_{GnP}≥13.5%. However, the experimental results (FIG. 42A), show improvements in the electrical conductivities of the composites with v_{GnP}<13.5% (i.e., 7.5, 10, and 12.5%). This implies that the non-uniform distribution of GnPs within the fabricated composites, especially in the hybrid cases, acts in favor of the formation of the conduction channels with relatively a lower average rₜᵤₙ.

The quantum tunneling conductivity (σₜᵤₙ) of the composites can be calculated using the following equation:

$${σ}_{tun} = {σ}_{0} exp ( - \frac{4}{3} {( \frac{4 α {r}_{tun}}{a} )}^{3 / 4} {( \frac{{W}_{0}}{κ T} )}^{1 / 4} ) \qquad Formula 18$$

where α is an empirical constant which can be estimated ≈0.7 in the case of carbon-based particles, through Monte-Carlo numerical simulation. a is the characteristic radius of the conductive clusters which is ≈D_{ave.}/2=19 μm. W₀=5 eV is the characteristic barrier height in field emission, i.e., the maximum of the potential energy along the forward path of electron moving out of the graphene edge to the dielectric potential barrier. κ=1.380649×10⁻²³ J/K is the Boltzmann constant and T=298 K is the temperature. In Equation 11,

$${σ}_{0} = \frac{16 {G}_{0} {r}_{tun}^{3} N}{{a}_{0}}$$

is the pre-exponential normalization factor where

$${G}_{0} = \frac{{e}^{2}}{π ℏ} = 7.748092 \times 1 {0}^{- 5} S$$

is the conductance quantum (e=1.602177×10⁻¹⁹ C is the elementary charge and \tilde{h}=1.054571×10⁻⁵ J·s is the reduced Planck constant). Also, N is the density of the free electrons which can be approximated that rₜᵤₙ³N=0.24. At v_{GnP}<13.5%, the tunneling distance can be considered ≈3 nm, assuming that the GnP content is below the theoretical volume fraction to cause lower tunneling distances. By considering the above-mentioned values and also assuming a₀=D_{ave.}, σₜᵤₙ at v_{GnP} 10% is calculated approximately 6.02 S/m.

The electrical conductivity of the channel in out-of-plane mode (σ_{⊥}) (FIG. 28C) can be calculated as follows:

$${σ}_{⊥} = {( {( p \cdot {σ}_{i n} )}^{- 1} + c \times \frac{2 {t}^{2}}{{\overline{l}}_{i n} \sqrt{{\overline{A}}_{out}}} {σ}_{out}^{- 1} )}^{- 1} \qquad Formula 19$$

where

$$p \approx 1 - \frac{{\overline{l}}_{in}}{{D}_{ave .}}$$

is the packing density of the channel. σᵢₙ≈10⁶ S/m and σₒᵤₜ≈3.3×10² S/m

are the in-plane and out-of-plane conductivity of GnP, respectively. c which ranges from 1.5 to 1.9 is a nonideality factor inserted to compensate for the simplifications and assumptions. l̅ᵢₙ is the average in-plane distance between overlaps, and Āₒᵤₜ≈D_{ave.}²−D_{ave.} l̅ᵢₙ is the average overlap area. Therefore, by assuming c=1.5, t=3.4 nm and l̅ᵢₙ=0.8 D_{ave.}, the conductivity of the channel in the out-of-plane mode is calculated 1.99×10⁵ S/m. By changing the nonideality factor and l̅ᵢₙ, it can be shown that σ_{⊥}=10⁴-10⁶ σₜᵤₙ.

It is worth mentioning that the calculated values represent the conductivity of the conduction channels, which differs from the total conductivity of the composites. Because in real circumstances, even at concentrations beyond the percolation threshold, the GnP clusters at the middle points of the conduction paths (Voronoi edges) and/or their junctions (Voronoi vertices) are very likely to have imperfect overlapping and/or be totally disconnected by the dielectric medium.

What is claimed is:

1. A polymer composite for use in electromagnetic inference shielding, the polymer composite comprising:
a polymer matrix;
between 10±2% to 30±6% by weight of the polymer composite of glass fibers; and
between 1±0.2% to 3±0.6% by weight of the polymer composite of graphene nanoplatelets.

2. The polymer composite of claim 1 having an electromagnetic inference shielding effectiveness of about 19 dB to about 24 dB.

3. The polymer composite of claim 1 having a thermal conductivity of about 0.84 W/m·K to about 1.24 W/m·K.

4. The polymer composite of claim 1 having a tensile strength of about 60 to about 85 MPa.

5. The polymer composite of claim 1 having a tensile modulus of about 7 GPa to about 10 GPa.

6. The polymer composite of claim 1 wherein the glass fibers are silanized.

7. The polymer composite of claim 1 wherein the glass fibers have an average length between 1±0.05 mm and 20±1 mm.

8. The polymer composite of claim 1 wherein the glass fibers have an average diameter of between 4±0.2 μm and 34±1.7 μm.

9. The polymer composite of claim 1 wherein the glass fibers comprise between 20% and 26% by weight of the polymer composite.

10. The polymer composite of claim 9 wherein the glass fibers comprise 25±1% by weight of the polymer composite.

11. The polymer composite of claim 1 wherein the agglomerate flake diameter of the graphene nanoplatelets is about 38±2 μm.

12. The polymer composite of claim 1 wherein the graphene nanoplatelets comprise between about 6 and about 10 layers of graphene on average.

13. The polymer composite of claim 1 wherein the graphene nanoplatelets comprise between about 11 and about 20 layers of graphene on average.

14. The polymer composite of claim 1 wherein the graphene nanoplatelets have a bulk density of 0.18±0.01 g/cm³.

15. The polymer composite of claim 1 wherein the graphene nanoplatelets comprise 1.8%±0.4% by weight of the polymer composite.

16. The polymer composite of claim 1 wherein the polymer matrix comprises polypropylene.

17. The polymer composite of claim 1 having a density of about 0.99±0.1 g/cm³.

18. A polymer composite for electromagnetic interference shielding, the polymer composite comprising:
polypropylene;
25±1% by weight of the polymer composite of glass fibers; and
1.8±0.4% by weight of the polymer composite of graphene nanoplatelets, the graphene nanoplatelets comprising an average of 6 to 10 layers of graphene;
wherein the polymer composite has an electromagnetic interference shielding effectiveness of at least about 20 dB.

19. An enclosure for an electric component of a vehicle comprising the polymer composite of claim 1.

20. An electric vehicle comprising the polymer composite of claim 1.
